(19) United States
(12) Patent Application Publication
(10) Pub. No.: US 2026/0256003 A1
(43) Pub. Date: Aug. 27, 2026

(54) PHOTOSENSITIVE COMPOSITION, TRANSFER FILM, METHOD FOR MANUFACTURING LAMINATE, LAMINATE, AND SEMICONDUCTOR PACKAGE

(71) Applicant: FUJIFILM Corporation, Tokyo (JP)

(72) Inventor: Keigo Yamaguchi, Shizuoka (JP)

(73) Assignee: FUJIFILM Corporation, Tokyo (JP)

(21) Appl. No.: 19/644,117

(22) Filed: Apr. 10, 2026

Related U.S. Application Data
(63) Continuation of application No. PCT/JP2024/039588, filed on Nov. 7, 2024.

(30) Foreign Application Priority Data
Nov. 17, 2023 (JP) 2023-196109

(51) Int. Cl. H10W 70/695; C08G 73/10; C08K 3/36; C08K 5/18; H10W 70/05; H10W 70/63

(52) U.S. Cl. CPC H10W 70/695; C08G 73/1025; C08K 3/36; C08K 5/18; H10W 70/095; H10W 70/096; H10W 70/635; C08K 2201/003

(57) ABSTRACT

An object of the present invention is to provide a photosensitive composition capable of forming a film having excellent migration resistance and excellent resolution. The photosensitive composition according to the embodiment of the present invention includes a polyimide precursor; a polymerizable compound that is a compound different from the polyimide precursor; and a compound represented by Formula (1), in which the polymerizable compound includes a compound having two or more polymerizable groups, and an acid value of the polyimide precursor is 75 mgKOH/g or less.

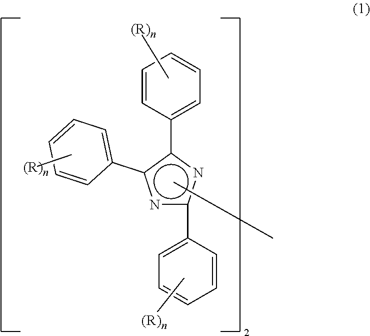

### CROSS-REFERENCE TO RELATED APPLICATIONS

This application is a Continuation of PCT International Application No. PCT/JP2024/039588 filed on Nov. 7, 2024, which claims priority under 35 U.S.C. § 119 (a) to Japanese Patent Application No. 2023-196109 filed on Nov. 17, 2023. The above applications are hereby expressly incorporated by reference, in their entirety, into the present application.

### BACKGROUND OF THE INVENTION

### 1. Field of the Invention

The present invention relates to a photosensitive composition, a transfer film, a method for manufacturing a laminate, a laminate, and a semiconductor package.

### 2. Description of the Related Art

In a display device provided with a touch panel such as a capacitive input device (for example, a display device such as an organic electroluminescence (EL) display device and a liquid crystal display device), a conductive pattern such as an electrode pattern corresponding to a sensor in a visual recognition part and a wiring for a peripheral wiring portion and a lead-out wiring portion is provided inside the touch panel. An insulating film is used for forming, protecting, and the like of such an electrode pattern and a conductive pattern. Similarly, in a build-up substrate or the like of a multi-layer printed wiring board and a semiconductor package, the insulating film is provided between each layer for the purpose of insulating and protecting wirings.

As a composition capable of forming the above-described insulating film, for example, WO2021/006315A discloses a negative photosensitive resin composition containing an alkali-soluble resin and two or more predetermined oxime ester-based photopolymerization initiators.

### SUMMARY OF THE INVENTION

As a result of studying a film formed of the above-described negative photosensitive resin composition, the present inventors have found that the resolution does not satisfy a desired level and there is room for improvement.

In addition, the film obtained from the photosensitive composition is also required to have excellent migration resistance.

Therefore, an object of the present invention is to provide a photosensitive composition capable of forming a film having excellent migration resistance and excellent resolution.

In addition, another object of the present invention is to provide a transfer film, a method for manufacturing a laminate, a laminate, and a semiconductor package, which are related to the above-described photosensitive composition.

As a result of conducting an extensive investigation to achieve the objects, the present inventors have found that the objects can be achieved by the following configuration.

[1] A photosensitive composition comprising: a polyimide precursor; a polymerizable compound that is a compound different from the polyimide precursor; and a compound represented by Formula (1), in which the polymerizable compound includes a compound having two or more polymerizable groups, and an acid value of the polyimide precursor is 75 mgKOH/g or less.

[2] The photosensitive composition according to [1], in which the acid value of the polyimide precursor is 10 mgKOH/g or less.

[3] The photosensitive composition according to [1] or [2], in which a dissolution rate of the polyimide precursor in 200 mL of an aqueous solution of 2.38% by mass tetramethylammonium hydroxide at 23° C. is 100 mg/min or less.

[4] The photosensitive composition according to any one of [1] to [3], in which the polyimide precursor has a polymerizable group.

[5] The photosensitive composition according to any one of [1] to [4], in which a weight-average molecular weight of the polyimide precursor is 10,000 to 50,000.

[6] The photosensitive composition according to any one of [1] to [5], in which a content of the polyimide precursor is 10.0% to 90.0% by mass with respect to a total solid content of the photosensitive composition.

[7] The photosensitive composition according to any one of [1] to [6], in which a weight-average molecular weight of the polymerizable compound is 150 to 1,000.

[8] The photosensitive composition according to any one of [1] to [7], in which a content of the polymerizable compound is 3.0% to 50.0% by mass with respect to a total solid content of the photosensitive composition.

[9] The photosensitive composition according to any one of [1] to [8], in which a mass ratio of a content of the polymerizable compound to a content of the polyimide precursor is 0.20 or more.

[10] The photosensitive composition according to any one of [1] to [9], further comprising: a chain transfer agent.

[11] The photosensitive composition according to [10], in which a content of the chain transfer agent is 0.01% to 5.0% by mass with respect to a total solid content of the photosensitive composition.

[12] The photosensitive composition according to any one of [1] to [11], further comprising: a polymerization inhibitor.

[13] The photosensitive composition according to [12], in which a content of the polymerization inhibitor is 0.01% to 5.0% by mass with respect to a total solid content of the photosensitive composition.

[14] The photosensitive composition according to any one of [1] to [13], further comprising: a sensitizer.

[15] The photosensitive composition according to [14], in which a content of the sensitizer is 0.01% to 5.0% by mass with respect to a total solid content of the photosensitive composition.

[16] The photosensitive composition according to any one of [1] to [15], further comprising: a filler.

[17] The photosensitive composition according to [16], in which the filler includes at least one selected from the group consisting of silicon dioxide, boron nitride, barium sulfate, and silicate.

[18] The photosensitive composition according to or [17], in which an average particle diameter of the filler is 100 nm or less.

[19] The photosensitive composition according to any one of to [18], in which a content of the filler is 30.0% by mass or more with respect to a total solid content of the photosensitive composition.

[20] The photosensitive composition according to any one of to [19], in which a content of the filler is 90.0% by mass or less with respect to a total solid content of the photosensitive composition.

[21] A transfer film comprising: a temporary support; and a photosensitive composition layer formed of the photosensitive composition according to any one of [1] to [20].

[22] A method for manufacturing a laminate, comprising: a step 1 of forming a photosensitive composition layer on a base material using the photosensitive composition according to any one of [1] to [20]; a step 2 of forming a pattern including a via on the photosensitive composition layer; and a step 3 of performing at least one of heating or exposure on the pattern.

[23] A laminate manufactured by the method for manufacturing a laminate according to [22].

[24] A semiconductor package comprising: the laminate according to [23].

According to the present invention, it is possible to provide a photosensitive composition capable of forming a film having excellent migration resistance and excellent resolution.

In addition, according to the present invention, it is also possible to provide a transfer film, a manufacturing method of a laminate, a laminate, and a semiconductor package, each of which is related to the above-described photosensitive composition.

### BRIEF DESCRIPTION OF THE DRAWINGS

FIG. 1 is a schematic view showing an example of a layer configuration of a transfer film.

### DESCRIPTION OF THE PREFERRED EMBODIMENTS

Hereinafter, the present invention will be described in detail.

The description of the configuration requirements described below may be made based on the representative embodiments of the present invention, but the present invention is not limited to those embodiments.

In the present specification, a numerical range expressed using “to” means a range that includes the preceding and succeeding numerical values of “to” as a lower limit value and an upper limit value, respectively.

In addition, in the present specification, in a case where there are two or more components corresponding to a certain component, “content” of such a component means the total content of the two or more components.

In the present specification, regarding numerical ranges that are described stepwise, an upper limit value or a lower limit value described in a numerical range may be replaced with an upper limit value or a lower limit value of another stepwise numerical range. In addition, in the numerical range described in the present specification, an upper limit value and a lower limit value described in a certain numerical range may be replaced with values shown in Examples.

In the present specification, a combination of two or more preferred aspects is a more preferred aspect.

A term “step” in the present specification includes not only an independent step but also a step that cannot be clearly distinguished from other steps, as long as the intended purpose of the step is achieved.

In the present specification, a temperature condition may be set to 25° C. unless otherwise specified. For example, unless otherwise specified, a temperature at which each of the above-described steps is performed may be 25° C. In addition, in the present specification, the room temperature is 25° C. unless otherwise specified.

In the present specification, a term “transparent” means that an average transmittance of visible light at a wavelength of 400 to 700 nm is 80% or more, and preferably 90% or more.

In addition, the average transmittance of visible light is a value measured by using a spectrophotometer, and for example, can be measured by using a spectrophotometer U-3310 manufactured by Hitachi, Ltd.

In the present specification, “actinic ray” or “radiation” means, for example, a bright line spectrum of a mercury lamp such as g-rays, h-rays and i-rays, or far ultraviolet rays typified by an excimer laser, extreme ultraviolet rays (EUV light), X-rays, electron beams (EB). Incidentally, in the present invention, light means actinic rays or radiation.

Unless otherwise specified, “exposure” in the present specification encompasses not only exposure by a mercury lamp, far ultraviolet rays typified by an excimer laser, extreme ultraviolet rays, X-rays, EUV light, or the like, but also exposure of drawing by corpuscular beams such as electron beams and ion beams.

In the present specification, the term “solid content” of a photosensitive composition means a component that forms a film formed of the photosensitive composition. Typically, in a case where the photosensitive composition layer contains a solvent (for example, an organic solvent, water, and the like), the “solid content” means all components excluding the solvent. In addition, in a case where the components are components which form the film, the components are considered to be solid contents even in a case where the components are liquid components.

In the present specification, unless otherwise specified, a content ratio of each repeating unit of a polymer is a molar ratio.

In the present specification, unless otherwise specified, a molecular weight in a case of a molecular weight distribution is a weight-average molecular weight (Mw). In the present specification, a weight-average molecular weight (Mw) and a number-average molecular weight (Mn) are values in terms of polystyrene by gel permeation chromatography (GPC).

In the present specification, the term “(meth)acryl” is a concept including both acryl and methacryl, the term “(meth)acryloyl” is a concept including both acryloyl and methacryloyl group, the term “(meth)acrylate” is a concept including both acrylate and methacrylate, and the term “(meth)acrylamide” is a concept including both acrylamide group and methacrylamide.

A bonding direction of a divalent group (for example, —CO—O—) described in the present specification is not limited unless otherwise specified. For example, in a case where Y in a compound represented by a formula “X-Y-Z” is —CO—O—, the compound may be “X—O—CO—Z” or “X—CO—O—Z”.

The compounds described in the present specification may include, unless otherwise specified, isomers (compounds having the same number of atoms but having different structures), optical isomers, and isotopes thereof. Moreover, only one kind or a plurality of kinds of the isomers and the isotopes may be included.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The above-described average thickness is an average thickness obtained by producing a section to be measured using an ultramicrotome, measuring thicknesses of any five points, and arithmetically averaging the values.

In the present specification, a boiling point means a boiling point at normal pressure (1 atm, 760 mmHg) unless otherwise specified.

In the present specification, a refractive index is a value measured with an ellipsometer at a wavelength of 550 nm unless otherwise specified.

### Photosensitive Composition

Hereinafter, the photosensitive composition according to the embodiment of the present invention (hereinafter, also simply referred to as “photosensitive composition”) will be described in detail.

The photosensitive composition according to the embodiment of the present invention contains a polyimide precursor; a polymerizable compound that is a compound different from the polyimide precursor; and a compound (hereinafter, also referred to as “specific compound”) represented by Formula (1), in which the polymerizable compound includes a compound having two or more polymerizable groups, and an acid value of the polyimide precursor is 75 mgKOH/g or less.

The reason why the photosensitive composition having the above-described structure can solve the problems of the present invention is not entirely clear, but the present inventors speculate as follows.

The mechanism by which the effect is obtained is not limited by the following speculation. In other words, even in a case where the effect is obtained by a mechanism other than the one described below, it is still included within the scope of the present invention.

In the photosensitive composition according to the embodiment of the present invention, by containing a polyimide precursor having an acid value of 75 mgKOH/g or less, an unintended reaction such as a decomposition reaction derived from an acid group or the like contained in the polyimide in the formed film is suppressed, and the formed film has excellent migration resistance. In addition, it is presumed that in the photosensitive composition according to the embodiment of the present invention, since the polymerizable compound includes a compound having two or more polymerizable groups and the compound represented by Formula (1) is contained as an initiator, the reactivity of the polymerizable group with respect to the exposure amount is improved, and as a result, the resolution is also excellent. Furthermore, it is presumed that since the radical generated from the compound represented by Formula (1) has a large molecular size and has a plurality of aromatic ring structures that easily interact with the polyimide precursor, the diffusivity of the radical in a case where the photosensitive composition according to the embodiment of the present invention is subjected to pattern exposure is small, and the optical pattern during the pattern exposure is easily maintained, that is, the resolution is excellent.

Hereinafter, the fact that the film formed of the photosensitive composition according to the embodiment of the present invention has excellent migration resistance is also simply referred to as “excellent migration resistance”, and the fact that at least one of the resolution or the migration resistance is more excellent is also referred to as “the effect of the present invention is more excellent”.

### Polyimide Precursor

The photosensitive composition contains a polyimide precursor having an acid value of 75 mgKOH/g or less. The acid value will be described in detail later.

The polyimide precursor is a resin which is converted into a polyimide, which is a resin having an imide structure, by a heat treatment, a light treatment, or a chemical treatment.

The polyimide is preferably a resin having a cyclic imide structure, and may have a substituent.

The polyimide precursor preferably has a polymerizable group. In the present specification, even in a case where the polyimide precursor has a polymerizable group, the polyimide precursor is not regarded as a polymerizable compound.

Examples of the polymerizable group include known polymerizable groups such as a radically polymerizable group, an epoxy group, an oxetanyl group, a methylol group, and an alkoxymethyl group, and a radically polymerizable group is preferable.

The radically polymerizable group is preferably a group having an ethylenically unsaturated double bond. Examples of the group having an ethylenically unsaturated double bond include a (meth)acryloyl group, a (meth)acrylamide group, a vinyl group, a styryl group, an allyl group, and a vinyl ether group; and a (meth)acryloyl group is preferable.

The polymerizable group is also preferably a polymerizable group which can be polymerized with a polymerizable group in a polymerizable compound described later.

The polyimide precursor may have an acid group, but it is also preferable that the polyimide precursor does not have an acid group from the viewpoint that an acid value of the polyimide precursor and a dissolution rate described later can be adjusted and the effect of the present invention is more excellent. Examples of the acid group include a carboxy group, a phenolic hydroxy group, a sulfonic acid group, a phosphoric acid group, and salts thereof.

The polyimide precursor preferably has a repeating unit represented by Formula (1). In other words, the polyimide formed from the polyimide precursor contained in the photosensitive composition is preferably a resin synthesized from a polyimide precursor having a repeating unit represented by Formula (1) (for example, a resin obtained by a cyclization reaction).

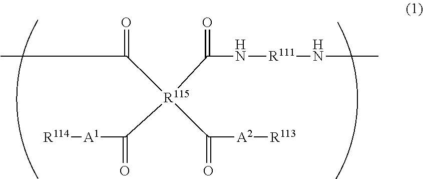

In Formula (1), A¹ and A² each independently represents an oxygen atom or —NH—. R111 represents a divalent organic group. R¹¹³ and R¹¹⁴ each independently represents a hydrogen atom or a monovalent organic group. R¹¹⁵ represents a tetravalent organic group.

In Formula (1), A¹ and A² each independently represents an oxygen atom or —NH—. As A¹ and A², an oxygen atom is preferable.

In Formula (1), R¹¹¹ represents a divalent organic group.

Examples of the above-described divalent organic group include a divalent aliphatic group, a divalent aromatic ring group, and a group formed by a combination of these groups. As the divalent organic group, a divalent aliphatic group having 2 to 20 carbon atoms, a divalent aromatic ring group having 6 to 20 carbon atoms, or a group formed by a combination of these groups is preferable, and a divalent aromatic ring group having 6 to 20 carbon atoms is more preferable. The above-described aliphatic group may be linear, branched, or cyclic. The aromatic ring group may be any of monocyclic or polycyclic. The above-described aliphatic group and aromatic ring group may have a heteroatom. The heteroatom may be included in a divalent organic group as a group such as —O—, —CO—, —S—, —SO₂—, and —NHCO—.

As R^{111,} a divalent organic group derived from a diamine is also preferable. The above-described diamine is preferably a diamine used for producing the polyimide precursor, and more preferably an aliphatic diamine or an aromatic diamine.

The above-described diamine is preferably a diamine having a linear aliphatic group having 2 to 20 carbon atoms, a branched aliphatic group having 3 to 20 carbon atoms, a cyclic aliphatic group having 3 to 20 carbon atoms, an aromatic ring group having 6 to 20 carbon atoms, or a group formed by a combination of these groups; and more preferably a diamine having an aromatic ring group having 6 to 20 carbon atoms (aromatic diamine). Examples of the above-described aromatic ring group include groups having the following structures.

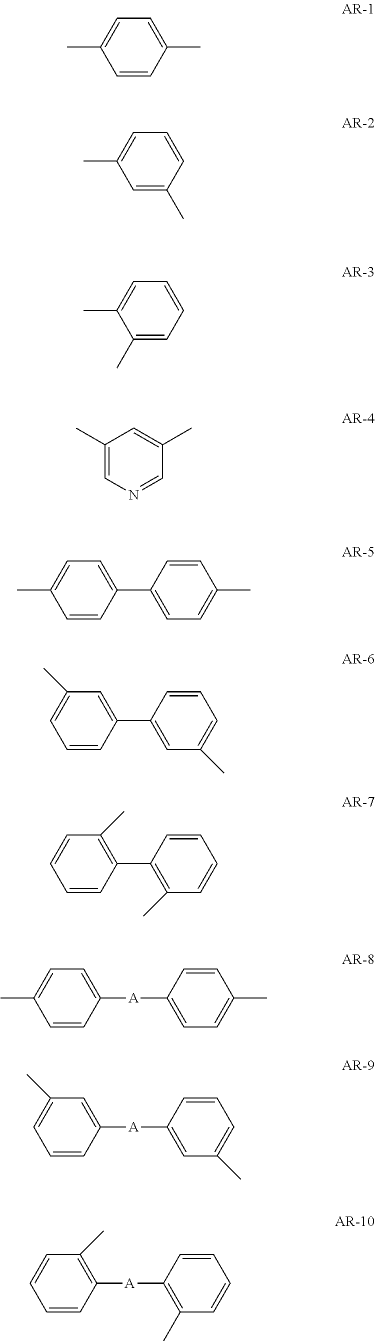

In AR-8 to AR-10, A represents a divalent aliphatic hydrocarbon group having 1 to 10 carbon atoms, which may have a fluorine atom, —O—, —CO—, —S—, —SO₂—, —NHCO—, a group formed by a combination of these groups, or a single bond. A is preferably an alkylene group having 1 to 3 carbon atoms, which may have a fluorine atom, —O—, —CO—, —S—, or —SO₂—, more preferably —CH₂—, —O—, —S—, —SO₂—, —C (CF₃)₂—, or —C (CH₃)₂—, and still more preferably —O—. R¹¹¹ is also preferably *—Ar⁰—L⁰—Ar⁰—*.

Ar⁰'s each independently represents a divalent aromatic hydrocarbon group. L⁰ represents a divalent aliphatic hydrocarbon group having 1 to 10 carbon atoms, which may have a fluorine atom, —O—, —CO—, —S—, —SO₂—, —NHCO—, a group obtained by combining these groups, or a single bond, and * represents a bonding position.

Ar⁰'s may be the same or different from each other.

The number of carbon atoms in the divalent aromatic hydrocarbon group represented by Ar0 is preferably 6 to 22, more preferably 6 to 18, and still more preferably 6 to 10. As the above-described aromatic hydrocarbon group, a phenylene group is preferable.

L⁰ has the same meaning as A described above, and a suitable aspect thereof is also the same.

Examples of the diamine include 1,2-diaminoethane, 1,2-diaminopropane, 1,3-diaminopropane, 1,4-diaminobutane, 1,6-diaminohexane; 1,2- or 1,3-diaminocyclopentane, 1,2-, 1,3-, or 1,4-diaminocyclohexane, 1,2-, 1,3-, or 1,4-bis(aminomethyl)cyclohexane, bis(4-aminocyclohexyl)methane, bis(3-aminocyclohexyl)methane, 4,4′-diamino-3,3′-dimethylcyclohexylmethane, or isophorone diamine; m- or p-phenylenediamine, diaminotoluene, 4,4′- or 3,3′-diaminobiphenyl, 4,4′-diaminodiphenyl ether, 3,3′-diaminodiphenyl ether, 4,4′- or 3,3′-diaminodiphenylmethane, 4,4′- or 3,3′-diaminodiphenyl sulfone, 4,4′- or 3,3′-diaminodiphenyl sulfide, 4,4′- or 3,3′-diaminobenzophenone, 3,3′-dimethyl-4,4′-diaminobiphenyl, 2,2′-dimethyl-4,4′-diaminobiphenyl (4,4′-diamino-2,2′-dimethylbiphenyl), 3,3′-dimethoxy-4,4′-diaminobiphenyl, 2,2-bis(4-aminophenyl)propane, 2,2-bis(4-aminophenyl)hexafluoropropane, 2,2-bis(3-hydroxy-4-aminophenyl)propane, 2,2-bis(3-hydroxy-4-aminophenyl) hexafluoropropane, 2,2-bis(3-amino-4-hydroxyphenyl) propane, 2,2-bis(3-amino-4-hydroxyphenyl)hexafluoropropane, bis(3-amino-4-hydroxyphenyl) sulfone, bis(4-amino-3-hydroxyphenyl)sulfone, 4,4′-diamino-p-terphenyl, 4,4′-bis(4-aminophenoxy)biphenyl, bis[4-(4-aminophenoxy)phenyl]sulfone, bis [4-(3-aminophenoxy)phenyl]sulfone, bis[4-(2-aminophenoxy)phenyl]sulfone, 1,4-bis(4-aminophenoxy)benzene, 9,10-bis(4-aminophenyl)anthracene, 3,3′-dimethyl-4,4′-diaminodiphenyl sulfone, 1,3-bis(4-aminophenoxy)benzene, 1,3-bis(3-aminophenoxy)benzene, 1,3-bis(4-aminophenyl)benzene, 3,3′-diethyl-4,4′-3,3′-dimethyl-4,4′-diaminodiphenylmethane, 4,4′-diaminodiphenylmethane, diaminooctafluorobiphenyl, 2,2-bis [4-(4-aminophenoxy)phenyl]propane, 2,2-bis[4-(4-aminophenoxy)phenyl]hexafluoropropane, 9,9-bis(4-aminophenyl)-10-hydroanthracene, 3,3′,4,4′-tetraaminobiphenyl, 3,3′,4,4′-tetraaminodiphenyl ether, 1,4-diaminoanthraquinone, 1,5-diaminoanthraquinone, 3,3′-dihydroxy-4,4′-diaminobiphenyl, 9,9′-bis(4-aminophenyl)fluorene, 4,4′-dimethyl-3,3′-diaminodiphenyl sulfone, 3,3′,5,5′-tetramethyl-4,4′-diaminodiphenylmethane, 2-(3′,5′-diaminobenzoyloxy)ethyl methacrylate, 2,4- or 2,5-diaminocumene, 2,5-dimethyl-p-phenylenediamine, acetoguanamine, 2,3,5,6-tetramethyl-p-phenylenediamine, 2,4,6-trimethyl-m-phenylenediamine, bis(3-aminopropyl)tetramethyldisiloxane, 2,7-diaminofluorene, 2,5-diaminopyridine, 1,2-bis(4-aminophenyl)ethane, diaminobenzanilide, esters of diaminobenzoic acid, 1,5-diaminonaphthalene, diaminobenzotrifluoride, 1,3-bis(4-aminophenyl) hexafluoropropane, 1,4-bis(4-aminophenyl)octafluorobutane, 1,5-bis(4-aminophenyl)decafluoropentane, 1,7-bis(4-aminophenyl)tetradecafluoroheptane, 2,2-bis[4-(3-aminophenoxy)phenyl]hexafluoropropane, 2,2-bis[4-(2-aminophenoxy)phenyl]hexafluoropropane, 2,2-bis[4-(4-aminophenoxy)-3,5-dimethylphenyl]hexafluoropropane, 2,2-bis[4-(4-aminophenoxy)-3,5-bis(trifluoromethyl)phenyl]hexafluoropropane, p-bis(4-amino-2-trifluoromethylphenoxy)benzene, 4,4′-bis(4-amino-2-trifluoromethylphenoxy)biphenyl, 4,4′-bis(4-amino-3-trifluoromethylphenoxy)biphenyl, 4,4′-bis(4-amino-2-trifluoromethylphenoxy)diphenyl sulfone, 4,4′-bis(3-amino-5-trifluoromethylphenoxy)diphenyl sulfone, 2,2-bis[4-(4-amino-3-trifluoromethylphenoxy)diphenyl]hexafluoropropane, 3,3′,5,5′-tetramethyl-4,4′-diaminobiphenyl, 4,4′-diamino-2,2′-bis(trifluoromethyl)biphenyl, 2,2+,5,5′,6,6′- hexafluorotolidine, and 4,4′-diaminoquaterphenyl.

In addition, examples of the diamine also include a compound represented by any of Formulae (DA-1) to (DA-18).

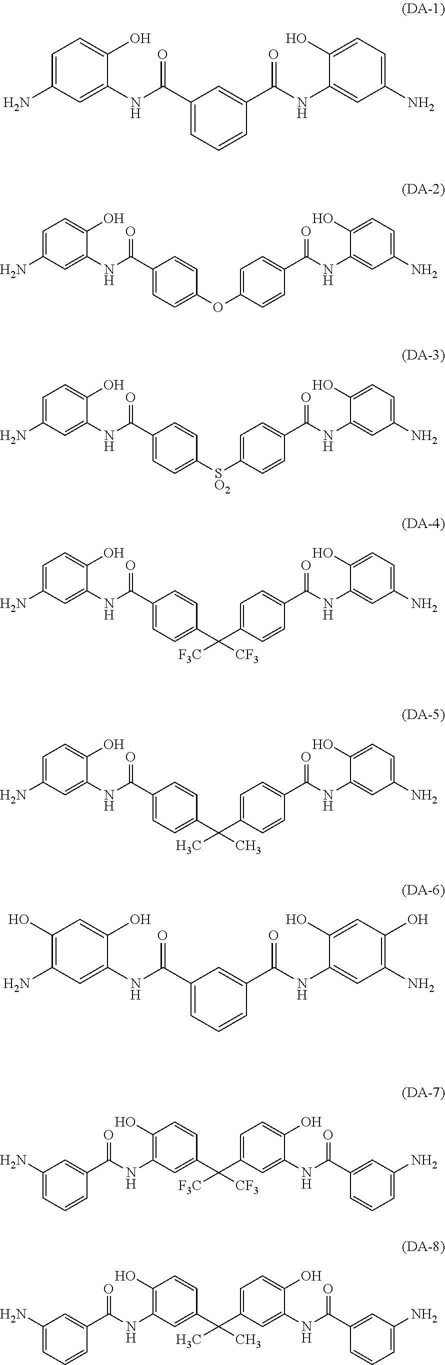

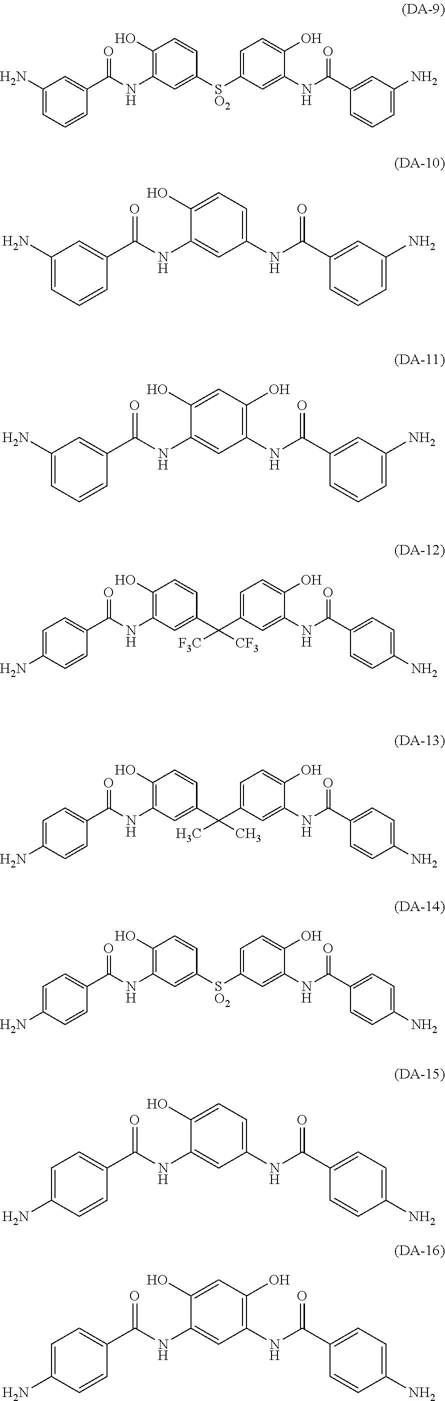

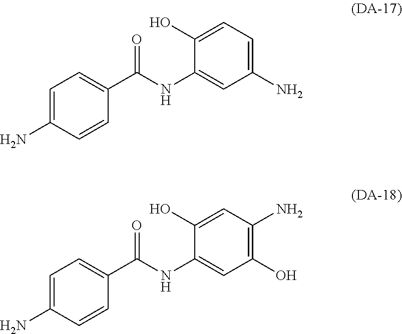 [SMILES: Nc1ccc(C(=O)Nc2cc(N)ccc2O)cc1 ; Nc1ccc(C(=O)Nc2cc(O)c(N)cc2O)cc1]

In addition, examples of the diamine also include a diamine having two or more alkylene glycol units in the main chain; and as the diamine having two or more alkylene glycol units in the main chain, a diamine including two or more of one or both of an ethylene glycol chain and a propylene glycol chain in one molecule is preferable. In addition, a diamine not including an aromatic ring is also preferable.

Examples of the above-described diamine include JEFFAMINE (registered trademark) series (KH-511, ED-600, ED-900, ED-2003, EDR-148, EDR-176, D-200, D-400, D-2000, and D-4000, manufactured by HUNTSMAN Corporation); 1-(2-(2-(2-aminopropoxy)ethoxy)propoxy)propane-2-amine, and 1-(1-(1-(2-aminopropoxy)propane-2-yl)oxy)propane-2-amine.

In Formula (1), R¹¹³ and R¹¹⁴ each independently represents a hydrogen atom or a monovalent organic group.

From the viewpoint that the acid value can be adjusted and the effect of the present invention is more excellent, it is preferable that R¹¹³ and R¹¹⁴ represent a monovalent organic group.

Examples of the monovalent organic group represented by R¹¹³ or R¹¹⁴ include an aliphatic group, an aromatic ring group, and an arylalkyl group. Examples thereof include an aromatic ring group having 6 to 20 carbon atoms and an arylalkyl group having 7 to 25 carbon atoms. More specific examples thereof include a phenyl group and a benzyl group. The monovalent organic group represented by R¹¹³ or R¹¹⁴ may have an acid group as a substituent, but from the viewpoint that the acid value of the polyimide precursor and the dissolution rate described later can be adjusted and the effect of the present invention is more excellent, it is also preferable that the monovalent organic group does not have an acid group. The acid group is as described above.

The above-described monovalent organic group may be a monovalent organic group X described later.

Examples of the monovalent organic group represented by R¹¹³ or R¹¹⁴ also include a leaving group that leaves by the action of an acid.

It is preferable that at least one of R¹¹³ or R¹¹⁴ represents a group having a polymerizable group, and it is more preferable that both R¹¹³ and R¹¹⁴ represent a group having a polymerizable group. Examples of the polymerizable group include the groups exemplified as the polymerizable group which may be included in the above-described resin.

R¹¹³ and R¹¹⁴ are each preferably a group having an ethylenically unsaturated double bond, and more preferably a vinyl group, an allyl group, a (meth)acryloyl group, or a group represented by Formula (III).

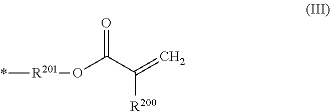

In Formula (III), R²⁰⁰ represents a hydrogen atom or a methyl group. R²⁰¹ represents an alkylene group having 2 to 12 carbon atoms, —CH₂CH(OH)CH₂—, or a (poly)oxyalkylene group having 4 to 30 carbon atoms, and * represents a bonding position.

In Formula (III), R²⁰⁰ represents a hydrogen atom or a methyl group.

R²⁰⁰ is preferably a methyl group.

In Formula (III), R²⁰¹ represents an alkylene group having 2 to 12 carbon atoms, —CH₂CH (OH) CH₂—, or a (poly) oxyalkylene group having 4 to 30 carbon atoms.

The number of carbon atoms in the alkylene group constituting the above-described (poly) oxyalkylene group is preferably 1 to 12, more preferably 1 to 6, and still more preferably 1 to 3. The repetition number of the oxyalkylene constituting the above-described (poly)oxyalkylene group is preferably 1 to 12, more preferably 1 to 6, and still more preferably 1 to 3.

The (poly)oxyalkylene group is a concept including both an oxyalkylene group and a polyoxyalkylene group.

Examples of R²⁰¹ include an ethylene group, a propylene group, a trimethylene group, a tetramethylene group, a 1,2-butanediyl group, a 1,3-butanediyl group, a pentamethylene group, a hexamethylene group, an octamethylene group, a dodecamethylene group, and —CH₂CH(OH)CH₂—; and an ethylene group, a propylene group, a trimethylene group, or —CH₂CH(OH)CH₂— is preferable, and an ethylene group is more preferable. In Formula (1), R¹¹⁵ represents a tetravalent organic group.

As the tetravalent organic group, a tetravalent organic group having an aromatic ring is preferable; and a group represented by Formula (5) or a group represented by Formula (6) is more preferable.

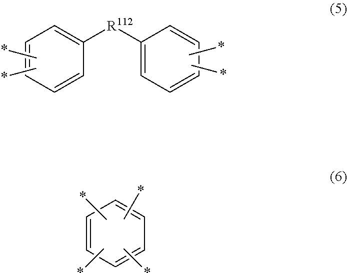

In Formula (5), R¹¹² represents a divalent aliphatic hydrocarbon group having 1 to 10 carbon atoms, which may have a fluorine atom, —O—, —CO—, —S—, —SO₂—, —NHCO—, a group formed by a combination of these groups, or a single bond, and * represents a bonding position.

In Formula (6), * represents a bonding position.

In Formula (5), R¹¹² has the same meaning as A described above, and a suitable aspect thereof is also the same.

Examples of the tetravalent organic group also include a tetracarboxylic acid residue remaining after removing an acid dianhydride group from a tetracarboxylic acid dianhydride. The tetracarboxylic acid dianhydride is preferably a compound represented by Formula (7).

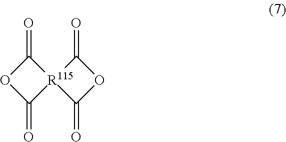

In Formula (7), R¹¹⁵ represents a tetravalent organic group.

R¹¹⁵ in Formula (7) has the same meaning as R¹¹⁵ in Formula (1), and a suitable aspect thereof is also the same.

Examples of the tetracarboxylic acid dianhydride include pyromellitic acid, pyromellitic acid dianhydride (PMDA), 3,3′,4,4′-biphenyltetracarboxylic acid dianhydride, 3,3′,4,4′-diphenylsulfide tetracarboxylic acid dianhydride, 3,3′,4,4′-diphenylsulfone tetracarboxylic acid dianhydride, 3,3′,4,4′-benzophenone tetracarboxylic acid dianhydride, 3,3′,4,4′-diphenylmethane tetracarboxylic acid dianhydride, 2,2′,3,3′-diphenylmethane tetracarboxylic acid dianhydride, 2,3,3′,4′-biphenyltetracarboxylic acid dianhydride, 2,3,3′,4′-benzophenone tetracarboxylic acid dianhydride, 4,4′-oxydiphthalic acid dianhydride, 2,3,6,7-naphthalene tetracarboxylic acid dianhydride, 1,4,5,7-naphthalene tetracarboxylic acid dianhydride, 2,2-bis(3,4-dicarboxyphenyl)propane dianhydride, 2,2-bis(2,3-dicarboxyphenyl)propane dianhydride, 2,2-bis(3,4-dicarboxyphenyl)hexafluoropropane dianhydride, 1,3-diphenylhexafluoropropane-3,3,4,4-tetracarboxylic acid dianhydride, 1,4,5,6-naphthalene tetracarboxylic acid dianhydride, 2,2′,3,3′-diphenyl tetracarboxylic acid dianhydride, 3,4,9,10-perylene tetracarboxylic acid dianhydride, 1,2,4,5-naphthalene tetracarboxylic acid dianhydride, 1,4,5,8-naphthalene tetracarboxylic acid dianhydride, 1,8,9,10-phenanthrene tetracarboxylic acid dianhydride, 1,1-bis(2,3-dicarboxyphenyl)ethane dianhydride, 1,1-bis(3,4-dicarboxyphenyl)ethane dianhydride, 1,2,3,4-benzene tetracarboxylic acid dianhydride, alkyl derivatives thereof, having 1 to 6 carbon atoms, and alkoxy derivatives thereof, having 1 to 6 carbon atoms.

Examples of the tetracarboxylic acid dianhydride also include a compound represented by any of Formulae (DAA-1) to (DAA-5).

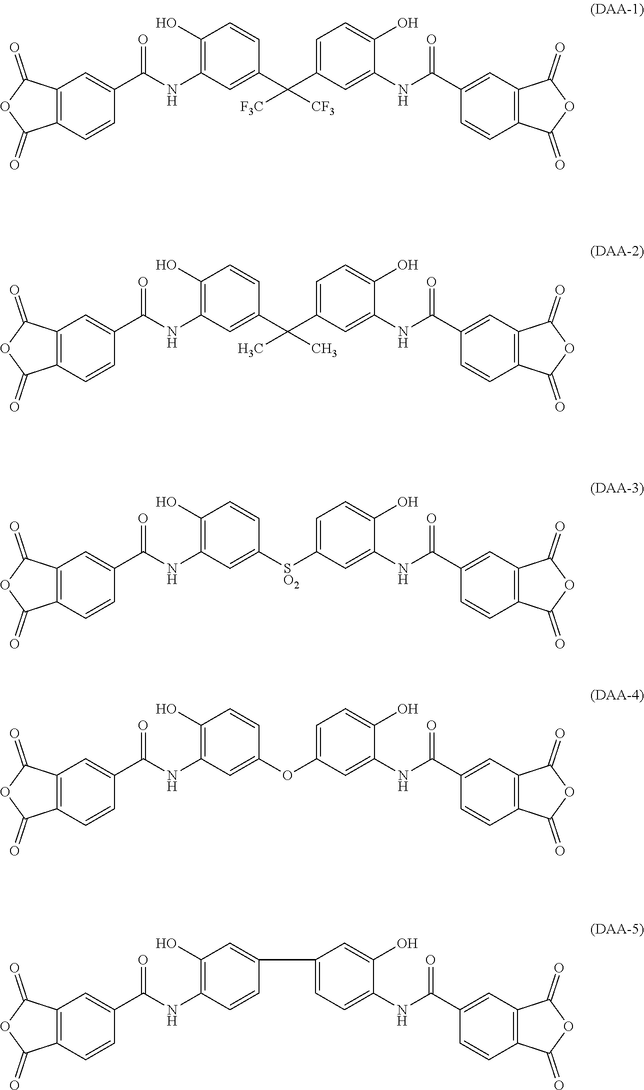 [SMILES: O=C(Nc1cc(C(c2ccc(O)c(NC(=O)c3ccc4c(c3)C(=O)OC4=O)c2)(C(F)(F)F)C(F)(F)F)ccc1O)c1ccc2c(c1)C(=O)OC2=O ; CC(C)(c1ccc(O)c(NC(=O)c2ccc3c(c2)C(=O)OC3=O)c1)c1ccc(O)c(NC(=O)c2ccc3c(c2)C(=O)OC3=O)c1 ; O=C(Nc1cc(S(=O)(=O)c2ccc(O)c(NC(=O)c3ccc4c(c3)C(=O)OC4=O)c2)ccc1O)c1ccc2c(c1)C(=O)OC2=O ; O=C(Nc1cc(Oc2ccc(O)c(NC(=O)c3ccc4c(c3)C(=O)OC4=O)c2)ccc1O)c1ccc2c(c1)C(=O)OC2=O ; O=C(Nc1ccc(-c2ccc(NC(=O)c3ccc4c(c3)C(=O)OC4=O)c(O)c2)cc1O)c1ccc2c(c1)C(=O)OC2=O]

### Monovalent Organic Group X

The monovalent organic group X is preferably an alkyl group which may have a substituent or an aromatic ring group which may have a substituent; and more preferably an alkyl group which may have an aromatic ring group.

The above-described alkyl group may be linear, branched, or cyclic. The cyclic ring may be either a monocyclic ring or a polycyclic ring.

The number of carbon atoms in the linear or branched alkyl group is preferably 1 to 30. The number of carbon atoms in the cyclic alkyl group (cycloalkyl group) is preferably 3 to 30.

Examples of the above-described alkyl group include linear or branched alkyl groups such as a methyl group, an ethyl group, a propyl group, a butyl group, a pentyl group, a hexyl group, a heptyl group, an octyl group, a nonyl group, a decyl group, a dodecyl group, a tetradecyl group, an octadecyl group, an isopropyl group, an isobutyl group, a sec-butyl group, a t-butyl group, a 1-ethylpentyl group, and a 2-ethylhexyl group; monocyclic cycloalkyl groups such as a cyclopropyl group, a cyclobutyl group, a cyclopentyl group, a cyclohexyl group, a cycloheptyl group, and a cyclooctyl group; and polycyclic cycloalkyl groups such as an adamantyl group, a norbornyl group, a bornyl group, a camphanyl group, a decahydronaphthyl group, a tricyclodecanyl group, a tetracyclodecanyl group, a camphoroyl group, a dicyclohexyl group, and a pyrenyl group.

As the substituent which can be included in the above-described alkyl group, an aromatic ring group described below is preferable.

The aromatic ring group may be any one of an aromatic hydrocarbon ring group or an aromatic heterocyclic group. In addition, the aromatic ring group may be monocyclic or polycyclic.

Examples of a ring constituting the aromatic ring group include aromatic hydrocarbon rings such as a benzene ring, a naphthalene ring, a biphenyl ring, a fluorene ring, a pentalene ring, an indene ring, an azulene ring, a heptalene ring, an indacene ring, a perylene ring, a pentacene ring, an acenaphthene ring, a phenanthrene ring, an anthracene ring, a naphthacene ring, a chrysene ring, and a triphenylene ring; and aromatic heterocyclic groups such as a pyrrole ring, a furan ring, a thiophene ring, an imidazole ring, an oxazole ring, a thiazole ring, a pyridine ring, a pyrazine ring, a pyrimidine ring, a pyridazine ring, an indridine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, and a phenazine ring.

As the substituent which can be included in the above-described aromatic ring group, the above-described alkyl group is preferable.

As the repeating unit represented by Formula (1), a repeating unit represented by Formula (1-A) or a repeating unit represented by Formula (1-B) is preferable.

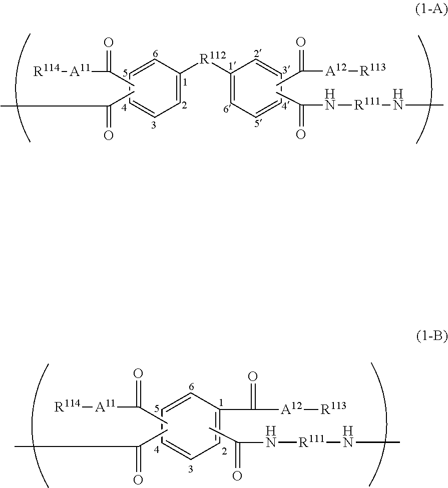

In Formula (1-A) and Formula (1-B), A¹¹, A¹², R¹¹¹, R¹¹³, and R¹¹⁴ each have the same meaning as A1, A2, R¹¹¹, R¹¹³, and R¹¹⁴ in Formula (1), and suitable aspects thereof are also the same.

In Formula (1-A), R¹¹² has the same meaning as R¹¹² in Formula (5), and a suitable aspect thereof is also the same.

In Formula (1-A), a bonding position of the carbonyl group to the benzene ring is preferably 4, 5, 3′, or 4′ in Formula (1-A).

In Formula (1-B), a bonding position of the carbonyl group to the benzene ring is preferably 1, 2, 4, or 5 in Formula (1-B).

From the viewpoint that the effect of the present invention is more excellent, the content of the repeating unit represented by Formula (1) is preferably 50% by mole or more, more preferably 70% by mole or more, and still more preferably 90% by mole or more with respect to all repeating units of the polyimide precursor. The upper limit thereof is preferably 100 mol % or less.

From the viewpoint that the effect of the present invention is more excellent, the content of the repeating unit represented by Formula (1) having an acid group is preferably 70% by mole or less, more preferably 40% by mole or less, still more preferably 15% by mole or less, and particularly preferably 5% by mole or less with respect to all repeating units of the polyimide precursor. The lower limit thereof is preferably 0% by mole.

The polyimide precursor may include other repeating units in addition to the repeating unit represented by Formula (1).

It is also preferable that the polyimide precursor has a fluorine atom.

A content of the fluorine atom in the polyimide precursor is preferably 10% by mass or more and more preferably 20% by mass or more with respect to the total mass of the polyimide precursor. The upper limit thereof is preferably 50% by mass or less.

From the viewpoint of improving adhesiveness with the substrate, the polyimide precursor may be obtained by copolymerization with an aliphatic group having a siloxane structure and the repeating unit represented by Formula (1). Examples of the aliphatic group having a siloxane structure include bis(3-aminopropyl) tetramethyldisiloxane and bis(paraminophenyl) octamethylpentasiloxane.

The weight-average molecular weight (Mw) of the polyimide precursor is preferably 2,000 to 500,000, more preferably 5,000 to 100,000, and still more preferably 10,000 to 50,000.

The number-average molecular weight (Mn) of the polyimide precursor is preferably 800 to 250,000, more preferably 2,000 to 50,000, and still more preferably 4,000 to 25,000.

A polydispersity (Mw/Mn) of the polyimide precursor is preferably 1.5 to 3.5, and more preferably 2.0 to 3.0.

### Acid Value

The acid value of the polyimide precursor is 75 mgKOH/g or less, and from the viewpoint that the effect of the present invention is more excellent, it is preferably 60 mgKOH/g or less, more preferably 30 mgKOH/g or less, still more preferably 10 mgKOH/g or less, and particularly preferably 5 mgKOH/g or less. The lower limit of the acid value of the polyimide precursor is not particularly limited, but is preferably 0 mgKOH/g.

The acid value (mgKOH/g) is the number of mg of potassium hydroxide (KOH) required to neutralize 1 g of the sample. The acid value is determined by a method based on JIS K0070.

Examples of a method of adjusting the acid value of the polyimide precursor include a method of adjusting the content of the acid group contained in the polyimide precursor. More specific examples thereof include a method of synthesizing a polyimide precursor using a raw material having no acid group or a raw material having an acid group, and a method of reacting an acid group with a protective group. Examples of the protective group include a monovalent organic group represented by R¹¹³ or R¹¹⁴.

### Dissolution Rate

From the viewpoint that the effect of the present invention is more excellent, the dissolution rate of the polyimide precursor in 200 mL of an aqueous solution of 2.38% by mass tetramethylammonium hydroxide (TMAH 2.38 wt % aq) at 23° C. is preferably 100 mg/min or less, more preferably 50 mg/min or less, and still more preferably 10 mg/min or less. The lower limit of the above-described dissolution rate is not particularly limited, but is preferably 1 μg/min or more, more preferably 3 μg/min or more, and still more preferably 5 μg/min or more.

The dissolution rate in 200 mL of the above-described TMAH 2.38 wt % aq can be measured, for example, by the following method. The polyimide precursor is dissolved in N-methyl-2-pyrrolidone (NMP) to 30% by mass, applied onto a glass substrate such that the film thickness after drying is 100 μm, and heated on a hot plate at 100° C. until the residual amount of NMP is less than 1% to remove NMP. The obtained film of the polyimide precursor is immersed in 200 mL of TMAH 2.38 wt % aq at 23° C. for 1 minute. The immersed film is dried, the weight of the film of the polyimide precursor before and after the immersion is measured, and the difference is divided by the immersion time to calculate the dissolution rate (mg/min). The weight of the film of the polyimide precursor can be measured using an electronic balance (for example, manufactured by METTLER TOLEDO).

The above-described dissolution rate can be adjusted, for example, by adjusting the structure, acid value, molecular weight, and the like of the polyimide precursor.

From the viewpoint that the effect of the present invention is more excellent, the content of the polyimide precursor is preferably 5.0% to 95.0% by mass, more preferably 10.0% to 90.0% by mass, and still more preferably 15.0% to 73.0% by mass with respect to the total solid content of the photosensitive composition.

### Polymerizable Compound

The photosensitive composition contains a polymerizable compound different from the polyimide precursor.

The polymerizable compound is a compound having one or more polymerizable groups in the molecule.

Examples of the polymerizable group include known polymerizable groups such as a radically polymerizable group, an epoxy group, an oxetanyl group, a methylol group, and an alkoxymethyl group, and a radically polymerizable group is preferable.

The radically polymerizable group is preferably a group having an ethylenically unsaturated double bond. Examples of the group having an ethylenically unsaturated double bond include a vinyl group, a styryl group, a (meth)acryloyl group, a (meth)acrylamide group, an allyl group, and a vinyl ether group, and a vinyl group, a styryl group, or a (meth)acryloyl group is preferable, and a (meth)acryloyl group is more preferable. The polymerizable compound is preferably a low-molecular-weight compound.

The weight-average molecular weight (Mw) of the polymerizable compound is preferably 2,000 or less, more preferably 1,500 or less, and still more preferably 1,000 or less. The lower limit thereof is not particularly limited, but is preferably 100 or more and more preferably 150 or more.

The number of polymerizable groups included in the polymerizable compound is preferably 1 or 2 or more, more preferably 2 to 10, and still more preferably 2 to 6.

Examples of the polymerizable compound include a polymerizable compound having one polymerizable group in one molecule (hereinafter, also referred to as “monofunctional polymerizable compound”); a polymerizable compound having two polymerizable groups in one molecule (hereinafter, also referred to as “bifunctional polymerizable compound”); and a polymerizable compound having three or more polymerizable groups in one molecule (hereinafter, also referred to as “tri- or higher functional polymerizable compound”). As the polymerizable compound, a bifunctional polymerizable compound or a tri- or higher functional polymerizable compound is preferable.

The photosensitive composition contains a compound having two or more polymerizable groups as the polymerizable compound. That is, the polymerizable compound includes at least one selected from the group consisting of a difunctional polymerizable compound and a trifunctional or higher functional polymerizable compound.

The polymerizable compound may further include a monofunctional polymerizable compound.

Examples of the difunctional polymerizable compound include polyethylene glycol (meth)acrylate, tricyclodecane dimethanol di(meth)acrylate, 1,9-nonanediol di(meth)acrylate, ethoxylated bisphenol A di(meth)acrylate, and 1,6-hexanediol di(meth)acrylate.

Examples of a commercially available product of the bifunctional polymerizable compound include diethylene glycol dimethacrylate (2G, manufactured by Shin-Nakamura Chemical Co., Ltd.), triethylene glycol dimethacrylate (3G, manufactured by Shin-Nakamura Chemical Co., Ltd.), polyethylene glycol #200 dimethacrylate (4G, manufactured by Shin-Nakamura Chemical Co., Ltd.), tricyclodecane dimethanol diacrylate (A-DCP, manufactured by Shin-Nakamura Chemical Co., Ltd.), tricyclodecane dimethanol methacrylate (DCP, manufactured by Shin-Nakamura Chemical Co., Ltd.), 1,9-nonandiol diacrylate (A-NOD-N, manufactured by Shin-Nakamura Chemical Co., Ltd.), 1,6-hexanediol diacrylate (A-HD-N, manufactured by Shin-Nakamura Chemical Co., Ltd.), SR205NS (manufactured by Sartomer Inc.), and SR209 (manufactured by Sartomer Inc.).

Examples of the tri- or higher functional polymerizable compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

The “(tri/tetra/penta/hexa) (meth)acrylate” has a concept including tri(meth)acrylate, tetra (meth)acrylate, penta(meth)acrylate, and hexa(meth)acrylate, and the “(tri/tetra) (meth)acrylate” has a concept including tri(meth)acrylate and tetra(meth)acrylate.

Examples of the polymerizable compound include a caprolactone-modified compound of a (meth)acrylate compound (KAYARAD (registered trademark) DPCA-20 and the like manufactured by Nippon Kayaku Co., Ltd.; and A-9300-1CL and the like manufactured by Shin-Nakamura Chemical Co., Ltd.), an alkylene oxide-modified compound of a (meth)acrylate compound (KAYARAD RP-1040 and the like manufactured by Nippon Kayaku Co., Ltd.; ATM-35E, A-9300, and the like manufactured by Shin-Nakamura Chemical Co., Ltd.; and EBECRYL (registered trademark) 135 manufactured by Daicel-Allnex Ltd.), and ethoxylated glycerin triacrylate (A-GLY-9E and the like manufactured by Shin-Nakamura Chemical Co., Ltd.).

Examples of the polymerizable compound also include urethane (meth)acrylate (preferably, tri- or higher functional urethane (meth)acrylate).

The number of polymerizable groups included in the urethane (meth)acrylate is preferably 6 or more, and more preferably 8 or more. The upper limit thereof is 20 or less.

Examples of the tri- or higher functional urethane (meth)acrylate include 8UX-015A (manufactured by Taisei Fine Chemical Co., Ltd.); UA-32P, U-15HA, and UA-1100H (all manufactured by Shin-Nakamura Chemical Co., Ltd.); AH-600 (manufactured by KYOEISHA CHEMICAL Co., LTD.); and UA-306H, UA-306T, UA-306I, UA-510H, and UX-5000 (all manufactured by Nippon Kayaku Co., Ltd.).

The polymerizable compound may be used alone, or two or more types thereof may be used in combination.

A content of the polymerizable compound is preferably 3.0% to 50.0% by mass, more preferably 5.0% to 40.0% by mass, and still more preferably 15.0% to 35.0% by mass with respect to the total solid content of the photosensitive composition.

From the viewpoint that the effect of the present invention and the level difference conformability are more excellent, a mass ratio of the content of the polymerizable compound to the content of the polyimide precursor is preferably 0.10 or more, more preferably 0.20 or more, and still more preferably 0.22 or more. The upper limit of the above-described mass ratio is not particularly limited, but from the viewpoint that the migration resistance is more excellent, it is preferably 1.00 or less, more preferably 0.75 or less, and still more preferably 0.60 or less.

The above-described level difference conformability is intended to be the level difference conformability of the photosensitive composition layer in a case where the transfer film described later is transferred onto a pattern having a level difference.

### Specific Compound

The photosensitive composition contains a specific compound which is a compound represented by Formula (1).

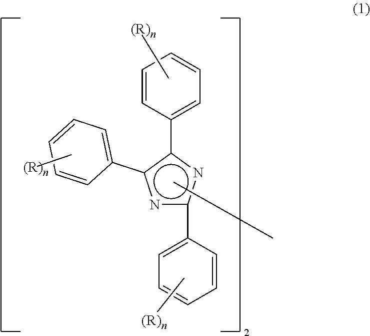

In Formula (1), R's each independently represents a substituent.

The substituent represented by R is not particularly limited, and examples thereof include a halogen atom, an alkyl group, an alkoxy group, an alkynyl group, an alkenyl group, an aryl group, an aryloxy group, a formyl group, an acyl group, an alkoxycarbonyl group, an acyloxy group, a hydroxy group, an amino group, a carboxy group, a nitro group, and a cyano group; and from the viewpoint of more excellent effects of the present invention, a halogen atom, an alkyl group, or an alkoxy group is preferable, and an alkoxy group is more preferable.

Examples of the above-described halogen atom include a fluorine atom, a chlorine atom, a bromine atom, and an iodine atom, and a chlorine atom is preferable.

The number of carbon atoms in the above-described alkyl group and alkoxy group is preferably 1 to 10, more preferably 1 to 6, and still more preferably 1 to 3.

The number of carbon atoms in the alkynyl group, the alkenyl group, the acyl group, the alkoxycarbonyl group, and the acyloxy group described above is preferably 2 to 10, more preferably 2 to 6, and still more preferably 2 to 4.

Each group represented as the above-described substituent may further have a substituent as much as possible. As such a substituent, a halogen atom, a hydroxy group, an alkyl group having 1 to 4 carbon atoms, or an alkoxy group having 1 to 4 carbon atoms is preferable, and a halogen atom or a hydroxy group is more preferable.

In a case where a plurality of R's are present, the plurality of R's may be the same or different from each other.

In Formula (1), n's each independently represents an integer of 0 to 5, preferably an integer of 0 to 3, and more preferably an integer of 0 to 2.

The total of n's is an integer of 0 or more, and is preferably an integer of 1 or more, more preferably an integer of 0 to 10, and still more preferably an integer of 0 to 5.

In a case where n is 1 or more, it is preferable that R is located at at least one of an ortho position or a para position with respect to a bonding position to a biimidazole skeleton.

Among these, the compound represented by Formula (1) is preferably a compound represented by Formula (1-1) or a compound represented by Formula (1-2), and more preferably a compound represented by Formula (1-1).

In Formulae (1-1) and (1-2), the definition and suitable aspects of R and n are the same as those in Formula (1).

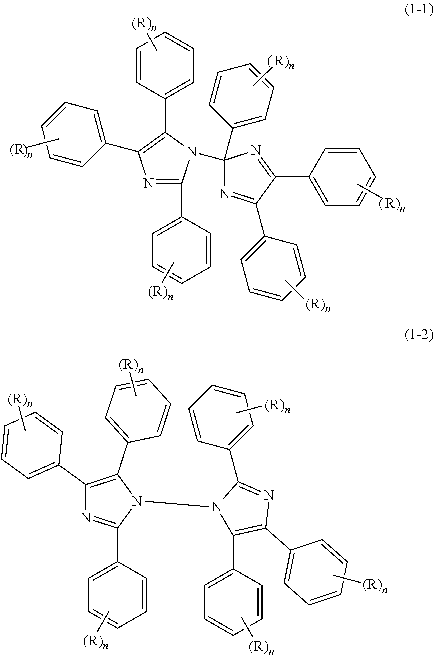

Examples of the compound represented by Formula (1) include 2,2′-bis(2-chlorophenyl)-4,4′,5,5′-tetraphenyl-1,1′-biimidazole, 2,2′,4-tris(2-chlorophenyl)-5-(3,4-dimethoxyphenyl)-4′,5′-diphenyl-1,1′-biimidazole, 2,2′-bis(2-methoxyphenyl)-4,4′,5,5′-tetraphenyl-1,1′-biimidazole, 2-(o-chlorophenyl)-4,5-diphenylbiimidazole, 2-(o-chlorophenyl)-4,5-bis-(m-methoxyphenyl) biimidazole, 2-(p-methoxyphenyl)-4,5-diphenylbiimidazole, 2,2′,5-tris-(o-chlorophenyl)-4-(3,4-dimethoxyphenyl)-4′,5′-diphenylbiimidazole, 2,4-bis-(o-chlorophenyl)-5-(3,4-dimethoxyphenyl)-diphenylbiimidazole, 2,4,5-tris-(o-chlorophenyl)-diphenylbiimidazole, 2-(o-chlorophenyl)-bis-4,5-(3,4-dimethoxyphenyl)-biimidazole, 2,2′-bis-(2-fluorophenyl)-4,4′,5,5′-tetrakis-(3-2,2′-bis-(2,3-difluoromethylphenyl)-4,4′,5,5′-tetrakis-(3-methoxyphenyl)-biimidazole, 2,2′-bis-(2,4-difluorophenyl)-4,4′,5,5′-tetrakis-(3-methoxyphenyl)-biimidazole, 2,2′-bis-(2,5-difluorophenyl)-4,4′,5,5′-tetrakis-(3-methoxyphenyl)-biimidazole, 2,2′-bis-(2,6-difluorophenyl)-4,4′,5,5′-tetrakis-(3-methoxyphenyl)-biimidazole, 2,2′-bis-(2,3,4-trifluorophenyl)-4,4′,5,5′-tetrakis-(3-methoxyphenyl)-biimidazole, 2,2′-bis-(2,3,5-trifluorophenyl)-4,4′,5,5′-tetrakis-(3-methoxyphenyl)-biimidazole, 2,2′-bis-(2,3,6-trifluorophenyl)-4,4′,5,5′-tetrakis-(3-methoxyphenyl)-biimidazole, 2,2′-bis-(2,4,5-trifluorophenyl)-4,4′,5,5′-tetrakis-(3-methoxyphenyl)-biimidazole, 2,2′-bis-(2,4,6-trifluorophenyl)-4,4′,5,5′-tetrakis-(3-methoxyphenyl)-biimidazole, 2,2′-bis-(2,3,4,5-tetrafluorophenyl)-4,4′,5,5′-tetrakis-(3-methoxyphenyl)-biimidazole, 2,2′-bis-(2,3,4,6-tetrafluorophenyl)-4,4′,5,5′-tetrakis-(3-methoxyphenyl)-biimidazole, 2,2′-bis-(2,3,4,5,6-pentafluorophenyl)-4,4′,5,5′-tetrakis-(3-methoxyphenyl)-biimidazole, 2,2′,4-tris(2-fluorophenyl)-5-(3,4-dimethoxyphenyl)-4′,5′-methoxyphenyl)-biimidazole, 2,2′-bis(2,4-dichlorophenyl)-4,4′,5,5′-tetraphenyl 1,1′-diphenyl-1,1′-biimidazole, biimidazole, and 2,2′-bis(2-methoxyphenyl)-4,4′,5,5′-tetraphenyl 1,1′-biimidazole; and 2,2′-bis(2-chlorophenyl)-4,4′,5,5′-tetraphenyl-1,1′-biimidazole, 2,2′,4-tris(2-chlorophenyl)-5-(3,4 -dimethoxyphenyl)-4′,5′-diphenyl-1,1′-biimidazole, or 2,2′-bis(2-methoxyphenyl)-4,4′,5,5′-tetraphenyl-1,1′-biimidazole is preferable.

The specific compound may be used alone or in combination of two or more thereof.

A content of the specific compound is preferably 0.1% to 20.0% by mass and more preferably 1.0% to 10.0% by mass with respect to the total solid content of the photosensitive composition.

### Chain Transfer Agent

From the viewpoint that the resolution is more excellent, the photosensitive composition preferably contains a chain transfer agent.

As the chain transfer agent, known compounds can be used, and examples thereof include an N-phenylglycine compound, a phenoxyacetic acid compound, a thiol compound, a disulfide compound, a thiophenoxy compound, a halogenated hydrocarbon, and a secondary alcohol; and an N-phenylglycine compound is preferable.

Examples of the above-described N-phenylglycine compound include N-phenylglycine and a derivative thereof, and a compound represented by Formula (II) is preferable.

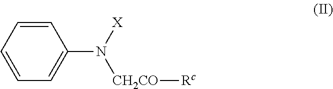

In Formula (II), X represents a hydrogen atom or a monovalent organic group.

As the above-described monovalent organic group, a hydrocarbon group which may have a substituent or a carboxy group is preferable.

The number of carbon atoms in the above-described hydrocarbon group which may have a substituent is preferably 1 to 10, and more preferably 2 to 9.

Examples of the above-described hydrocarbon group include an alkyl group, a phenyl group, and a benzyl group.

Examples of the substituent which may be included in the above-described hydrocarbon group include a carboxy group, an amino group, an alkylamino group, and an anilinocarbonyl group.

Examples of the above-described monovalent organic group include an alkyl group having 1 to 10 carbon atoms, a carboxyalkyl group having 2 to 9 carbon atoms, a carboxyphenyl group, a carboxybenzyl group, an anilinocarbonylalkyl group having 2 to 9 carbon atoms, an anilinocarbonylphenyl group, and an anilinocarbonylbenzyl group.

In Formula (II), R^{c} represents a hydroxy group, an alkoxy group, or —OM⁺. M⁺ represents an alkali metal cation.

The number of carbon atoms in the above-described alkoxy group is preferably 1 to 3, and more preferably 1.

Examples of the alkali metal cation include Li⁺, Na⁺, and K⁺.

Examples of the compound represented by Formula (II) include the following compounds.

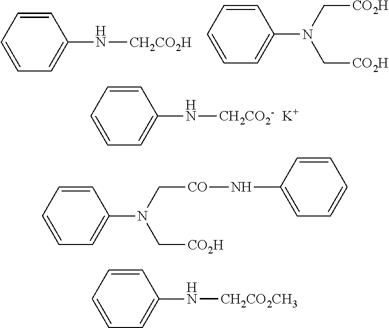

The chain transfer agent may be used alone, or two or more types thereof may be used in combination.

A content of the chain transfer agent is preferably 5.0% by mass or less and more preferably 3.0% by mass or less with respect to the total solid content of the photosensitive composition. A content of the chain transfer agent is preferably 0.01% by mass or more and more preferably 0.1% by mass or more with respect to the total solid content of the photosensitive composition.

### Polymerization Inhibitor

From the viewpoint that the resolution is more excellent, the photosensitive composition preferably contains a polymerization inhibitor.

Examples of the polymerization inhibitor include radical scavengers, and specific examples thereof include imino compounds such as phenothiazine, phenoxazine, and bis(2,2,6,6-tetramethyl-4-piperidyl) sebacate, phenolic compounds such as hydroquinone, 4 -tert-butylcatechol, 2-tert-butylhydroquinone, hydroquinone monomethyl ether, 2,6-di-tert-butyl-p-cresol, 2,2′-methylenebis(4-methyl-6-tert-butylphenol), 1,1,3-tris(2-methyl-4-hydroxy-5-tert-butylphenyl)butane, 1,3,5-trimethyl-2,4,6-tris(3,5-di-tert-butyl-4-hydroxybenzyl)benzene, and 1,3,5-tris(3′,5′-di-tert-butyl-4-hydroxybenzyl)-S-triazine-2,4,6-(1H,3H,5H)trione, quinone compounds such as methaquinone and benzoquinone, nitro compounds, and nitroso compounds; and phenothiazine, phenoxazine, or a quinone compound is preferable.

The polymerization inhibitor may be used alone, or two or more types thereof may be used in combination.

A content of the polymerization inhibitor is preferably 0.01% to 5.0% by mass and more preferably 0.1% to 3.0% by mass with respect to the total solid content of the photosensitive composition.

From the viewpoint that the effect of the present invention is more excellent, a mass ratio of the content of the polymerization inhibitor to the content of the specific compound is preferably 0.01 to 2.0 and more preferably 0.03 to 0.7.

### Sensitizer

From the viewpoint that the resolution is more excellent, the photosensitive composition preferably contains a sensitizer.

The sensitizer is not particularly limited, and examples thereof include a benzoin-based compound, a benzophenone-based compound, a xanthone-based compound, a thioxanthone-based compound, an acetophenone-based compound, an anthraquinone-based compound, a ketal-based compound, a fluorene-based compound, a naphthoquinone-based compound, and a coumarin-based compound; and a benzophenone-based compound or a thioxanthone-based compound is preferable, and a benzophenone-based compound is more preferable.

Examples of the benzophenone-based compound include benzophenone, 4,4′-bis(dimethylamino)benzophenone, 4,4′-bis(diethylamino) benzophenone (EAB-F), and 4,4′-bis(ethylmethylamino)benzophenone; and EAB-F is preferable.

Examples of the sensitizer also include compounds described in paragraphs 0113 to 0116 of JP2021-120946A, the contents of which are incorporated herein by reference.

A content of the sensitizer is preferably 5.0% by mass or less and more preferably 1.0% by mass or less with respect to the total solid content of the photosensitive composition. The content of the sensitizer is preferably 0.01% by mass or more, and more preferably 0.1% by mass or more with respect to the total solid content of the photosensitive composition.

### Filler

From the viewpoint that the migration resistance is more excellent and the linear expansion coefficient is smaller, the photosensitive composition preferably contains a filler. From the viewpoint of durability, reliability, dimensional stability in design, and the like, it is preferable that the linear expansion coefficient of the film to be formed is small.

From the viewpoint that the migration resistance is more excellent, an average particle diameter of the filler is preferably 500 nm or less, more preferably 300 nm or less, still more preferably 150 nm or less, and particularly preferably 100 nm or less. A lower limit of the average particle diameter of the filler is more than 0 nm, preferably 5 nm or more and more preferably 10 nm or more. In addition, the average particle diameter of the filler is also preferably 5 to 300 nm and more preferably 10 to 100 nm.

The average particle diameter of the filler is a value calculated by the following particle diameter measuring method.

Particle diameter measuring method: a rectangular region of 3 μm×10 μm in a cross section of the photosensitive composition layer along a normal direction of a surface of the photosensitive composition layer is observed with a scanning electron microscope, an operation of measuring a major diameter of all the fillers observed in the region is performed at five different locations on the photosensitive composition layer, and an average value of all major diameters of the fillers measured in each operation is obtained as the average particle diameter of the filler.

The above-described particle diameter measuring method will be described in detail.

The photosensitive composition is applied onto a substrate (preferably, a glass substrate) to form a photosensitive composition layer. A thickness of the photosensitive composition layer is preferably 3 μm or more. In addition, in the formation of the photosensitive composition layer, a drying treatment may be performed as necessary after applying the photosensitive composition.

A cross section of the obtained photosensitive composition layer along the normal direction of a surface (surface opposite to the substrate side) of the photosensitive composition layer is cut out, a rectangular region of 3 μm×10 μm in the cross section is observed with a scanning electron microscope, and a major diameter of all fillers observed in the region is measured. As the scanning electron microscope, S-4800 manufactured by Hitachi High-Tech Corporation is used. A magnification in the observation is 50,000 times.

The above-described operation is performed at five different positions on the photosensitive composition layer, and an average value (arithmetic mean value) of the major diameters of all the fillers measured in each operation is defined as the average particle diameter of the filler.

The above-described major diameter refers to a length of the longest line segment among line segments connecting any two points on a contour line of an outer shape of the filler in the observation image.

In addition, in a case where the fillers are aggregated in the observation image to constitute an aggregate, the major diameter of each filler constituting the aggregate is measured.

Examples of the filler include an organic filler and a mineral filler, and a mineral filler is preferable.

Examples of the filler include silicon dioxide (silica); silicate such as kaolinite, kaolin clay, calcined clay, talc, and non-doped glass; and alumina, barium sulfate, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, zirconium phosphate, cordierite, zirconium tungstate, and manganese nitride.

The filler preferably includes at least one selected from the group consisting of silicon dioxide (silica), boron nitride, barium sulfate, and silicate, and more preferably includes silicon dioxide (silica).

A shape of the filler may be a spherical shape or a non-spherical shape (for example, a crushed shape and a fibrous shape), and a spherical shape is preferable.

The filler may be subjected to a surface treatment. Examples of the surface treatment include a treatment of introducing a functional group and a treatment using a known surface treatment agent. Examples of the above-described functional group include a polymerizable group (for example, a polymerizable group included in the compound Z) and a hydrophobic group.

Examples of the surface treatment agent include a silane coupling agent, a titanate-based coupling agent, and a silazane compound.

Examples of a method of the surface treatment of the filler include a dry method of performing the surface treatment in a gas phase, and a wet method of performing the surface treatment in a liquid phase.

Examples of the filler include NHM-5N (manufactured by Tokuyama Corporation, silicon dioxide, concentration of solid contents: 100% by mass), NHM-3N (manufactured by TOKUYAMA CORPORATION, silicon dioxide, concentration of solid contents of 100% by mass), Sea Foster KE-S30 (manufactured by Nippon Shokubai Co., Ltd., silicon dioxide, concentration of solid contents of 100% by mass), YA050C-MJE (manufactured by Admatechs Co., Ltd., silicon dioxide, MEK slurry having a concentration of solid contents of 50% by mass), SFP-20M (manufactured by Denka Company Limited, silicon dioxide), PMA-ST (manufactured by Nissan n Chemical Corporation, silicon dioxide), MEK-ST-L (manufactured by Nissan Chemical Corporation, silicon dioxide), MEK-AC-5140Z (manufactured by Nissan Chemical Corporation, silicon dioxide), MEK-EC-2430Z (manufactured by NISSAN CHEMICAL CORPORATION, concentration of solid contents of 30% by mass), barium sulfate (manufactured by SOLVAY SPECIALTY CHEMICALS JAPAN, concentration of solid contents of 100% by mass), Y50SP-AM1 (manufactured by Admatechs Co., Ltd., silicon dioxide, MEK slurry having a concentration of solid contents of 50% by mass), and Y50SZ-AM1 (manufactured by Admatechs Co., Ltd., silicon dioxide, MEK slurry having a concentration of solid contents of 50% by mass).

A refractive index of the filler is preferably 0.5 to 30.0 and more preferably 1.2 to 1.8. The refractive index can be measured by the above-described method. The filler may be used alone or in combination of two or more thereof.

A content of the filler is preferably 20.0% by mass or more, more preferably 30.0% by mass or more, and still more preferably 40.0% by mass or more with respect to the total solid content of the photosensitive composition. In addition, the content of the filler is preferably 90.0% by mass or less and more preferably 80.0% by mass or less with respect to the total solid content of the photosensitive composition.

A mass ratio of the content of the filler to the content of the polyimide precursor is preferably 0.5 to 30.0 and more preferably 1.0 to 20.0.

### Thermal-Base Generator

The photosensitive composition may contain a thermal-base generator.

In a case where the photosensitive composition contains a thermal-base generator, a cyclization reaction of the polyimide precursor is promoted, and thus a polyimide is easily generated, and the migration resistance is more excellent.

As the thermal-base generator, an acidic compound or an onium salt compound (a compound consisting of a cation and an anion), which generates a base by heating, is preferable.

As the onium salt compound, an ammonium salt compound (a compound consisting of an ammonium cation and an anion), an iminium salt compound (a compound consisting of an iminium cation and an anion), a sulfonium salt compound (a compound consisting of a sulfonium cation and an anion), an iodonium salt compound (a compound consisting of an iodonium cation and an anion), or a phosphonium salt compound (a compound consisting of a phosphonium cation and an anion) is preferable; and an iminium salt compound is more preferable.

As the anion constituting the onium salt compound, a carboxylate anion, a phenolate anion, a phosphate anion, or a sulfate anion is preferable; and a carboxylate anion is more preferable.

It is preferable that the anion constituting the ammonium salt compound further has an aromatic ring.

Examples of the above-described aromatic ring include an aromatic ring constituting an aromatic ring group represented by A^{a1} in Formula (A1) described later.

A temperature at which the above-described acidic compound and the above-described onium salt compound generate a base is preferably a heating temperature of a step 3 in a manufacturing method of a laminate described later.

A temperature at which the thermal-base generator generates a base can be obtained, for example, by heating a compound to be measured in a pressure-resistant capsule to 250° C. at 5° C./min using differential scanning calorimetry, reading a peak temperature of an exothermic peak at the lowest temperature, and setting the peak temperature as a base generation temperature.

The base generated by the thermal-base generator is preferably a secondary amine or a tertiary amine, and more preferably a tertiary amine. The above-described base may be linear, branched, or cyclic, and is preferably cyclic.

As the acidic compound, a compound represented by Formula (A1) is preferable.

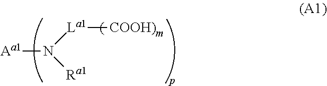

In Formula (A1), A^{a1} represents a p-valent organic group. R^{a1} represents a monovalent organic group. L^{a1} represents an (m+1)-valent linking group, m represents an integer of 1 or more, and p represents an integer of 1 or more.

In Formula (A1), A^{a1} represents a p-valent organic group.

Examples of the above-described organic group include an aliphatic hydrocarbon group and an aromatic ring group; and an aromatic ring group is preferable.

Examples of a monovalent aliphatic hydrocarbon group include an alkyl group and an alkenyl group.

The above-described alkyl group may be any of linear, branched, or cyclic.

The number of carbon atoms in the above-described alkyl group is preferably 1 to 30, more preferably 1 to 20, and still more preferably 1 to 10.

Examples of the above-described alkyl group include a methyl group, an ethyl group, a tert-butyl group, a dodecyl group, a cyclopentyl group, a cyclohexyl group, a cycloheptyl group, and an adamantyl group.

The alkenyl group may be linear, branched, or cyclic.

The number of carbon atoms in the alkenyl group is preferably 2 to 30, more preferably 2 to 20, and still more preferably 2 to 10.

Examples of the alkenyl group include a vinyl group, an allyl group, and a methallyl group.

Examples of the p-valent (p is an integer of 2 or more) aliphatic hydrocarbon group include a group formed by removing (p−1) hydrogen atoms from the above-described monovalent aliphatic hydrocarbon group.

The aliphatic hydrocarbon group may further have a substituent.

The aromatic ring group may be monocyclic or polycyclic.

The aromatic ring group may be any one of an aromatic hydrocarbon ring group or an aromatic heterocyclic group.

Examples of the aromatic ring group include a benzene ring group, a naphthalene ring group, a biphenyl ring group, a fluorene ring group, a pentalene ring group, an indene ring group, an azulene ring group, a heptalene ring group, an indacene ring group, a perylene ring group, a pentacene ring group, an acenaphthene ring group, a phenanthrene ring group, an anthracene ring group, a naphthacene ring group, a chrysene ring group, and a triphenylene ring group, a fluorene ring group, a biphenyl ring group, a pyrrole ring group, a furan ring group, a thiophene ring group, an imidazole ring group, an oxazole ring group, a thiazole ring group, a pyridine ring group, a pyrazine ring group, a pyrimidine ring group, a pyridazine ring group, an indridine ring group, an indole ring group, a benzofuran ring group, a benzothiophene ring group, an isobenzofuran ring group, a quinolizine ring group, a quinoline ring group, a phthalazine ring group, a naphthyridine ring group, a quinoxaline ring group, a quinoxazoline ring group, an isoquinoline ring group, a carbazole ring group, a phenanthridine ring group, an acridine ring group, a phenanthroline ring group, a thianthrene ring group, a chromene ring group, a xanthene ring group, a phenoxathiin ring group, a phenothiazine ring group, and a phenazine ring group; and a benzene ring group is preferable.

The aromatic ring group may further have a substituent. In Formula (A1), R^{a1} represents a monovalent organic group.

Examples of the monovalent organic group include the monovalent aliphatic hydrocarbon group and the monovalent aromatic ring group represented by A^{a1}.

The monovalent organic group may further have a substituent. The above-described substituent is preferably a carboxy group.

In Formula (A1), L^{a1} represents an (m+1)-valent linking group.

Examples of the (m+1)-valent linking group include a divalent linking group such as an ether group (—O—), a carbonyl group (—CO—), an ester group (—COO—), a thioether group (—S—), —SO₂—, —NR^{N}— (R^{N} represents a hydrogen atom or a substituent), an alkylene group (preferably having 1 to 10 carbon atoms), and an alkenylene group (preferably having 2 to 10 carbon atoms); a trivalent linking group having a group represented by “—N<” and a trivalent linking group having a group represented by “—CR<” (R represents a hydrogen atom or a substituent); a tetravalent linking group having a group represented by “>C<”; a k-valent linking group having a ring group such as an aromatic ring group and an alicyclic ring group; and a group formed by a combination of these groups.

In Formula (A1), m represents an integer of 1 or more, preferably 1 or 2, and more preferably 1.

In Formula (A1), p represents an integer of 1 or more, preferably 1 or 2, and more preferably 1.

As the ammonium cation constituting the ammonium salt compound, a cation represented by Formula (101) is preferable.

As the iminium cation constituting the iminium salt compound, a cation represented by Formula (102) is preferable.

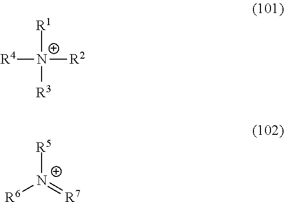

In Formula (101), R¹ to R⁴ each independently represents a hydrogen atom or an aliphatic group. At least two of R¹ to R⁴ may be bonded to each other to form a ring.

In Formula (102), R⁵ and R⁶ each independently represents a hydrogen atom or an aliphatic group. R⁷ represents an aliphatic group. At least two of R⁵ to R⁷ may be bonded to each other to form a ring.

The aliphatic group represented by R¹ to R⁴ and R⁵ to R⁷ may be linear, branched, or cyclic.

The number of carbon atoms in the above-described aliphatic group is preferably 1 to 10.

The above-described aliphatic group is preferably an alkyl group or an alkenyl group, and more preferably an alkyl group.

The above-described aliphatic group may have a substituent. Examples of the substituent include an arylcarbonyl group.

In addition, in the aliphatic group, a methylene group (—CH₂—) in the group may have a heteroatom (for example, an oxygen atom, a sulfur atom, —NR—, and the like. R represents a hydrogen atom or a substituent).

At least one of R⁵ to R⁷ is preferably an aliphatic group having —NR—, and more preferably an alkyl group having —NR—.

At least two of R⁵ to R⁷ may be bonded to each other to form a ring, and it is preferable that R⁵ and R⁷, and R⁶ and R⁷ are bonded to each other to form a ring. In other words, the above-described ring is preferably a polycyclic heterocycle and more preferably a bicyclic heterocycle.

As the thermal-base generator, a compound represented by Formula (B1) or Formula (B2) is also preferable.

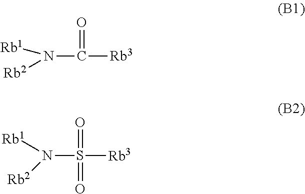

In Formula (B1) and Formula (B2), Rb¹ to Rb³ each independently represents an organic group not having a tertiary amine structure, a halogen atom, or a hydrogen atom. Here, at least one of Rb¹ or Rb² represents an organic group not having a tertiary amine structure or a halogen atom. The above-described tertiary amine structure is intended to be a structure in which a nitrogen atom forms a covalent bond with three carbon atoms, and does not include an amide group.

Rb¹ and Rb² are preferably a hydrogen atom, an alkyl group (preferably having 1 to 24 carbon atoms, more preferably 2 to 18 carbon atoms, and still more preferably 3 to 12 carbon atoms), an alkenyl group (preferably having 2 to 24 carbon atoms, more preferably 2 to 18 carbon atoms, and still more preferably 3 to 12 carbon atoms), an aryl group (preferably having 6 to 22 carbon atoms, more preferably 6 to 18 carbon atoms, and still more preferably 6 to 10 carbon atoms), or an arylalkyl group (preferably having 7 to 25 carbon atoms, more preferably 7 to 19 carbon atoms, and still more preferably 7 to 12 carbon atoms).

The alkyl group, the alkenyl group, the aryl group, and the arylalkyl group may have a substituent other than the tertiary amino group. The substituent is not particularly limited, and examples thereof include a halogen atom, an alkyl group, an alkoxy group, an alkynyl group, an alkenyl group, an aryl group, an aryloxy group, a formyl group, an acyl group, an alkoxycarbonyl group, an acyloxy group, a hydroxy group, a primary amino group, a secondary amino group, a carboxy group, a nitro group, and a cyano group. In addition, the group exemplified as the substituent may further have the above-described substituent, if possible.

Rb¹ and Rb² may be bonded to each other to form a ring which may have a substituent.

The above-described ring may be a monocycle or a polycycle. The number of ring member atoms of the above-described ring is preferably 4 to 7 and more preferably 5 or 6.

Examples of the substituent which may be included in the above-described ring are the same as the substituents which may be included in the groups exemplified as Rb¹ and Rb².

Examples of Rb3 include an alkyl group (preferably having 1 to 24 carbon atoms, more preferably having 2 to 18 carbon atoms, and still more preferably having 3 to 12 carbon atoms), an aryl group (preferably having 6 to 22 carbon atoms, more preferably having 6 to 18 carbon atoms, and still more preferably having 6 to 10 carbon atoms), an alkenyl group (preferably having 2 to 24 carbon atoms, more preferably having 2 to 12 carbon atoms, and still more preferably having 2 to 6 carbon atoms), an arylalkyl group (preferably having 7 to 23 carbon atoms, more preferably having 7 to 19 carbon atoms, and still more preferably having 7 to 12 carbon atoms), an arylalkenyl group (preferably having 8 to 24 carbon atoms, more preferably having 8 to 20 carbon atoms, and still more preferably having 8 to 16 carbon atoms), an alkoxyl group (preferably having 1 to 24 carbon atoms, more preferably having 2 to 18 carbon atoms, and still more preferably having 3 to 12 carbon atoms), an aryloxy group (preferably having 6 to 22 carbon atoms, more preferably having 6 to 18 carbon atoms, and still more preferably having 6 to 12 carbon atoms), and an arylalkyloxy group (preferably having 7 to 23 carbon atoms, more preferably having 7 to 19 carbon atoms, and still more preferably having 7 to 12 carbon atoms). Among the above, a cycloalkyl group (preferably having 3 to 24 carbon atoms, more preferably 3 to 18 carbon atoms, and still more preferably 3 to 12 carbon atoms), an arylalkenyl group, or an arylalkyloxy group is preferable.

The alkyl group, the alkenyl group, the aryl group, the arylalkyl group, the arylalkenyl group, the alkoxy group, the aryloxy group, and the arylalkyloxy group may have a substituent other than the tertiary amino group. Examples of the substituent other than the tertiary amino group are the same as the substituents which may be included in the groups exemplified as Rb¹ and Rb².

From the viewpoint that the effect of the present invention is more excellent, it is preferable that at least one of Rb¹, Rb², or Rb³ includes a ring structure, and it is more preferable that at least two of Rb¹, Rb², or Rb³ include a ring structure. The above-described ring structure may be any of a monocycle or a polycycle, and is preferably a monocycle or a bicyclic ring formed by fusing two monocycles.

The above-described ring structure may be any of an aliphatic ring or an aromatic ring, and is preferably a cyclohexane ring or a benzene ring.

Examples of the thermal-base generator include the thermal-base generators described in WO2018/038002A and the base generators described in JP2024-149522A.

The thermal-base generator may be used alone or in combination of two or more thereof.

A content of the thermal-base generator is preferably 0.1% to 10.0% by mass and more preferably 0.2% to 5.0% by mass with respect to the total solid content of the photosensitive composition.

A mass ratio of the content of the thermal-base generator to the content of the polyimide precursor is preferably 0.01 to 0.1 and more preferably 0.024 to 0.05.

### Adhesion Improver

The photosensitive composition may contain an adhesion improver from the viewpoint of adhesiveness to the substrate.

Examples of the adhesion improver include a silane coupling agent, an aluminum-based adhesion promoter, a titanium-based adhesion promoter, a compound having a sulfonamide structure, a compound having a thiourea structure, a phosphoric acid induction compound, a β-keto ester compound, and an amino compound, and a silane coupling agent is preferable.

### Silane Coupling Agent

Examples of the silane coupling agent include the compounds described in paragraph 0167 of WO2015/199219A, the compounds described in paragraphs 0062 to 0073 of JP2014-191002A, the compounds described in paragraphs 0063 to 0071 of WO2011/080992A, the compounds described in paragraphs 0060 and 0061 of JP2014-191252A, the compounds described in paragraphs 0045 to 0052 of JP2014-041264A, the compounds described in paragraph 0055 of WO2014/097594A, and the compounds described in paragraphs 0067 to 0078 of JP2018-173573A, the contents of which are incorporated in the present specification. In addition, it is also preferable to use two or more kinds of different silane coupling agents as described in paragraphs 0050 to 0058 of JP2011-128358A. In addition, it is also preferable to use a silane coupling agent having a nitrogen atom.

Examples of the silane coupling agent include the following compounds. In the following formulae, Me represents a methyl group and Et represents an ethyl group.

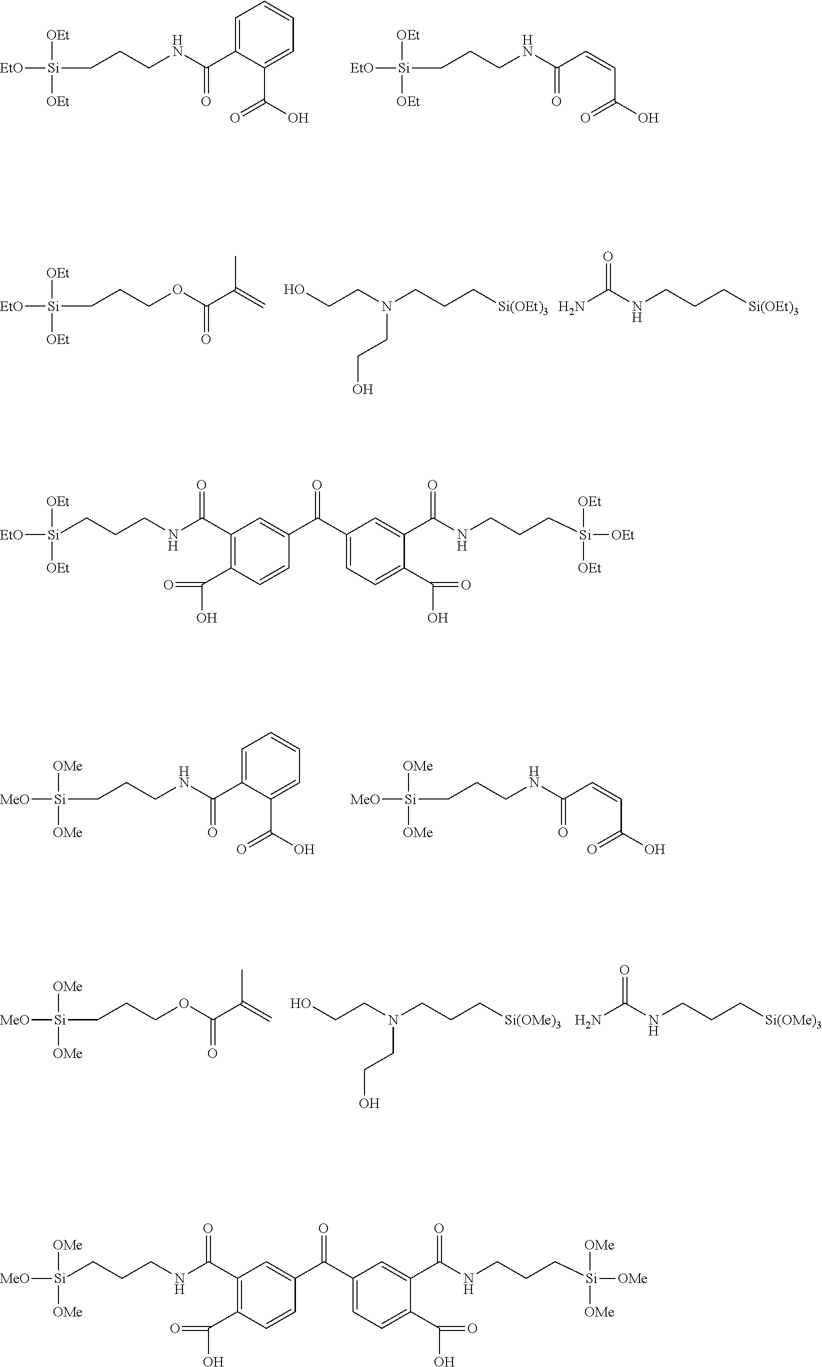

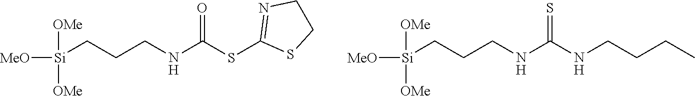 [SMILES: CO[Si](CCCNC(=O)SC1=NCCS1)(OC)OC ; CCCCNC(=S)NCCC[Si](OC)(OC)OC]

Examples of other adhesion improvers include the compounds described in paragraphs 0289 to 0295 of JP7354479B, the contents of which are incorporated herein by reference.

The adhesion improver may be used alone or in combination of two or more kinds thereof.

A content of the adhesion improver is preferably 0.1% to 10.0% by mass and more preferably 0.5% to 5.0% by mass with respect to the total solid content of the photosensitive composition.

### Surfactant

It is also preferable that the photosensitive composition contains a surfactant.

Examples of the surfactant include a fluorine-based surfactant, a hydrocarbon-based surfactant, and a silicone-based surfactant. As the surfactant, a silicone-based surfactant is preferable. From the viewpoint of improving environmental suitability, it is also preferable that the surfactant does not contain a fluorine atom.

Examples of the fluorine-based surfactant include an acrylic compound which has a molecular structure including a functional group having a fluorine atom and in which the functional group having a fluorine atom is broken to volatilize a fluorine atom by applying heat to the molecular structure. Examples of such a fluorine-based surfactant include MEGAFACE DS series (manufactured by DIC Corporation; The Chemical Daily, Feb. 22, 2016; Nikkei Business Daily, Feb. 23, 2016), MEGAFACE DS-21, and the like).

In addition, the fluorine-based surfactant may be a polymer of a fluorine atom-containing vinyl ether compound having a fluorinated alkyl group or a fluorinated alkylene ether group, and a hydrophilic vinyl ether compound. The fluorine-based surfactant may be a block polymer.

As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) may be used.

In addition, examples of the fluorine-based surfactant also include a fluorine-containing polymer having a group having an ethylenically unsaturated double bond in a side chain. Specific examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of a commercially available product of the fluorine-based surfactant include MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, and F-780 (all of which are manufactured by DIC Corporation); EXP.MFS-324, EXP.MFS-330, EXP.MFS-578, EXP.MFS-578-2, EXP.MFS-579, EXP.MFS-586, EXP.MFS-587, EXP.MFS-628, EXP.MFS-631, EXP.MFS-603, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730 LM, 650AC, 681, and 683 (all of which are manufactured by NEOS COMPANY LIMITED); and U-120E (Uni-chem Co., Ltd.).

Examples of the hydrocarbon-based surfactant include glycerol, trimethylolpropane, trimethylolethane, and ethoxylate and propoxylate thereof (for example, glycerol propoxylate, glycerol ethoxylate, and the like), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester.

Examples of a commercially available product of the hydrocarbon-based surfactant include PLURONIC (registered trademark) L10, L31, L61, L62, 10R5, 17R2, and 25R2, TETRONIC 304, 701, 704, 901, 904, and 150R1, and HYDROPALAT WE 3323 (all of which are manufactured by BASF); Solsperse 20000 (manufactured by Nippon Lubrizol Corporation); NCW-101, NCW-1001, and NCW-1002 (all of which are manufactured by FUJIFILM Wako Pure Chemical Corporation); Pionin D-1105, D-6112, D-6112-W, and D-6315 (all of which are manufactured by TAKEMOTO OIL & FAT Co., Ltd.); and OLFINE E1010, and SURFYNOL 104, 400, and 440 (all of which are manufactured by Nissin Chemical Co., Ltd.).

Examples of the silicone-based surfactant include a linear polymer including a siloxane bond, a modified siloxane polymer in which an organic group is introduced into a side chain and/or a terminal, and a polymer having a repeating unit having a hydrophilic group in a side chain and a repeating unit having a siloxane bond-containing group in a side chain. As the silicone-based surfactant, a polymer having a repeating unit having a hydrophilic group in a side chain and a repeating unit having a siloxane bond-containing group in a side chain is preferable. The above-described polymer may be either a random copolymer or a block copolymer.

As the repeating unit having a siloxane bond-containing group in a side chain, a repeating unit represented by Formula (SX1) or a repeating unit represented by Formula (SX2) is preferable.

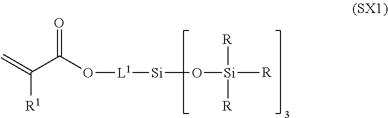

In Formula (SX1), R's each independently represents an alkyl group having 1 to 3 carbon atoms. R¹ represents a hydrogen atom or a methyl group. L¹ represents a single bond or a divalent organic group.

In a case where a plurality of R's are present, R's may be the same or different from each other.

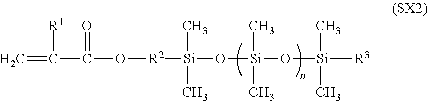

In Formula (SX2), R¹ represents a hydrogen atom or a methyl group. R² represents an alkylene group having 1 to 10 carbon atoms. R³ represents an alkyl group having 1 to 4 carbon atoms, and n represents an integer of 5 to 50.

As the repeating unit having a hydrophilic group in a side chain, a repeating unit represented by Formula (SX3) is preferable.

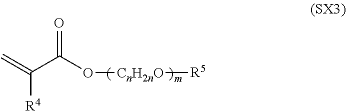

In Formula (SX3), R⁴ and R⁵ each independently represents a hydrogen atom or a methyl group, n represents an integer of 1 to 4, and m represents an integer of 1 to 100.

Examples of a commercially available product of the silicone-based surfactant include EXP.S-309-2, EXP.S-315, EXP.S-503-2, EXP.S-505-2, and S-506 (all of which are manufactured by DIC Corporation); DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.); X-22-4952, X-22-4272, X-22-6266, KF-351A, K354L, KF-355A, KF-945, KF-640, KF-642, KF-643, X-22-6191, X-22-4515, KF-6004, KF-6001, KF-6002, KP-101 KP-103, KP-104, KP-105, KP-106, KP-109, KP-112, KP-120, KP-121, KP-124, KP-125, KP-301, KP-306, KP-310, KP-322, KP-323, KP-327, KP-341, KP-368, KP-369, KP-611, KP-620, KP-621, KP-626, and KP-652 (all of which are manufactured by Shin-Etsu Silicone Co., Ltd.); F-4440, TSF-4300, TSF-4445, TSF-4460, and TSF-4452 (all of which are manufactured by Momentive Performance Materials Co., Ltd.); and BYK300, BYK306, BYK307, BYK310, BYK320, BYK323, BYK325, BYK330, BYK313, BYK315N, BYK331, BYK333, BYK345, BYK347, BYK348, BYK349, BYK370, BYK377, BYK378, and BYK323 (all of which are manufactured by BYK Chemie).

In addition, examples of the surfactant also include a nonionic surfactant other than those described above.

Examples of the surfactant also include surfactants described in paragraph 0017 of JP04502784B and paragraphs 0060 to 0071 of JP2009-237362A.

The surfactant may be used alone, or two or more types thereof may be used in combination.

A content of the surfactant is preferably 0.01% to 5.0% by mass and more preferably 0.1% to 1.0% by mass with respect to the total solid content of the photosensitive composition.

### Rust Inhibitor

It is also preferable that the photosensitive composition contains a rust inhibitor.

Examples of the rust inhibitor include a heterocyclic compound. Examples of the heterocyclic compound include a triazole compound, a benzotriazole compound, a tetrazole compound, a thiadiazole compound, a triazine compound, a rodanin compound, a thiazole compound, a benzothiazole compound, a benzimidazole compound, a benzoxazole compound, a pyrimidine compound, and a pyridine compound; and a triazole compound, a benzotriazole compound, or a tetrazole compound is preferable.

Examples of the heterocyclic compound include the compounds described in WO2022/039027A.

The rust inhibitor may be used alone or in combination of two or more thereof.

A content of the rust inhibitor is preferably 0.01% to 5.0% by mass and more preferably 0.1% to 1.0% by mass with respect to the total solid content of the photosensitive composition.

### Other Additives

The photosensitive composition may contain other additives in addition to the above-described components.

Examples of the other additives include a plasticizer, a solvent, a photoacid generator, a curing agent, an aliphatic thiol compound, a thermal crosslinking compound, a hydrogen donating compound, impurities, an alkoxysilane compound, a maleimide compound, and a hydrosilylating agent.

### Plasticizer

The photosensitive composition may contain a plasticizer.

In a case where the photosensitive composition layer described later is formed using a transfer film, it is preferable that the photosensitive composition contains a plasticizer from the viewpoint that the level difference conformability of the photosensitive composition layer in a case of being bonded (laminated) to an adherend is excellent and a film can be formed with high accuracy. Among these, in a case where the photosensitive composition contains a filler, it is preferable that the photosensitive composition contains a plasticizer.

The plasticizer is a compound different from the above-described various components, and preferably does not have a polymerizable group.

A molecular weight of the plasticizer is preferably 200 to 1,000, more preferably 250 to 800, and still more preferably 300 to 600.

In a case where the plasticizer has a molecular weight distribution, the above-described molecular weight is intended to be a weight-average molecular weight.

A boiling point of the plasticizer is preferably 230° C. to 500° C., more preferably 280°° C. to 480° C., still more preferably 300° C. to 450° C., and particularly preferably 350° C. to 450° C.

In the present specification, a boiling point of a compound is a value obtained by the following measuring method.

In a case where the compound Y is distilled under normal pressure (760 mmHg), a temperature of a gas at a point in time when condensation of the evaporated gas starts is defined as the boiling point (measured at 23° C. to 300° C.; temperature rising rate: 1° C./min).

The compound is distilled using a Liebig condenser, and in a case where the distillation does not start at 300° C. under normal pressure, the compound Y is distilled under reduced pressure. The same distillation is performed in the order of an atmospheric pressure of 100 mmHg, 50 mmHg, and 5 mmHg (measured at 23° C. to 300° C.; temperature rising rate: 1° C./min; in a case where the distillation does not start at 300° C., the distillation is performed at the next pressure), and from the temperature and pressure at which the condensation of the evaporated gas starts, the boiling point under normal pressure is defined as the boiling point (calculated value) obtained using a nomograph described in Science of Petroleum, Vol. II, p. 1281 (1938). In a case where the distillation does not start at 300° C. under 5 mmHg, the boiling point under normal pressure is considered to be higher than 500° C. The nomograph is used by a known method. Specifically, a boiling point of the A line under reduced pressure and a degree of reduction of the C line are connected by a straight line (procedure 1), a numerical value of an intersection of the straight line drawn in the procedure 1 and the B line is read (procedure 2), and this is regarded as the boiling point under normal pressure.

A viscosity of the plasticizer at 25° C. is preferably 0.01 to 500 mPa·s, more preferably 0.05 to 300 mPa·s, and still more preferably 0.1 to 100 mPa·s.

The above-described viscosity can be measured with a B-type viscometer.

Examples of the plasticizer include polycarboxylic acid esters, phosphoric acid esters, polyether esters, alkylene glycol monoalkyl ethers, alkylene glycol dialkyl ethers, and benzyl benzoate; and polycarboxylic acid esters are preferable.

Examples of the polycarboxylic acid esters include aliphatic dicarboxylic acid esters (for example, adipic acid esters, azelaic acid esters, and sebacic acid esters); aromatic dicarboxylic acid esters (for example, phthalic acid esters); trimellitic acid esters; and citric acid esters (for example, acetyl citric acid tributyl esters).

Examples of the polycarboxylic acid esters include ethyl phthalyl ethyl glycolate, dihexyl phthalate, tributyl o-acetyl citrate, benzyl 2-ethylhexyl phthalate, bis(2-ethylhexyl) isophthalate, tris(2-ethylhexyl) trimellitate, and bis(2-butoxyethyl) adipate.

Examples of the phosphoric acid esters include triamyl phosphate and tris(2-butoxyethyl) phosphate.

The polyether esters are preferably organic acid esters of polyalkylene glycol. Examples of the organic acid include monocarboxylic acids (for example, butyric acid, isobutyric acid, 2-ethylbutyric acid, 2-ethylhexyl acid, and decanoic acid). Specific examples of the polyether esters include triethylene glycol bis(2-ethylhexanoate).

Examples of the alkylene glycol monoalkyl ethers and alkylene glycol dialkyl ethers include hexaethylene glycol monomethyl ether (mPEG6-OH), pentaethylene glycol monomethyl ether, tetraethylene glycol monomethyl ether, heptaethylene glycol monomethyl ether, octaethylene glycol monomethyl ether, nonaethylene glycol monomethyl ether, pentaethylene glycol dimethyl ether, hexaethylene glycol dimethyl ether, heptaethylene glycol dimethyl ether, octaethylene glycol dimethyl ether, and nonaethylene glycol dimethyl ether. The plasticizer may be used alone or in combination of two or more thereof.

A content of the plasticizer is preferably 5.0% to 50.0% by mass and more preferably 10.0% to 30.0% by mass with respect to the total solid content of the photosensitive composition.

### Solvent

The photosensitive composition may contain a solvent. The solvent is not particularly limited as long as it can dissolve or disperse the various components which can be contained in the photosensitive composition layer, other than the solvent.

Examples of the solvent include water, an alkylene glycol ether solvent, an alkylene glycol ether acetate solvent, an alcohol solvent (for example, methanol, ethanol, and the like), a ketone solvent (for example, acetone, methyl ethyl ketone, and the like), an aromatic hydrocarbon solvent (for example, toluene and the like), an aprotic polar solvent (for example, N,N-dimethylformamide and the like), a cyclic ether solvent (for example, tetrahydrofuran and the like), an ester solvent (for example, n-propyl acetate and the like), an amide solvent, a lactone solvent, and a solvent including two or more kinds thereof.

The solvent may be used alone or in combination of two or more kinds thereof.

A content of the solvent is preferably 50 to 1,900 parts by mass, more preferably 100 to 1,200 parts by mass, and still more preferably 100 to 900 parts by mass with respect to 100 parts by mass of the total solid content of the photosensitive composition layer.

The photoacid generator is a compound which generates an acid by light (for example, exposure light). In a case where the polyimide precursor has an acid-decomposable group, the photosensitive composition preferably contains a photoacid generator.

Examples of the photoacid generator include an ionic photoacid generator and a nonionic photoacid generator.

Examples of the ionic photoacid generator include a compound having a sulfonium structure, an onium salt compound having a diaryliodonium structure or a triarylsulfonium structure, and an ammonium salt compound having a quaternary ammonium structure. Examples of the ionic photoacid generator also include ionic photoacid generators described in paragraphs 0114 to 0133 of JP2014-085643A.

Examples of the nonionic photoacid generator include trichloromethyl-s-triazine and derivatives thereof (trichloromethyl-s-triazine which may have a substituent), a compound having a diazomethane structure, a compound having an imidosulfonate structure, and a compound having an oxime sulfonate structure. Examples of the trichloromethyl-s-triazine and derivatives thereof, the diazomethane compound, and the imidosulfonate compound include compounds described in paragraphs 0083 to 0088 of JP2011-221494A. In addition, examples of the oxime sulfonate compound include compounds described in paragraphs 0084 to 0088 of WO2018/179640A.

The photosensitive composition may contain impurities.

Examples of the impurities include sodium, potassium, magnesium, calcium, iron, manganese, copper, aluminum, titanium, chromium, cobalt, nickel, zinc, tin, halogen, and ions of these. Halide ion, sodium ion, and potassium ion are easily mixed as the impurities, so that the following content is preferable.

The content of the impurities is preferably 80 ppm by mass or less, more preferably 10 ppm by mass or less, and still more preferably 2 ppm by mass or less with respect to the total mass of the photosensitive composition. The lower limit value thereof is usually 0 ppb by mass or more, and may be 1 ppb by mass or more or 0.1 ppm by mass or more with respect to the total mass of the photosensitive composition.

The content of the impurities can be quantified by a known method such as inductively coupled plasma (ICP) emission spectroscopy, atomic absorption spectroscopy, and ion chromatography.

Examples of a method of adjusting the content of the impurities include a method of using a raw material having a low content of impurities as a raw material of the photosensitive composition, a method of purifying a raw material of the photosensitive composition and using the purified raw material, and a method of preventing the mixing of impurities during the preparation of the photosensitive composition.

In the photosensitive composition, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low. Specifically, the content of these compounds is preferably 100 ppm by mass or less, more preferably 20 ppm by mass or less, and still more preferably 4 ppm by mass or less with respect to the total solid content of the photosensitive composition. The lower limit value thereof may be 10 ppb by mass or more or 100 ppb by mass or more with respect to the total mass of the photosensitive composition.

The content of these compounds can be adjusted by the same method as that for the above-described impurities. In addition, these compounds can be quantified by a known measuring method.

Examples of the aliphatic thiol compound, the thermal crosslinking compound, and the hydrogen donating compound include various components described in WO2022/039027A.

### Transfer Film

The transfer film according to the embodiment of the present invention includes a temporary support and a photosensitive composition layer formed of the photosensitive composition.

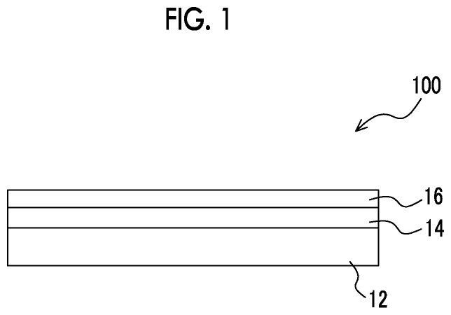

FIG. 1 is a schematic cross-sectional view showing an example of the embodiment of the transfer film.

A transfer film 100 shown in FIG. 1 has a configuration in which a temporary support 12, a composition layer 14, and a cover film 16 are laminated in this order.

The transfer film 100 shown in FIG. 1 has a form in which the cover film 16 is provided, but the transfer film may have a form in which the cover film 16 is not provided. In addition, as will be described later, the transfer film may further include an interlayer and/or a thermoplastic resin layer.

Hereinafter, each member included in the transfer film will be described in detail.

### Temporary Support

The transfer film includes a temporary support.

The temporary support is a member which supports the photosensitive composition layer, and is finally removed by a peeling treatment.

The temporary support may have a monolayer structure or a multilayer structure.

The temporary support is preferably a film and more preferably a resin film.

As the temporary support, a film which has flexibility and does not generate significant deformation, contraction, or stretching under pressure or under pressure and heating is also preferable. Examples of the above-described film include a polyethylene terephthalate (PET) film (for example, a biaxially stretched polyethylene terephthalate film and the like), a polymethyl methacrylate film, a cellulose triacetate film, a polystyrene film, a polyimide film, and a polycarbonate film; and a polyethylene terephthalate film is preferable.

In addition, it is preferable that the temporary support does not have deformation such as wrinkles and scratches.

From the viewpoint that pattern exposure through the temporary support can be performed, the temporary support preferably has high transparency. Specifically, any of transmittances at a wavelength of 313 nm, at a wavelength of 365 nm, at a wavelength of 405 nm, and at a wavelength of 436 nm is preferably 60% or more, more preferably 70% or more, still more preferably 80% or more, and most preferably 90% or more. The upper limit thereof is preferably less than 100%. Examples of a preferred value of any of the transmittances at each of the wavelengths described above include 87%, 92%, and 98%.

From the viewpoint of pattern formability during pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less. The lower limit is preferably 0% or more.

From the viewpoint of pattern formability during the pattern exposure through the temporary support and transparency of the temporary support, it is preferable that the number of fine particles, foreign substances, and defects contained in the temporary support is small. The number of fine particles having a diameter of 1 μm or more, foreign substances, and defects in the temporary support is preferably 50 pieces/10 mm² or less, more preferably 10 pieces/10 mm² or less, still more preferably 3 pieces/10 mm² or less, and particularly preferably 0 piece/10 mm².

A thickness of the temporary support is preferably 5 to 200 μm, and from the viewpoint of ease of handling and general-purpose properties, it is more preferably 5 to 150 μm, still more preferably 5 to 50 μm, and particularly preferably 5 to 35 μm. The thickness of the temporary support can be calculated as an average value of 5 random points measured by cross-sectional observation with a scanning electron microscope (SEM).

From the viewpoint of improving the adhesiveness between the temporary support and the photosensitive composition layer, the surface of the temporary support in contact with the photosensitive composition layer may be surface-modified by UV irradiation, corona discharge, plasma, or the like.

In a case where the surface is modified by UV irradiation, an exposure amount of the UV irradiation is preferably 10 to 2,000 mJ/cm² and more preferably 50 to 1,000 mJ/cm².

Examples of a light source for the UV irradiation include a low pressure mercury lamp, a high pressure mercury lamp, an ultra-high pressure mercury lamp, a carbon arc lamp, a metal halide lamp, a xenon lamp, a chemical lamp, an electrodeless discharge lamp, and a light emitting diode, all of which emit light in a wavelength range of 150 to 450 nm.

The lamp output and the illuminance can be appropriately adjusted.

Examples of the temporary support include a biaxial stretching polyethylene terephthalate film having a film thickness of 16 μm, a biaxial stretching polyethylene terephthalate film having a film thickness of 12 μm, and a biaxial stretching polyethylene terephthalate film having a film thickness of 9 μm.

The temporary support may be a recycled product. Examples of the recycled product include a product obtained by washing and chipping used films and the like, and forming the obtained material into a film. Examples of a commercially available product of the recycled product include Ecouse series (manufactured by Toray Industries, Inc.).

Examples of the temporary support include temporary supports described in paragraphs 0017 and 0018 of JP2014-085643A, paragraphs 0019 to 0026 of JP2016-027363A, paragraphs 0041 to 0057 of WO2012/081680A, and paragraphs 0029 to 0040 of WO2018/179370A, the contents of which are incorporated in the present specification.

The temporary support may have a layer (lubricant layer) containing fine particles on one or both surfaces of the temporary support, for the purpose of imparting handleability. A diameter of the fine particles contained in the lubricant layer is preferably 0.05 to 0.8 μm. A film thickness of the lubricant layer is preferably 0.05 to 1.0 μm.

Examples of a commercially available product of the temporary support include LUMIRROR 16FB40, LUMIRROR 16KS40, LUMIRROR #38-U48, LUMIRROR #75-U34, and LUMIRROR #25T60 (all of which are manufactured by Toray Industries, Inc.); and COSMOSHINE A4100, COSMOSHINE A4160, COSMOSHINE A4300, COSMOSHINE A4360, and COSMOSHINE A8300 (all of which are manufactured by TOYOBO Co., Ltd.).

### Photosensitive Composition Layer

The photosensitive composition layer is a layer formed of the above-described photosensitive composition. Various components that can be contained in the photosensitive composition layer have the same meaning as various components that can be contained in the above-described photosensitive composition, and suitable aspects thereof are also the same.

However, a suitable numerical range of the content of the various components in the photosensitive composition layer is the same as the suitable range in which “content (% by mass) of various components with respect to the total solid content of the photosensitive composition” is read as “content (% by mass) of various components with respect to the total mass of the photosensitive composition layer”. Specifically, the description “content of the polyimide precursor is preferably 5.0% by mass or more with respect to the total solid content of the photosensitive composition” is read as “content of the polyimide precursor is preferably 5.0% by mass or more with respect to the total mass of the photosensitive composition layer”.

From the viewpoint of improving reliability, improving handleability of the transfer film, and improving laminating properties, a moisture content of the composition layer is preferably 3.0% by mass or less, more preferably 2.0% by mass or less, and still more preferably 1.0% by mass or less with respect to the total mass of the composition layer. A lower limit of the moisture content of the photosensitive composition layer is preferably 0.0001% by mass or more, more preferably 0.01% by mass or more, and still more preferably 0.1% by mass or more with respect to the total mass of the photosensitive composition layer.

Specific examples of the moisture content in the photosensitive composition layer include 2.5% by mass, 1.5% by mass, and 0.3% by mass with respect to the total mass of the photosensitive composition layer.

From the viewpoint of improving reliability, improving handleability of the transfer film, and improving laminating properties, an amount of a residual solvent in the composition layer is preferably 6.0% by mass or less, more preferably 4.0% by mass or less, still more preferably 2.0% by mass or less, and particularly preferably 1.0% by mass or less with respect to the total mass of the composition layer. A lower limit of the amount of the residual solvent in the photosensitive composition layer is preferably 0.0001% by mass or more, more preferably 0.01% by mass or more, and still more preferably 0.1% by mass or more with respect to the total mass of the photosensitive composition layer.

Specific examples of the amount of the residual solvent in the photosensitive composition layer include 3.5% by mass, 2.5% by mass, 1.5% by mass, and 0.3% by mass with respect to the total mass of the photosensitive composition layer.

From the viewpoint that the migration resistance is more excellent, an average thickness of the photosensitive composition layer is preferably 0.5 μm or more, more preferably 1 μm or more, still more preferably 3 μm or more, and particularly preferably 5 μm or more. From the viewpoint that the resolution is excellent, the average thickness of the photosensitive composition layer is preferably 40 μm or less, more preferably 25 μm or less, and still more preferably 20 μm or less.

The transfer film may have other layers in addition to the above-described layers.

### Interlayer and Thermoplastic Resin Layer

The transfer film may include an interlayer and/or a thermoplastic resin layer.

Examples of the interlayer and the thermoplastic resin layer include those described in paragraphs 0164 to 0204 of WO2021/166719A, the contents of which are incorporated in the present specification.

### Cover Film

The transfer film may include a cover film.

The number of fisheyes with a diameter of 80 μm or more in the cover film is preferably 5 pieces/m² or less. The “fisheye” means that, in a case where a material is hot-melted, kneaded, extruded, biaxially stretched, cast and/or the like to produce a film, foreign substances, undissolved substances, oxidatively deteriorated substances, and/or the like of the material are incorporated into the film.

The number of particles having a diameter of 3 μm or more, included in the cover film, is preferably 30 particles/mm² or less, more preferably 10 particles/mm² or less, and still more preferably 5 particles/mm² or less. As a result, it is possible to suppress defects caused by ruggedness due to the particles contained in the cover film being transferred to the composition layer.

An arithmetic average roughness Ra of a surface of the cover film is preferably 0.01 μm or more, more preferably 0.02 μm or more, and still more preferably 0.03 μm or more. In a case where Ra is within such a range, for example, in a case where the transfer film has a long shape, take-up property in a case of winding the transfer film is excellent. In addition, from the viewpoint of suppressing defects during transfer, Ra is preferably less than 0.50 μm, more preferably 0.40 μm or less, and still more preferably 0.30 μm or less.

Examples of the cover film include a polyethylene terephthalate film, a polypropylene film, a polystyrene film, and a polycarbonate film.

Examples of the cover film include cover films described in paragraphs 0083 to 0087 and 0093 of JP2006-259138A.

Examples of the cover film include ALPHAN (registered trademark) FG-201 (manufactured by Oji F-Tex Co., Ltd.), ALPHAN (registered trademark) E-201F (manufactured by Oji F-Tex Co., Ltd.), Cerapeel (registered trademark) 25WZ (manufactured by TORAY ADVANCED FILM CO., LTD.), and LUMIRROR (registered trademark) 16QS62 (16KS40) (manufactured by Toray Industries, Inc.).

The cover film may be a recycled product. Examples of the recycled product include a product obtained by washing and chipping used films and the like, and forming the obtained material into a film. Examples of a commercially available product of the recycled product include Ecouse series (manufactured by Toray Industries, Inc.).

The transfer film may include a layer other than the above-described layers.

Examples of other layers include a layer of high refractive index.

Examples of the layer of high refractive index include those described in paragraphs 0168 to 0188 of WO2021/187549A, the contents of which are incorporated in the present specification.

### Manufacturing Method of Transfer Film

As a method for manufacturing the transfer film, a known manufacturing method can be adopted.

In the manufacturing method of the transfer film, it is preferable to apply the photosensitive composition onto the temporary support to form the photosensitive composition layer, and it is more preferable to dry the coating film of the photosensitive composition to form the photosensitive composition layer.

Examples of an applying method include slit coating, spin coating, curtain coating, and inkjet coating.

Examples of the manufacturing method of the transfer film 100 shown in FIG. 1 include a method including a step of applying the photosensitive composition onto the surface of the temporary support 12 to form a coating film and further drying the coating film to form the photosensitive composition layer 14.

Furthermore, the transfer film 100 shown in FIG. 1 is manufactured by pressure-bonding the cover film 16 to the photosensitive composition layer of the transfer film manufactured by the above-described manufacturing method. In addition, the transfer film 100 shown in FIG. 1 may be wound after the manufacturing to be stored as the transfer film 100 in a roll form. The roll-shaped transfer film 100 is provided as it is in a bonding step described later with the substrate in a roll-to-roll method.

In addition, as described above, the transfer film may have an interlayer and/or a thermoplastic resin layer between the temporary support and the photosensitive composition layer.

Examples of a composition for forming the interlayer, a method for forming the interlayer, a composition for forming the thermoplastic resin layer, and a method for forming the thermoplastic resin layer include paragraphs 0133 to 0136 and paragraphs 0143 and 0144 of WO2021/033451A, the contents of which are incorporated in the present specification.

### Use

The photosensitive composition can be used for forming a film (hereinafter, also referred to as a “specific film”), and the specific film can be applied to various applications. The specific film can be applied as, for example, an electrode protective film, an insulating film, a planarization film, an overcoat film, a hard coat film, a passivation film, a partition wall, a spacer, a microlens, an optical filter, an antireflection film, an etching resist, and a plating member.

More specific examples thereof include a protective film or an insulating film for a touch panel electrode, a protective film or an insulating film for a printed wiring board, a protective film or an insulating film for a TFT substrate, an interlayer insulating film in a build-up substrate of a semiconductor package, an organic interposer, a color filter, an overcoat film for a color filter, and an etching resist for a wiring formation.

Among these, the photosensitive composition and the transfer film can be suitably used for forming an insulating film, and the insulating film is preferably used as an insulating film for a semiconductor package. That is, the photosensitive composition and the transfer film are preferably used for forming an insulating film for a semiconductor package.

In addition, it is also preferable that the photosensitive composition and the transfer film are used for producing a laminate having a photosensitive composition layer having a pattern on a substrate.

### Method for Producing Laminate

The manufacturing method of a laminate according to the embodiment of the present invention is not particularly limited as long as it is a method of obtaining a laminate by forming a photosensitive composition layer on a substrate using the above-described photosensitive composition. Specifically, it is preferable that the manufacturing method of a laminate includes the following steps 1 to 3.

Step 1: step of forming a photosensitive composition layer on a substrate using a photosensitive composition

Step 2: step of forming a pattern including vias on the photosensitive composition layer

Step 3: step of subjecting the pattern to at least one of heating or exposure

Hereinafter, each step of the manufacturing method of a laminate will be described in detail.

### Step 1

The step 1 is a step of forming a photosensitive composition layer on a substrate using a photosensitive composition.

Examples of the method of forming the photosensitive composition layer include a method of applying a photosensitive composition. Examples of the method of applying a photosensitive composition include the method of applying a photosensitive composition in the manufacturing method of a transfer film. The photosensitive composition layer may be formed by drying a coating film of the photosensitive composition.

The photosensitive composition layer may be formed using the above-described transfer film. Examples of the method of forming the photosensitive composition layer using a transfer film include a method of bringing a surface of the photosensitive composition layer in the transfer film on a side opposite to the temporary support into contact with a substrate to bond the transfer film and the substrate to each other.

Examples of the bonding method include a known transfer method and a known laminating method; and a method in which the substrate is superimposed on the surface of the photosensitive composition layer and pressurization and heating are performed using a roll or the like is preferable.

Examples of the above-described laminating method include known laminators such as a vacuum laminator and an auto-cut laminator.

A laminating temperature is not particularly limited, but is preferably 70° C. to 130° C. In a case of using the transfer film, the step 1 is preferably performed by a roll-to-roll method. The substrate to which the transfer film is bonded is preferably a resin film or a resin film having a conductive layer.

The roll-to-roll method refers to a method in which, as the substrate, a substrate which can be wound up and unwound is used, a step of unwinding the substrate before any of the steps included in the manufacturing method of a laminate according to the embodiment of the present invention, a step of winding the substrate is included after any of the steps, and at least one of the steps (preferably, all steps or all steps other than the heating step) is performed while transporting the substrate.

As an unwinding method in the unwinding step and a winding method in the winding step, a known method may be used in the manufacturing method to which the roll-to-roll method is adopted.

### Substrate

Examples of the substrate include a glass substrate, a glass epoxy substrate, a silicon substrate, a resin substrate, and a substrate having a conductive layer.

A refractive index of the substrate is preferably 1.50 to 1.52.

The substrate may be composed of a translucent substrate such as a glass substrate, and for example, tempered glass typified by Gorilla glass of Corning Incorporated can also be used. In addition, examples of the material contained in the above-described substrate also include materials used in JP2010-086684A, JP2010-152809A, and JP2010-257492A.

In a case where the above-described substrate includes a resin substrate, as the resin substrate, a resin film having a small optical distortion and/or a high transparency is more preferable. Specific examples thereof include polyethylene terephthalate (PET), polyethylene naphthalate, polycarbonate, triacetyl cellulose, a cycloolefin polymer, and polyimide.

As the substrate having a conductive layer, from the viewpoint that it is possible to manufacture by a roll-to-roll method, a resin substrate having a conductive layer is preferable and a resin film having a conductive layer is more preferable. In addition, the substrate having a conductive layer may be a laminate obtained by the above-described method for manufacturing a laminate.

Examples of the conductive layer include any conductive layer used for general circuit wiring or touch panel wiring.

As the conductive layer, from the viewpoint of conductivity and fine line formability, one or more layers selected from the group consisting of a metal layer (for example, a metal foil or the like), a conductive metal oxide layer, a graphene layer, a carbon nanotube layer, and a conductive polymer layer are preferable, a metal layer is more preferable, and a copper layer or a silver layer is still more preferable.

The conductive layer in the substrate having a conductive layer may be one layer or two or more layers.

In a case where the substrate having a conductive layer includes two or more conductive layers, it is preferable that each conductive layer is a conductive layer formed of different materials.

Examples of a material of the conductive layer include simple substances of metal and conductive metal oxides.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The “conductive” means that a volume resistivity is less than 1×10⁶ Ω·cm, preferably less than 1×10⁴ Ω·cm. The conductive layer may be patterned.

Examples of a method for manufacturing the patterned conductive layer include a subtractive method such as an etching method, and an additive method. Examples of the etching method include a method by wet etching, which is described in paragraphs 0048 to 0054 of JP2010-152155A, and a method by dry etching such as a known plasma etching. In addition, the etching method may be a method using an etching resist.

### Step 2

Step 2 is a step of forming a pattern including vias on the photosensitive composition layer.

The pattern including vias may be formed only on the photosensitive composition layer, or may be formed on both the photosensitive composition layer and the substrate.

The pattern including vias may be a through hole or a via hole.

Examples of a shape of the above-described via include, as a cross-sectional shape, a quadrangular shape, a trapezoidal shape, and an inverted trapezoidal shape; and as a front shape, a circular shape and a quadrangular shape (a shape in a case where the via is observed from a direction in which a via bottom is seen). Among these, an inverted trapezoidal shape is preferable as the cross-sectional shape from the viewpoint of improving attachability of the copper plating to the via wall surface.

A size (diameter) of the via is preferably 300 μm or less, more preferably 100 μm or less, still more preferably 50 μm or less, and particularly preferably 5 μm or less. The lower limit thereof is preferably 1 μm or more.

The number of the above-described vias may be 1 or more, preferably 2 or more.

As a method of forming the pattern including vias, it is preferable to include an exposure step of subjecting the photosensitive composition layer to pattern exposure, and a development step of developing the pattern-exposed photosensitive composition layer using a developer to form a pattern. The “pattern exposure” refers to exposure in a patterned manner, that is, exposure in which an exposed portion and a non-exposed portion are present.

### Exposing Step

The exposing step is a step of exposing the photosensitive composition layer in a patterned manner.

A positional relationship between the exposed portion and the non-exposed portion in the pattern exposure is not particularly limited and is appropriately adjusted. The pattern exposure may be performed from the side of the photosensitive composition layer opposite to the substrate, or may be performed from the substrate side of the photosensitive composition layer.

As a light source used for the exposure, any light source may be used as long as it irradiates the photosensitive component (for example, the compound represented by Formula (1)) in the photosensitive composition layer with light in a photosensitive wavelength range (for example, light in a wavelength range of 254 nm, 313 nm, 365 nm, 405 nm, or the like). Specific examples thereof include an ultra-high pressure mercury lamp, a high pressure mercury lamp, a metal halide lamp, and a light emitting diode (LED).

An exposure amount is preferably 5 to 2,000 mJ/cm² and more preferably 10 to 1,000 mJ/cm².

In a case where the photosensitive composition layer is formed using the transfer film in the step 1, in the exposure step, the pattern exposure may be performed after peeling the temporary support from the photosensitive composition layer, or the pattern exposure may be performed through the temporary support before peeling the temporary support, and then the temporary support may be peeled off. In order to prevent mask contamination due to contact between the composition layer and the mask and to avoid an influence of foreign substance adhering to the mask on the exposure, it is preferable to perform the pattern exposure without peeling off the temporary support. The pattern exposure may be an exposure through a mask or a direct exposure using a laser or the like.

Examples of the mask include a quartz mask, a soda-lime glass mask, and a film mask. From the viewpoint of excellent dimensional accuracy, a quartz mask is preferable, and from the viewpoint that it is easy to increase the size, a film mask is preferable.

As a material of the film mask, a polyester film is preferable, and a polyethylene terephthalate film is more preferable. Specific examples of the material of the film mask include XPR-7S SG (manufactured by Fujifilm Global Graphic Systems).

It is preferable that the temporary support is peeled off from the photosensitive composition layer before the development step.

### Developing Step

The development step is a step of developing the exposed photosensitive composition layer with a developer to form a pattern after the exposure step.

Examples of the developer include an organic solvent developer.

Examples of the organic solvent developer include developers containing an organic solvent such as a ketone solvent, an ester solvent, an alcohol solvent, an amide solvent, an ether solvent, and a hydrocarbon solvent.

As the organic solvent developer, cyclopentanone or propylene glycol monomethyl ether acetate is preferable, and cyclopentanone is more preferable.

In the organic solvent developer, a plurality of organic solvents may be mixed, or may be mixed with an organic solvent other than the above or water. A content of water in the organic solvent developer is preferably less than 10% by mass with respect to the total mass of the organic solvent developer, and it is more preferable that the organic solvent developer does not substantially contain water. A content of the organic solvent in the organic solvent developer is preferably 50% by mass or more, more preferably 60% by mass or more, still more preferably 85% by mass or more, particularly preferably 90% by mass or more, and most preferably 95% by mass or more with respect to the total mass of the organic solvent developer. The upper limit thereof is preferably 100% by mass or less with respect to the total mass of the organic solvent developer.

Examples of the developing method include puddle development, shower development, spin development, and dip development. In the shower development, the unnecessary portion can be removed by spraying the developer onto the exposed photosensitive composition layer by showering. In addition, after the development, it is also preferable to spray a washing agent and the like with a shower and rub with a brush and the like to remove the developing residue. A liquid temperature of the developer is preferably 20° C. to 40° C.

### Step 3

The step 3 is a step of subjecting the pattern obtained in the step 2 to at least one of heating or exposure, and it is preferably a step of subjecting the pattern to at least heating.

In the step 3, the reaction (for example, cyclization reaction) of the polyimide precursor in the photosensitive composition is promoted, and the polyimide can be formed.

The temperature and time of the heat treatment can be appropriately selected according to the structure of the polyimide precursor.

The temperature of the heating treatment is preferably 120° C. to 400° C., more preferably 150° C. to 400° C., and still more preferably 180° C. to 350° C.

The time of the heating treatment is preferably 1 to 24 hours, more preferably 1 to 12 hours, and still more preferably 1 to 9 hours.

The heating treatment may be performed in any of an air environment or a nitrogen replacement environment.

The atmospheric pressure under the heating treatment environment is preferably 8.1 kPa or more, and more preferably 50.66 kPa or more. The upper limit thereof is preferably 121.6 kPa or less, more preferably 111.46 kPa or less, and still more preferably 101.3 kPa or less.

A light source and an exposure amount of the exposure treatment can be appropriately selected according to the type of the photosensitive component in the photosensitive composition layer.

Examples of the light source include an ultra-high pressure mercury lamp, a high pressure mercury lamp, a metal halide lamp, and a light emitting diode (LED).

The exposure amount is preferably 5 to 2,000 mJ/cm² and more preferably 10 to 2,000 mJ/cm².

### Other Steps

The manufacturing method of a laminate may include other steps in addition to the above-described steps.

Examples of the other steps include the following steps.

### Cover Film Peeling Step

In a case where the transfer film in the above-described manufacturing method of a laminate includes a cover film, it is preferable that the manufacturing method of a laminate includes a step of peeling off the cover film of the transfer film.

As a method of peeling off the cover film, and a known method can be adopted.

### Treatment Liquid Contacting Step

A step of bringing the pattern obtained in the step 2 into contact with a treatment liquid containing a basic compound and a solvent may be included between the step 2 and the step 3. Among these, in a case where the photosensitive composition does not contain a thermal-base generator, it is preferable that the manufacturing method of a laminate includes the treatment liquid contacting step.

Examples of the basic compound include a nitrogen-containing compound. In addition, as the basic compound, a basic compound among the compounds exemplified as the thermal-base generator can also be used.

A content of the basic compound is preferably 0.1% to 10% by mass and more preferably 1% to 8% by mass with respect to the total mass of the treatment liquid.

Examples of the solvent include water, an alkylene glycol ether solvent, an alkylene glycol ether acetate solvent, an alcohol solvent, a ketone solvent, an aromatic hydrocarbon solvent, an aprotic polar solvent, a cyclic ether solvent, an ester solvent, an amide solvent, a lactone solvent, and a solvent containing two or more kinds of these solvents.

A method of bringing the pattern into contact with the treatment liquid is not particularly limited, and examples thereof include a method of immersing the pattern in the treatment liquid, a method of spraying the treatment liquid onto the pattern, and a method of flowing the treatment liquid onto the pattern.

A contact time with the treatment liquid is, for example, preferably 1 to 30 minutes.

### Step of Reducing Visible Light Reflectivity

In a case where the substrate is a substrate having a conductive layer, the above-described manufacturing method of a laminate may further include a step of performing a treatment of reducing a visible light reflectivity of the conductive layer.

In a case where the above-described substrate is a substrate having a plurality of conductive layers, the treatment of reducing the visible light reflectivity may be performed on some conductive layers or all conductive layers.

Examples of the treatment of reducing the visible light reflectivity include an oxidation treatment. For example, by oxidizing copper to copper oxide, the visible light reflectivity of the conductive layer can be reduced due to blackening.

Examples of a suitable aspect of the treatment of reducing the visible light reflectivity include the descriptions in paragraphs 0017 to 0025 of JP2014-150118A, and paragraphs 0041, 0042, 0048, and 0058 of JP2013-206315A, the contents of which are incorporated in the present specification.

### Etching Step

In a case where the substrate is a substrate having a conductive layer, the above-described manufacturing method of a laminate may include a step (etching step) of etching, using the pattern (film) formed by the step 3 or the step 4 as an etching resist film, the conductive layer in a region where the etching resist film is not disposed.

Examples of a method of the etching treatment include a method by wet etching, which is described in paragraphs 0048 to 0054 of JP2010-152155A, and a method by dry etching such as a known plasma etching.

In the above-described manufacturing method of a laminate, it is also preferable to use a substrate having a plurality of conductive layers on both surfaces, and sequentially or simultaneously form patterns on the conductive layers formed on both surfaces.

With such a configuration, it is possible to form a first conductive pattern on one surface of the substrate and form a second conductive pattern on the other surface. It is also preferable to form from both surfaces of the substrate by the roll-to-roll.

### Laminate

The laminate is a laminate obtained by the above-described method for manufacturing a laminate. The laminate includes a substrate and a photosensitive composition layer having a pattern including vias.

The above-described laminate is used, for example, in a semiconductor device. Examples of the semiconductor device include various semiconductor devices such as a semiconductor package provided in an electrical product (for example, a computer, a mobile phone, a digital camera, and a television) and a vehicle (for example, a motorcycle, an automobile, a train, a ship, and an airplane).

### Manufacturing Method of Semiconductor Package

The above-described manufacturing method of a laminate can be suitably applied as a manufacturing method of a semiconductor package.

Examples of the manufacturing method of a semiconductor package include a known manufacturing method such as a manufacturing method of a build-up substrate.

Specific examples thereof include a manufacturing method including the step Z1 to the step Z4 in this order.

Step Z1: step of forming a photosensitive composition layer on a substrate having a conductive layer

Step Z2: step of forming a pattern having vias in the photosensitive composition layer

Step Z3: step of heat-treating the above-described pattern

Step Z4: step of forming a circuit pattern on the pattern

Examples of the step Z1 to the step Z3 in the manufacturing method of a semiconductor package include the above-described step 1 to the above-described step 3.

### Step Z4

The step Z4 is a step of forming a circuit pattern on the above-described pattern.

As a method of forming the circuit pattern, a semi-additive process is preferable from the viewpoint that a fine wiring can be formed. Examples of the semi-additive process include the following methods.

First, a seed layer is formed by performing an electroless copper plating treatment on the entire surface of the via bottom, the via wall surface, and the pattern after the above-described step Z3 using a palladium catalyst or the like.

The above-described seed layer is for forming a power feeding layer for performing the electrolytic copper plating, and a thickness of the seed layer is preferably 0.1 to 2.0 μm. In a case where the thickness of the above-described seed layer is 0.1 μm or more, the tendency is that the deterioration in connection insulating reliability during the electroless copper plating can be suppressed; and in a case where the thickness of the above-described seed layer is 2.0 μm or less, the tendency is that it is not necessary to increase the etching amount in a case of flash-etching the seed layer between the wirings, and the damage to the wirings during the etching can be suppressed.

The electroless copper plating treatment is performed by precipitating metallic copper on the surface of the pattern having a via by a reaction between copper ions and a reducing agent.

Examples of the electroless plating treatment method and the electrolytic plating treatment method include known plating treatment methods.

As the catalyst in the electroless plating treatment step, a palladium-tin mixed catalyst is preferable. An average primary particle diameter of the above-described mixed catalyst is preferably 10 nm or less. In addition, as the plating composition of the electroless plating treatment step, it is preferable to contain hypophosphorous acid as a reducing agent.

Examples of a commercially available product of the electroless copper plating liquid include “MSK-DK” manufactured by Atotech Japan K.K. and “SULKACUP (registered trademark) PEA ver. 4” series manufactured by Uemura Kogyo Co., Ltd.

It is also preferable that, after the electroless copper plating treatment, the surface of the photosensitive composition layer in the transfer film on the side opposite to the temporary support is thermocompression-bonded to the electroless copper plating by a roll laminator.

From the viewpoint that the thickness of the above-described photosensitive composition layer can be higher than the wiring height after the electro copper plating, the thickness of the photosensitive composition layer is preferably 5 to 30 μm.

After the thermal compression bonding of the transfer film, the photosensitive composition layer is exposed through, for example, a mask on which a desired wiring pattern is drawn. Examples of the above-described exposure method include the exposure method in the step 2-1.

After the exposure, the temporary support of the transfer film is peeled off, and the exposed photosensitive composition layer is developed with a developer to form a pattern. In addition, after the pattern is formed, a development residue of the photosensitive composition may be removed using plasma or the like.

After the development, the copper circuit layer is formed and the via filling is performed by performing the electro copper plating.

After the electro copper plating, the pattern is peeled off using an alkaline aqueous solution or an amine-based release agent.

After the pattern is peeled off, the seed layer between the wirings is removed (flash etching).

The flash etching is performed using, for example, an oxidative solution containing sulfuric acid and an acidic solution such as hydrogen peroxide. Examples of the oxidative solution include “SAC” manufactured by JCU CORPORATION and “CPE-800” manufactured by MITSUBISHI GAS CHEMICAL COMPANY, INC. After the flash etching, removal of palladium or the like adhering to a part between the wirings is performed as necessary. The removal of palladium can be performed using an acidic solution such as nitric acid and hydrochloric acid.

It is preferable to perform a post-baking treatment after the peeling of the pattern or after the flash etching step. The post-baking treatment sufficiently thermosets the unreacted thermosetting component, and further improves the electrical insulation reliability, the curing characteristics, and the adhesive strength with the plated copper.

The thermal curing conditions are preferably a curing temperature of 150° C. to 240° C. and a curing time of 15 to 500 minutes.

The method for manufacturing the semiconductor package may include a roughening step of roughening a pattern having a via. It is preferable that the above-described roughening step is performed after the above-described step Z3 and before the above-described step Z4. By performing the roughening step, the above-described patterned surface can be roughened, and the adhesiveness with the circuit wiring can be improved. In addition, the smearing can be removed at the same time.

Examples of the roughening step include a known desmutting treatment, and a treatment of bringing the roughening liquid into contact is preferable.

Examples of the roughening liquid include a roughening liquid containing chromium and sulfuric acid, a roughening liquid containing an alkali permanganate (for example, a sodium permanganate roughening liquid or the like), and a roughening liquid containing sodium fluoride, chromium, and sulfuric acid.

Each of the above-described steps is repeated according to the required number of layers, thereby manufacturing a semiconductor package. In addition, it is preferable that a solder resist is formed on the outermost layer.

### Semiconductor Package

The semiconductor package is not particularly limited as long as it includes the specific film.

The semiconductor package preferably includes the above-described laminate, and more preferably is manufactured by using the above-described manufacturing method of a semiconductor package.

In the semiconductor package, the specific film may be used as an insulating film, or may be used as an organic interposer or an insulating film in a so-called build-up substrate. Examples

Hereinbelow, the present invention will be described in more detail with reference to Examples.

The material, the amount used, the proportion, the process contents, the process procedure, and the like shown in the following examples can be appropriately changed, within a range not departing from the gist of the present invention. Therefore, the scope of the present invention should not be construed as being limited to Examples shown below.

### Preparation of Photosensitive Composition

Various components were mixed to have the blending amounts (blending amounts of solid content ratios) shown in the tables below, thereby preparing a mixture. Next, the above-described mixture was diluted with a mixed solvent having a concentration of methyl ethyl ketone (MEK) of 25% by mass and a concentration of NMP of 75% by mass, such that the concentration of solid contents was 30% by mass, thereby preparing photosensitive compositions of Examples 1 to 109 and Comparative Examples 1 to 4.

Hereinafter, various components contained in the photosensitive composition will be described.

### Resin

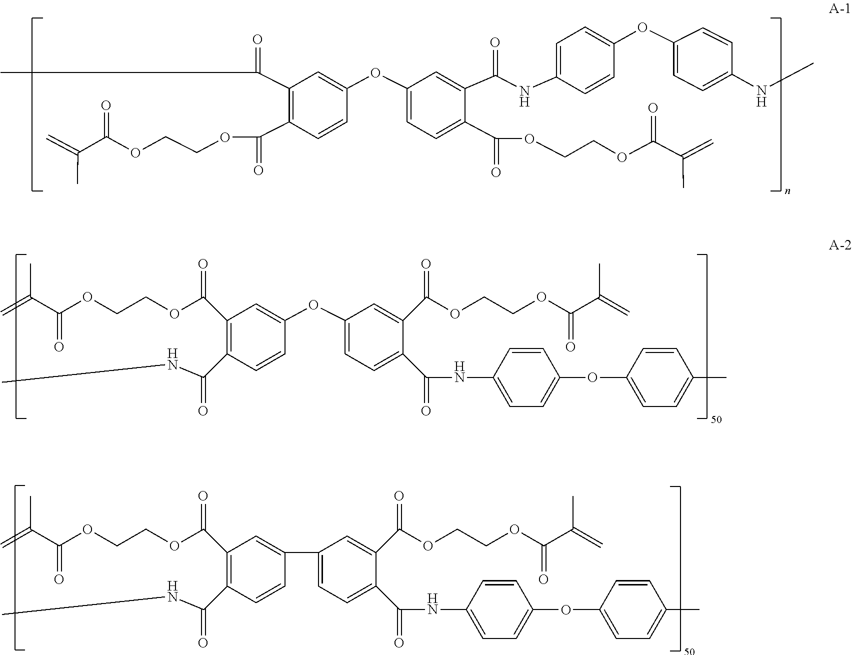

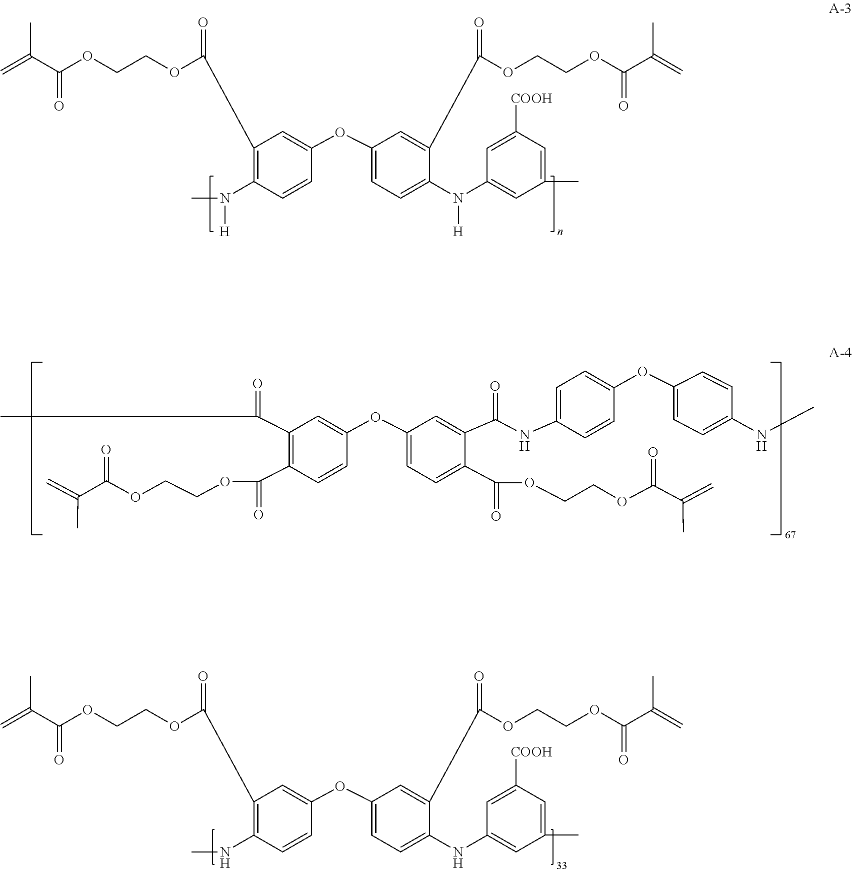

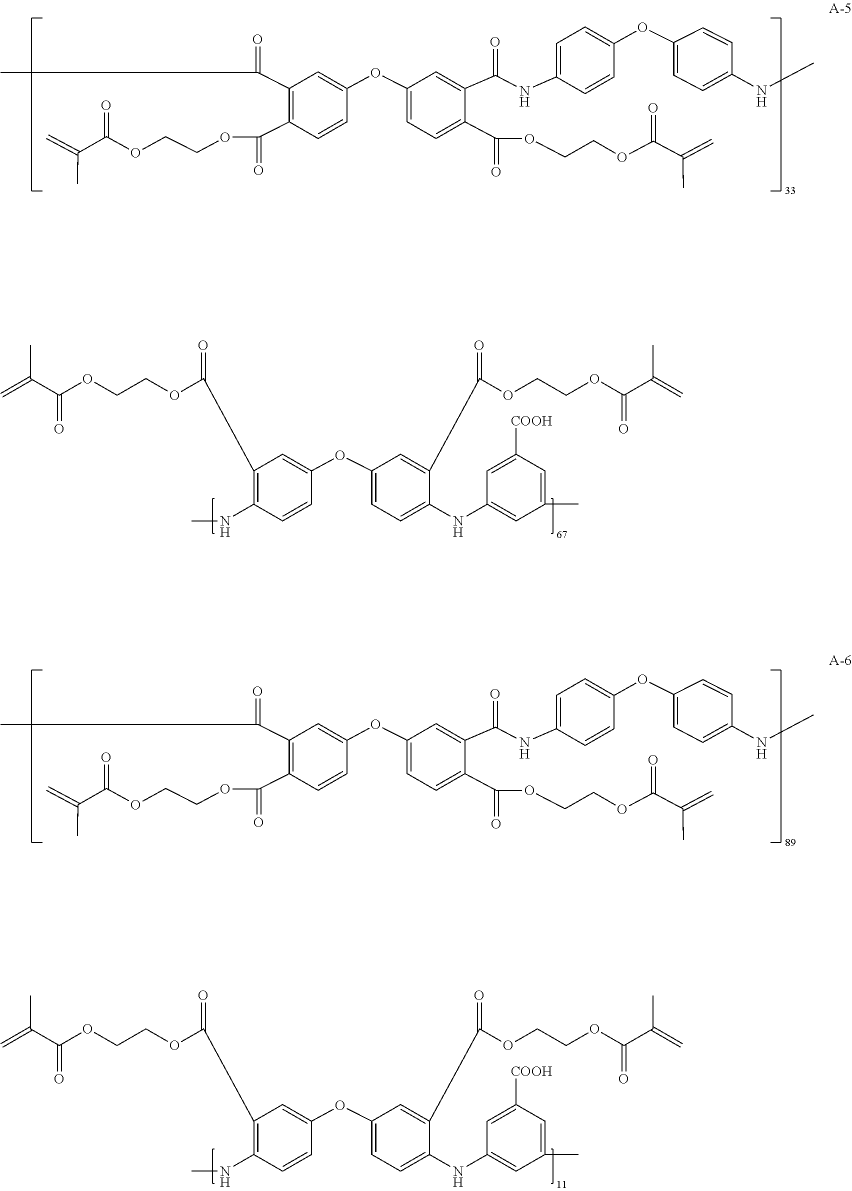

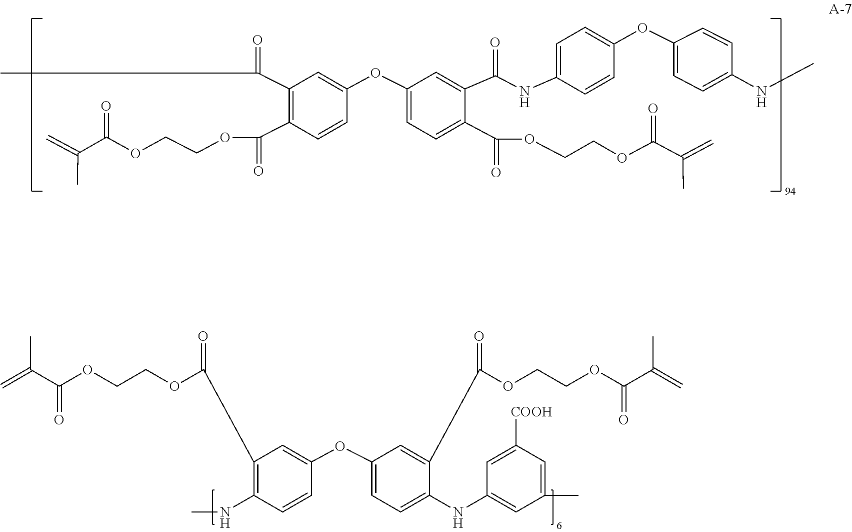

### Synthesis Method of Resin A-1

4,4′-oxydiphthalic acid anhydride (used after being dried at 140° C. for 12 hours; 20.0 g, 64.5 mmol), 2-hydroxyethyl methacrylate (16.8 g, 129 mmol), hydroquinone (0.05 g), pyridine (20.4 g, 258 mmol), and diethylene glycol dimethyl ether (100 g) were mixed, and the mixture was stirred at 60° C. for 18 hours to obtain a reaction mixture (a diester of 4,4′ -oxydiphthalic acid and 2-hydroxyethyl methacrylate). Next, a chlorination reaction was performed on the obtained diester using thionyl chloride (SOCl₂), thereby obtaining a reaction mixture.

Next, a solution obtained by dissolving 4,4′-diaminodiphenyl ether (11.08 g, 58.7 mmol) in N-methylpyrrolidone (100 mL) was added dropwise to the reaction mixture at −5° C. to 0° C. over 20 minutes. The reaction mixture was reacted at 0° C. for 1 hour, ethanol (70 g) was added thereto, and the mixture was stirred at room temperature for 1 day. The obtained reaction solution was added to water (5 L), and the mixture was stirred at a speed of 5,000 rpm for 15 minutes to obtain a precipitate which was a crude polymer. The precipitate collected from the above-described mixture was stirred in water (3 L) for 30 minutes, and collected by filtration again. The obtained precipitate was dried at 45° C. for 3 days under reduced pressure to obtain the resin A-1 which was a polyimide precursor.

The resin A-1 had a weight-average molecular weight (Mw) of 18,000 and an acid value of 0 mgKOH/g.

### Synthesis Method of Resin A-2

4,4′-oxydiphthalic acid dianhydride (77.6 g) and diphenyl-3,3′,4,4′-tetracarboxylic acid dianhydride (73.6 g) were charged into a 2 L separable flask, 2-hydroxyethyl methacrylate (134.0 g) and γ-butyrolactone (400 mL) were added thereto with stirring at room temperature, and pyridine (79.1 g) further was added thereto to obtain a reaction mixture. After the heat generation due to the reaction was stopped, the reaction mixture was further allowed to cool to room temperature and left to stand for 16 hours. Next, a solution obtained by dissolving dicyclohexylcarbodiimide (DCC, 206.3 g) in γ-butyrolactone (180 mL) was added to the reaction mixture over 40 minutes with stirring under ice cooling. Subsequently, a liquid obtained by suspending 4,4′-oxydianiline (ODA, Mw=200.24, 93.0 g) in γ-butyrolactone (350 mL) was added thereto over 60 minutes with stirring. After further stirring at room temperature for 2 hours, ethanol (30 mL) was added thereto and stirred for 1 hour, and then y-butyrolactone (400 mL) was added thereto. The precipitate formed in the reaction mixture was removed by filtration to obtain a reaction solution. The obtained reaction solution was added to ethyl alcohol (3 L) to obtain a precipitate as a crude polymer. The obtained crude polymer was collected by filtration and dissolved in tetrahydrofuran (1.5 L) to obtain a crude polymer solution. The obtained crude polymer solution was purified using an anion exchange resin (Amberlite TM15, manufactured by Organo Corporation) to obtain a polymer solution. The obtained polymer solution was added dropwise to water (28 L) to precipitate a polymer, and the obtained precipitate was collected by filtration and then vacuum-dried to obtain the resin A-2 as a powdery polyimide precursor.

The resin A-2 had a weight-average molecular weight (Mw) of 22,000 and an acid value of 0 mgKOH/g. The content of imide groups in the polyimide obtained from the resin A-2 was 27.4% by mass per repeating unit.

### Synthesis Method of Resin A-3

A resin A-3 was synthesized according to the synthesis method of the resin A-1, except that 4,4′-diaminodiphenyl ether (11.08 g, 58.7 mmol) was changed to 3,5-diaminobenzoic acid (8.94 g, 58.7 mmol).

The resin A-3 had a weight-average molecular weight (Mw) of 20,000 and an acid value of 90 mgKOH/g.

### Synthesis Method of Resin A-4

A resin A-4 was synthesized according to the synthesis method of the resin A-1, except that 4,4′-diaminodiphenyl ether (11.08 g, 58.7 mmol) was changed to 4,4′-diaminodiphenyl ether (7.39 g, 39.1 mmol) and 3,5-diaminobenzoic acid (2.98 g, 19.6 mmol).

The resin A-4 had a weight-average molecular weight (Mw) of 18,000. The acid value was 30 mgKOH/g.

### Synthesis Method of Resin A-5

A resin A-5 was synthesized according to the synthesis method of the resin A-1, except that 4,4′-diaminodiphenyl ether (11.08 g, 58.7 mmol) was changed to 4,4′-diaminodiphenyl ether (3.69 g, 19.6 mmol) and 3,5-diaminobenzoic acid (5.96 g, 39.1 mmol).

The resin A-5 had a weight-average molecular weight (Mw) of 23,000. The acid value was 60 mgKOH/g.

### Synthesis Method of Resin A-6

A resin A-6 was synthesized according to the synthesis method of the resin A-1, except that 4,4′-diaminodiphenyl ether (11.08 g, 58.7 mmol) was changed to 4,4′-diaminodiphenyl ether (9.85 g, 52.2 mmol) and 3,5-diaminobenzoic acid (0.99 g, 6.5 mmol).

The resin A-6 had a weight-average molecular weight (Mw) of 17,000. The acid value was 10 mgKOH/g.

### Synthesis Method of Resin A-7

A resin A-7 was synthesized according to the synthesis method of the resin A-1, except that 4,4′-diaminodiphenyl ether (11.08 g, 58.7 mmol) was changed to 4,4′-diaminodiphenyl ether (10.5 g, 55.4 mmol) and 3,5-diaminobenzoic acid (0.50 g, 3.3 mmol).

The resin A-7 had a weight-average molecular weight (Mw) of 21,000. The acid value was 5 mgKOH/g.

The acid value of each of the above-described resins was determined by dissolving 0.1 g of the synthesized resin in 20 ml of NMP and titrating the solution with KOH using thymolphthalein as an indicator, based on JIS K0070.

In a case where the dissolution rate of each resin in 200 mL of 2.38% by mass TMAHaq at 23° C. was determined by the above-described method, the dissolution rate was 1 mg/min or less.

### Polymerizable Compound

SR205NS: bifunctional polymerizable compound, manufactured by Sartomer Company Inc., triethylene glycol dimethacrylate
SR209: bifunctional polymerizable compound, manufactured by Sartomer Company Inc., tetraethylene glycol dimethacrylate
BPE-100: bifunctional polymerizable compound, manufactured by Shin-Nakamura Chemical Co., Ltd., ethoxylated bisphenol A dimethacrylate
VISCOAT #295: trifunctional polymerizable compound, manufactured by Osaka Organic Chemical Industry Ltd., trimethylolpropane triacrylate
TMPTMA: trifunctional polymerizable compound, manufactured by Tokyo Chemical Industry Co., Ltd., trimethylolpropane trimethacrylate
M-130G: monofunctional polymerizable compound, manufactured by Shin-Nakamura Chemical Co., Ltd., methoxypolyethylene glycol methacrylate
AM-130G: monofunctional polymerizable compound, manufactured by Shin-Nakamura Chemical Co., Ltd., methoxypolyethylene glycol #600 acrylate
SR355NS: tetrafunctional polymerizable compound, manufactured by Sartomer Company Inc., ditrimethylolpropane tetraacrylate
A-9550:5- or 6-functional polymerizable compound, manufactured by Shin-Nakamura Chemical Co., Ltd., dipentaerythritol polyacrylate
DPHA: hexafunctional polymerizable compound, manufactured by Tokyo Chemical Industry Co., Ltd., dipentaerythritol hexaacrylate

### Specific Compound and Comparative Compound

Compounds C-1 to C-5 are specific compounds, and compound C-9 is a compound different from the specific compound.
Compound C-1: TR-HABI 101, manufactured by Tronly
Compound C-2: TR-HABI 102, manufactured by Tronly
Compound C-3: TR-HABI 107, manufactured by Tronly
Compound C-4: TR-HABI 103, manufactured by Tronly
Compound C-5: TR-HABI 104, manufactured by Tronly
Compound C-9: Irgacure OXE-02, manufactured by BASF SE

### Other Additives

Compound D-1: chain transfer agent, the following compound

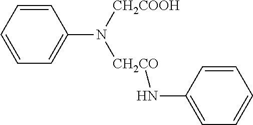

MEHQ: polymerization inhibitor, 4-methoxyphenol
Phenothiazine: polymerization inhibitor
EAB-F: sensitizer, 4,4′-bis(diethylamino) benzophenone
Compound G-1: thermal-base generator, the following compound

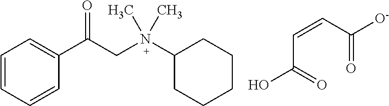

F-551A: fluorine-based surfactant, MEGAFACE (registered trademark) F551A, manufactured by DIC Corporation
S-506: silicone-based surfactant, manufactured by DIC Corporation
HAT: rust inhibitor, 5-amino-1H-tetrazole
Compound J-1: the following compound

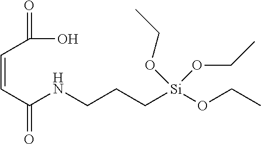 [SMILES: CCO[Si](CCCNC(=O)/C=C\C(=O)O)(OCC)OCC]

YA050C-MJE: filler, silicon dioxide (spherical silica slurry), average particle diameter: 50 nm, manufactured by Admatechs Co., Ltd.

### Production of Transfer Film

The prepared photosensitive composition was applied onto a temporary support (QS62, manufactured by Toray Industries, Inc., PET film having a thickness of 16 μm) and dried at 100° C. to form a photosensitive composition layer. The film thickness of the photosensitive composition layer was set to 12 μm after drying. Next, a protective film (manufactured by Oji F-Tex Co., Ltd., polypropylene film, FG-201, thickness: 30 μm) was bonded to a surface of the photosensitive composition layer opposite to the temporary support, thereby obtaining a transfer film.

### Evaluation

Using the obtained photosensitive composition or transfer film of each of Examples and Comparative Examples, the resolution of the photosensitive composition, the level difference conformability of the transfer film, and the migration resistance and the linear expansion coefficient of the formed film were evaluated.

### Resolution

Using a copper-clad polyimide film (METALLOYAL, manufactured by Toray Industries, Inc.) as a substrate, the above-described transfer film was laminated on the substrate to obtain a laminate having a substrate/photosensitive composition layer/temporary support. The lamination was carried out under the following conditions using a vacuum laminator manufactured by MCK Co., Ltd.: a substrate temperature of 50° C., a rubber roller temperature of 100° C., a linear pressure of 3 N/cm, and a transportation speed of 1 m/min. The obtained laminate was exposed from the temporary support side through a mask having a pattern of L/S (line/space)=100/100 (μm/μm) (using a high-pressure mercury lamp, at an interval of 5 mJ/cm² with an integrated illuminance of 0 to 1,000 mJ/cm² measured with an illuminance meter having a wavelength of 365 nm). The temporary support was peeled off at a timing of 30 minutes after the exposure, the obtained sample was immersed in cyclopentanone at 23° C. for 120 seconds, and then immersed in propylene glycol monomethyl ether acetate (PGMEA) at 23° C. for 30 seconds to remove the non-exposed portion, thereby forming a pattern. The obtained pattern of L/S=100/100 (um/um) was observed with an optical microscope, and the exposure amount at which the line width of the pattern was closest to the line width (100 μm) of the mask was determined as the optimum exposure amount.

Next, the above-described laminate having a substrate/photosensitive composition layer/temporary support was exposed from the temporary support side through a mask having a pattern of L/S=7/7 (um/um) (using a high-pressure mercury lamp, the above-described optimum exposure amount). The temporary support was peeled off at a timing of 30 minutes after the exposure, the obtained sample was immersed in cyclopentanone at 23° C. for 120 seconds, and then immersed in PGMEA at 23° C. for 30 seconds to obtain a patterning sample. The patterning sample was observed with a scanning electron microscope (SEM), and the resolution was evaluated according to the following standard. In a case where 20 patterns were observed and the number of patterns in which defects such as pattern collapse, pattern lifting, and connection between patterns were observed was 2 or less, it was determined that the pattern could be formed. In practice, the resolution is preferably evaluated as A or higher.

A: A pattern of L/S=7/7 (μm/μm) could be formed.
B: A pattern of L/S=7/7 (μm/μm) could not be formed.

### Step Followability

A test substrate was prepared by forming a copper pattern (L/S=25/25 (μm/μm)) having a thickness of 2 μm in a comb shape on a silicon wafer.

The transfer film from which the protective film had been peeled off was laminated such that the photosensitive composition layer faced the surface of the test substrate on which the wiring was formed. The lamination was carried out under the following conditions using a vacuum laminator manufactured by MCK Co., Ltd.: a substrate temperature of 50° C., a rubber roller temperature of 100° C., a linear pressure of 3 N/cm, and a transportation speed of 1m/min. The copper patterns after lamination were observed with an optical microscope, and the level difference conformability was evaluated according to the following standard.

A: No air entered between the wirings, or a very small amount of air entered between the wirings (the area of air bubbles was less than 10% of the area between the wirings).

B: A part of air entered between the wirings (the area of air bubbles was 10% or more and less than 40% of the area between the wirings).

C: Air entered between the wirings (the area of air bubbles was 40% or more of the area between the wirings).

### Migration Resistance

A test substrate was prepared by forming a copper pattern (L/S=25/25 (μm/μm)) having a thickness of 2.0 μm in a comb shape on a silicon wafer. Each photosensitive composition was applied onto the test substrate and dried such that the thickness of the photosensitive composition layer on the copper pattern was 12 μm, thereby forming a photosensitive composition layer.

Next, the obtained photosensitive composition layer was exposed using an ultra-high pressure mercury lamp. At this time, the integrated exposure amount measured with an illuminance meter at a wavelength of 365 nm was 300 mJ/cm². After the exposure, a heat treatment was performed at 200° C. for 100 minutes in a nitrogen atmosphere to produce an evaluation sample.

10 evaluation samples were produced, and using a HAST tester, the evaluation samples were installed in a chamber at 130° C. and 85% RH (relative humidity), and the time and the number of times when migration occurred when a voltage of 3.3 V was applied were confirmed, and the migration resistance was evaluated according to the following standard.

In a sample in which the initial resistance value measured at room temperature (23° C.) was 1×10¹⁴Ω or more, it was counted that migration occurred at a point in time when the resistance value was 1×10³Ω or less. In practice, the migration resistance is preferably evaluated as C or higher.

A: After 100 hours, no migration was confirmed in any of the samples, and after 200 hours, the number of samples in which migration was confirmed was 4 or less.

B: After 100 hours, the number of samples in which migration was confirmed was 1 to 4, and after 200 hours, the number of samples in which migration was confirmed was 1 to 4.

C: After 100 hours, the number of samples in which migration was confirmed was 1 to 4, and after 200 hours, the number of samples in which migration was confirmed was 5 to 10.

D: After 100 hours, the number of samples in which migration was confirmed was 5 to 10, and after 200 hours, the number of samples in which migration was confirmed was 5 to 10.

### Linear Expansion Coefficiency

A copper-clad polyimide film (Metalloyal, manufactured by Toray Industries, Inc.) was used as a substrate, and the prepared photosensitive composition was applied onto the substrate and dried to obtain a laminate having a photosensitive composition layer with a thickness of 30.0 μm on the substrate. The obtained laminate was exposed from the side of the photosensitive composition layer opposite to the substrate side (high-pressure mercury lamp, integrated illuminance of 300 mJ/cm² measured with an illuminance meter having a wavelength of 365 nm), was heat-treated in an oven (200° C., 100 minutes), was immersed in 2M hydrochloric acid for 8 hours for a peeling treatment, was rinsed (with pure water at room temperature for 1 hour), and was peeled off from the substrate to obtain a self-supporting film derived from the photosensitive composition layer. In a case where the self-supporting film could not be peeled off in the above-described peeling treatment, the film was further immersed in a 2 M hydrochloric acid for approximately 1 week and peeled off. The obtained self-supporting film was cut into strips to obtain a measurement sample.

The produced self-supporting film was cut into a strip shape (19 mm×5 mm), and a coefficient of thermal expansion was measured using a TMA (thermomechanical analyzer, “TMA450EM” manufactured by TA Instruments). The measurement conditions were a temperature rising rate of 10° C./min, a chuck distance of 20 mm, and a load of 45 mN. The coefficient of thermal expansion was a value (ppm/K) in a range of 50° C. to 150° C. during temperature rising, and was obtained as an average value in a case of being measured three times.

The linear expansion coefficient was evaluated according to the following evaluation standard.

A: linear expansion coefficient was 35 ppm/K or less.
B: linear expansion coefficient was more than 35 ppm/K.

### Results

The formulations and evaluation results in the photosensitive compositions are shown in the following tables.

Table 2 is a continuation of Table 1, and Table 3 is a continuation of Table 2. Table 5 is a continuation of Table 4, and Table 6 is a continuation of Table 5. For example, the photosensitive composition of Example 1 contained the resin A-1 and SR205NS described in Table 1, the compounds C-1, D-1, MEHQ, EAB-F, and G-1 described in Table 2, and HAT and J-1 described in Table 3.

In the tables, “Amount” indicates a content (% by mass) with respect to the total solid content of the photosensitive composition.

In the tables, the column of “B/A” indicates a mass ratio of the content of the polymerizable compound (B) to the content of the polyimide precursor (A) (content of polymerizable compound (B)/content of polyimide precursor (A)).

In the tables, (n) (n represents an integer) shown after the component of the polymerizable compound indicates the number of polymerizable groups contained in the polymerizable compound.

TABLE 1

| | Formulation | | | | | | | | | |
|---|---|---|---|---|---|---|---|---|---|---|
| | (A) Polyimide | | | | | | | | | |
| | precursor | | (B) Polymerizable compound | | | | | | Total | |
| | Name | Amount | Name | Amount | Name | Amount | Name | Amount | amount | B/A |
| Example 1 | A-1 | 60.0% | SR205NS (2) | 29.2% | — | 0.0% | — | 0.0% | 29.2% | 0.49 |
| Example 2 | A-1 | 65.0% | SR205NS (2) | 24.2% | — | 0.0% | — | 0.0% | 24.2% | 0.37 |
| Example 3 | A-1 | 71.0% | SR205NS (2) | 18.2% | — | 0.0% | — | 0.0% | 18.2% | 0.26 |
| Example 4 | A-1 | 75.0% | SR205NS (2) | 14.2% | — | 0.0% | — | 0.0% | 14.2% | 0.19 |
| Example 5 | A-1 | 80.0% | SR205NS (2) | 9.2% | — | 0.0% | — | 0.0% | 9.2% | 0.12 |
| Example 6 | A-1 | 73.7% | SR205NS (2) | 19.2% | — | 0.0% | — | 0.0% | 19.2% | 0.26 |
| Example 7 | A-1 | 72.2% | SR205NS (2) | 18.6% | — | 0.0% | — | 0.0% | 18.6% | 0.26 |
| Example 8 | A-1 | 71.2% | SR205NS (2) | 17.5% | — | 0.0% | — | 0.0% | 17.5% | 0.25 |
| Example 9 | A-1 | 72.2% | SR205NS (2) | 18.6% | — | 0.0% | — | 0.0% | 18.6% | 0.26 |
| Example 10 | A-1 | 71.9% | SR205NS (2) | 18.6% | — | 0.0% | — | 0.0% | 18.6% | 0.26 |
| Example 11 | A-1 | 71.5% | SR205NS (2) | 18.6% | — | 0.0% | — | 0.0% | 18.6% | 0.26 |
| Example 12 | A-1 | 72.7% | SR205NS (2) | 18.6% | — | 0.0% | — | 0.0% | 18.6% | 0.26 |
| Example 13 | A-1 | 71.7% | SR205NS (2) | 18.6% | — | 0.0% | — | 0.0% | 18.6% | 0.26 |
| Example 14 | A-1 | 70.7% | SR205NS (2) | 18.6% | — | 0.0% | — | 0.0% | 18.6% | 0.26 |
| Example 15 | A-1 | 60.0% | SR209 (2) | 29.2% | — | 0.0% | — | 0.0% | 29.2% | 0.49 |
| Example 16 | A-1 | 65.0% | SR209 (2) | 24.2% | — | 0.0% | — | 0.0% | 24.2% | 0.37 |
| Example 17 | A-1 | 71.0% | SR209 (2) | 18.2% | — | 0.0% | — | 0.0% | 18.2% | 0.26 |
| Example 18 | A-1 | 75.0% | SR209 (2) | 14.2% | — | 0.0% | — | 0.0% | 14.2% | 0.19 |
| Example 19 | A-1 | 80.0% | SR209 (2) | 9.2% | — | 0.0% | — | 0.0% | 9.2% | 0.12 |
| Example 20 | A-1 | 73.7% | SR209 (2) | 19.2% | — | 0.0% | — | 0.0% | 19.2% | 0.26 |
| Example 21 | A-1 | 72.2% | SR209 (2) | 18.6% | — | 0.0% | — | 0.0% | 18.6% | 0.26 |
| Example 22 | A-1 | 71.2% | SR209 (2) | 17.5% | — | 0.0% | — | 0.0% | 17.5% | 0.25 |
| Example 23 | A-1 | 72.2% | SR209 (2) | 18.6% | — | 0.0% | — | 0.0% | 18.6% | 0.26 |
| Example 24 | A-1 | 71.9% | SR209 (2) | 18.6% | — | 0.0% | — | 0.0% | 18.6% | 0.26 |
| Example 25 | A-1 | 71.5% | SR209 (2) | 18.6% | — | 0.0% | — | 0.0% | 18.6% | 0.26 |
| Example 26 | A-1 | 72.7% | SR209 (2) | 18.6% | — | 0.0% | — | 0.0% | 18.6% | 0.26 |
| Example 27 | A-1 | 71.7% | SR209 (2) | 18.6% | — | 0.0% | — | 0.0% | 18.6% | 0.26 |
| Example 28 | A-1 | 70.7% | SR209 (2) | 18.6% | — | 0.0% | — | 0.0% | 18.6% | 0.26 |
| Example 29 | A-1 | 71.3% | SR205NS (2) | 18.2% | — | 0.0% | — | 0.0% | 18.2% | 0.26 |
| Example 30 | A-1 | 72.5% | SR209 (2) | 18.6% | — | 0.0% | — | 0.0% | 18.6% | 0.26 |
| Example 31 | A-1 | 60.0% | SR205NS (2) | 29.2% | — | 0.0% | — | 0.0% | 29.2% | 0.49 |
| Example 32 | A-1 | 65.0% | SR205NS (2) | 24.2% | — | 0.0% | — | 0.0% | 24.2% | 0.37 |
| Example 33 | A-1 | 71.0% | SR205NS (2) | 18.2% | — | 0.0% | — | 0.0% | 18.2% | 0.26 |
| Example 34 | A-1 | 75.0% | SR205NS (2) | 14.2% | — | 0.0% | — | 0.0% | 14.2% | 0.19 |
| Example 35 | A-1 | 80.0% | SR205NS (2) | 9.2% | — | 0.0% | — | 0.0% | 9.2% | 0.12 |
| Example 36 | A-1 | 73.7% | SR205NS (2) | 19.2% | — | 0.0% | — | 0.0% | 19.2% | 0.26 |
| Example 37 | A-1 | 72.2% | SR205NS (2) | 18.6% | — | 0.0% | — | 0.0% | 18.6% | 0.26 |
| Example 38 | A-1 | 71.2% | SR205NS (2) | 17.5% | — | 0.0% | — | 0.0% | 17.5% | 0.25 |
| Example 39 | A-1 | 72.2% | SR205NS (2) | 18.6% | — | 0.0% | — | 0.0% | 18.6% | 0.26 |
| Example 40 | A-1 | 71.9% | SR205NS (2) | 18.6% | — | 0.0% | — | 0.0% | 18.6% | 0.26 |
| Example 41 | A-1 | 71.5% | SR205NS (2) | 18.6% | — | 0.0% | — | 0.0% | 18.6% | 0.26 |
| Example 42 | A-1 | 72.7% | SR205NS (2) | 18.6% | — | 0.0% | — | 0.0% | 18.6% | 0.26 |
| Example 43 | A-1 | 71.7% | SR205NS (2) | 18.6% | — | 0.0% | — | 0.0% | 18.6% | 0.26 |
| Example 44 | A-1 | 70.7% | SR205NS (2) | 18.6% | — | 0.0% | — | 0.0% | 18.6% | 0.26 |
| Example 45 | A-1 | 60.0% | SR205NS (2) | 29.2% | — | 0.0% | — | 0.0% | 29.2% | 0.49 |
| Example 46 | A-1 | 65.0% | SR205NS (2) | 24.2% | — | 0.0% | — | 0.0% | 24.2% | 0.37 |
| Example 47 | A-1 | 71.0% | SR205NS (2) | 18.2% | — | 0.0% | — | 0.0% | 18.2% | 0.26 |
| Example 48 | A-1 | 75.0% | SR205NS (2) | 14.2% | — | 0.0% | — | 0.0% | 14.2% | 0.19 |
| Example 49 | A-1 | 80.0% | SR205NS (2) | 9.2% | — | 0.0% | — | 0.0% | 9.2% | 0.12 |
| Example 50 | A-1 | 73.7% | SR205NS (2) | 19.2% | — | 0.0% | — | 0.0% | 19.2% | 0.26 |
| Example 51 | A-1 | 72.2% | SR205NS (2) | 18.6% | — | 0.0% | — | 0.0% | 18.6% | 0.26 |
| Example 52 | A-1 | 71.2% | SR205NS (2) | 17.5% | — | 0.0% | — | 0.0% | 17.5% | 0.25 |
| Example 53 | A-1 | 72.2% | SR205NS (2) | 18.6% | — | 0.0% | — | 0.0% | 18.6% | 0.26 |
| Example 54 | A-1 | 71.9% | SR205NS (2) | 18.6% | — | 0.0% | — | 0.0% | 18.6% | 0.26 |
| Example 55 | A-1 | 71.5% | SR205NS (2) | 18.6% | — | 0.0% | — | 0.0% | 18.6% | 0.26 |
| Example 56 | A-1 | 72.7% | SR205NS (2) | 18.6% | — | 0.0% | — | 0.0% | 18.6% | 0.26 |
| Example 57 | A-1 | 71.7% | SR205NS (2) | 18.6% | — | 0.0% | — | 0.0% | 18.6% | 0.26 |
| Example 58 | A-1 | 70.7% | SR205NS (2) | 18.6% | — | 0.0% | — | 0.0% | 18.6% | 0.26 |

TABLE 2

| | Formulation | | | | | | | | | | | |
|---|---|---|---|---|---|---|---|---|---|---|---|---|
| | | | | | (E) | | | | | | | |
| | | | | | Polymer- | | | | | | | |
| | (C) Specific | | (D) Chain | | ization | | | | (G) Thermal- | | (H) | |
| | compound | | transfer agent | | inhibitor | | (F) Sensitizer | | base generator | | Surfactant | |
| | Name | Amount | Name | Amount | Name | Amount | Name | Amount | Name | Amount | Name | Amount |
| Example 1 | C-1 | 6.3% | D-1 | 0.5% | MEH | 0.3% | EAB-F | 0.1% | G-1 | 1.7% | — | 0.0% |
| | | | | | Q | | | | | | | |
| Example 2 | C-1 | 6.3% | D-1 | 0.5% | MEH | 0.3% | EAB-F | 0.1% | G-1 | 1.7% | — | 0.0% |
| | | | | | Q | | | | | | | |
| Example 3 | C-1 | 6.3% | D-1 | 0.5% | MEH | 0.3% | EAB-F | 0.1% | G-1 | 1.7% | — | 0.0% |
| | | | | | Q | | | | | | | |
| Example 4 | C-1 | 6.3% | D-1 | 0.5% | MEH | 0.3% | EAB-F | 0.1% | G-1 | 1.7% | — | 0.0% |
| | | | | | Q | | | | | | | |
| Example 5 | C-1 | 6.3% | D-1 | 0.5% | MEH | 0.3% | EAB-F | 0.1% | G-1 | 1.7% | — | 0.0% |
| | | | | | Q | | | | | | | |
| Example 6 | C-1 | 4.2% | D-1 | 0.5% | MEH | 0.2% | EAB-F | 0.1% | G-1 | 1.8% | — | 0.0% |
| | | | | | Q | | | | | | | |
| Example 7 | C-1 | 6.3% | D-1 | 0.5% | MEH | 0.3% | EAB-F | 0.1% | G-1 | 1.7% | — | 0.0% |
| | | | | | Q | | | | | | | |
| Example 8 | C-1 | 8.4% | D-1 | 0.5% | MEH | 0.4% | EAB-F | 0.1% | G-1 | 1.6% | — | 0.0% |
| | | | | | Q | | | | | | | |
| Example 9 | C-1 | 6.4% | D-1 | 0.5% | MEH | 0.3% | — | 0.0% | G-1 | 1.7% | — | 0.0% |
| | | | | | Q | | | | | | | |
| Example 10 | C-1 | 6.3% | D-1 | 0.5% | MEH | 0.4% | EAB-F | 0.3% | G-1 | 1.7% | — | 0.0% |
| | | | | | Q | | | | | | | |
| Example 11 | C-1 | 6.3% | D-1 | 0.5% | MEH | 0.5% | EAB-F | 0.6% | G-1 | 1.7% | — | 0.0% |
| | | | | | Q | | | | | | | |
| Example 12 | C-1 | 6.3% | — | 0.0% | MEH | 0.3% | EAB-F | 0.1% | G-1 | 1.7% | — | 0.0% |
| | | | | | Q | | | | | | | |
| Example 13 | C-1 | 6.3% | D-1 | 1.0% | MEH | 0.3% | EAB-F | 0.1% | G-1 | 1.7% | — | 0.0% |
| | | | | | Q | | | | | | | |
| Example 14 | C-1 | 6.3% | D-1 | 2.0% | MEH | 0.3% | EAB-F | 0.1% | G-1 | 1.7% | — | 0.0% |
| | | | | | Q | | | | | | | |
| Example 15 | C-1 | 6.3% | D-1 | 0.5% | MEH | 0.3% | EAB-F | 0.1% | G-1 | 1.7% | — | 0.0% |
| | | | | | Q | | | | | | | |
| Example 16 | C-1 | 6.3% | D-1 | 0.5% | MEH | 0.3% | EAB-F | 0.1% | G-1 | 1.7% | — | 0.0% |
| | | | | | Q | | | | | | | |
| Example 17 | C-1 | 6.3% | D-1 | 0.5% | MEH | 0.3% | EAB-F | 0.1% | G-1 | 1.7% | — | 0.0% |
| | | | | | Q | | | | | | | |
| Example 18 | C-1 | 6.3% | D-1 | 0.5% | MEH | 0.3% | EAB-F | 0.1% | G-1 | 1.7% | — | 0.0% |
| | | | | | Q | | | | | | | |
| Example 19 | C-1 | 6.3% | D-1 | 0.5% | MEH | 0.3% | EAB-F | 0.1% | G-1 | 1.7% | — | 0.0% |
| | | | | | Q | | | | | | | |
| Example 20 | C-1 | 4.2% | D-1 | 0.5% | MEH | 0.2% | EAB-F | 0.1% | G-1 | 1.8% | — | 0.0% |
| | | | | | Q | | | | | | | |
| Example 21 | C-1 | 6.3% | D-1 | 0.5% | MEH | 0.3% | EAB-F | 0.1% | G-1 | 1.7% | — | 0.0% |
| | | | | | Q | | | | | | | |
| Example 22 | C-1 | 8.4% | D-1 | 0.5% | MEH | 0.4% | EAB-F | 0.1% | G-1 | 1.6% | — | 0.0% |
| | | | | | Q | | | | | | | |
| Example 23 | C-1 | 6.4% | D-1 | 0.5% | MEH | 0.3% | — | 0.0% | G-1 | 1.7% | — | 0.0% |
| | | | | | Q | | | | | | | |
| Example 24 | C-1 | 6.3% | D-1 | 0.5% | MEH | 0.4% | EAB-F | 0.3% | G-1 | 1.7% | — | 0.0% |
| | | | | | Q | | | | | | | |
| Example 25 | C-1 | 6.3% | D-1 | 0.5% | MEH | 0.5% | EAB-F | 0.6% | G-1 | 1.7% | — | 0.0% |
| | | | | | Q | | | | | | | |
| Example 26 | C-1 | 6.3% | — | 0.0% | MEH | 0.3% | EAB-F | 0.1% | G-1 | 1.7% | — | 0.0% |
| | | | | | Q | | | | | | | |
| Example 27 | C-1 | 6.3% | D-1 | 1.0% | MEH | 0.3% | EAB-F | 0.1% | G-1 | 1.7% | — | 0.0% |
| | | | | | Q | | | | | | | |
| Example 28 | C-1 | 6.3% | D-1 | 2.0% | MEH | 0.3% | EAB-F | 0.1% | G-1 | 1.7% | — | 0.0% |
| | | | | | Q | | | | | | | |
| Example 29 | C-1 | 6.3% | D-1 | 0.5% | MEH | 0.3% | EAB-F | 0.1% | G-1 | 1.7% | — | 0.0% |
| | | | | | Q | | | | | | | |
| Example 30 | C-1 | 6.3% | D-1 | 0.5% | MEH | 0.3% | EAB-F | 0.1% | G-1 | 1.7% | — | 0.0% |
| | | | | | Q | | | | | | | |
| Example 31 | C-2 | 6.3% | D-1 | 0.5% | MEH | 0.3% | EAB-F | 0.1% | G-1 | 1.7% | — | 0.0% |
| | | | | | Q | | | | | | | |
| Example 32 | C-2 | 6.3% | D-1 | 0.5% | MEH | 0.3% | EAB-F | 0.1% | G-1 | 1.7% | — | 0.0% |
| | | | | | Q | | | | | | | |
| Example 33 | C-2 | 6.3% | D-1 | 0.5% | MEH | 0.3% | EAB-F | 0.1% | G-1 | 1.7% | — | 0.0% |
| | | | | | Q | | | | | | | |
| Example 34 | C-2 | 6.3% | D-1 | 0.5% | MEH | 0.3% | EAB-F | 0.1% | G-1 | 1.7% | — | 0.0% |
| | | | | | Q | | | | | | | |
| Example 35 | C-2 | 6.3% | D-1 | 0.5% | MEH | 0.3% | EAB-F | 0.1% | G-1 | 1.7% | — | 0.0% |
| | | | | | Q | | | | | | | |
| Example 36 | C-2 | 4.2% | D-1 | 0.5% | MEH | 0.2% | EAB-F | 0.1% | G-1 | 1.8% | — | 0.0% |
| | | | | | Q | | | | | | | |
| Example 37 | C-2 | 6.3% | D-1 | 0.5% | MEH | 0.3% | EAB-F | 0.1% | G-1 | 1.7% | — | 0.0% |
| | | | | | Q | | | | | | | |
| Example 38 | C-2 | 8.4% | D-1 | 0.5% | MEH | 0.4% | EAB-F | 0.1% | G-1 | 1.6% | — | 0.0% |
| | | | | | Q | | | | | | | |
| Example 39 | C-2 | 6.4% | D-1 | 0.5% | MEH | 0.3% | — | 0.0% | G-1 | 1.7% | — | 0.0% |
| | | | | | Q | | | | | | | |
| Example 40 | C-2 | 6.3% | D-1 | 0.5% | MEH | 0.4% | EAB-F | 0.3% | G-1 | 1.7% | — | 0.0% |
| | | | | | Q | | | | | | | |
| Example 41 | C-2 | 6.3% | D-1 | 0.5% | MEH | 0.5% | EAB-F | 0.6% | G-1 | 1.7% | — | 0.0% |
| | | | | | Q | | | | | | | |
| Example 42 | C-2 | 6.3% | — | 0.0% | MEH | 0.3% | EAB-F | 0.1% | G-1 | 1.7% | — | 0.0% |
| | | | | | Q | | | | | | | |
| Example 43 | C-2 | 6.3% | D-1 | 1.0% | MEH | 0.3% | EAB-F | 0.1% | G-1 | 1.7% | — | 0.0% |
| | | | | | Q | | | | | | | |
| Example 44 | C-2 | 6.3% | D-1 | 2.0% | MEH | 0.3% | EAB-F | 0.1% | G-1 | 1.7% | — | 0.0% |
| | | | | | Q | | | | | | | |
| Example 45 | C-3 | 6.3% | D-1 | 0.5% | MEH | 0.3% | EAB-F | 0.1% | G-1 | 1.7% | — | 0.0% |
| | | | | | Q | | | | | | | |
| Example 46 | C-3 | 6.3% | D-1 | 0.5% | MEH | 0.3% | EAB-F | 0.1% | G-1 | 1.7% | — | 0.0% |
| | | | | | Q | | | | | | | |
| Example 47 | C-3 | 6.3% | D-1 | 0.5% | MEH | 0.3% | EAB-F | 0.1% | G-1 | 1.7% | — | 0.0% |
| | | | | | Q | | | | | | | |
| Example 48 | C-3 | 6.3% | D-1 | 0.5% | MEH | 0.3% | EAB-F | 0.1% | G-1 | 1.7% | — | 0.0% |
| | | | | | Q | | | | | | | |
| Example 49 | C-3 | 6.3% | D-1 | 0.5% | MEH | 0.3% | EAB-F | 0.1% | G-1 | 1.7% | — | 0.0% |
| | | | | | Q | | | | | | | |
| Example 50 | C-3 | 4.2% | D-1 | 0.5% | MEH | 0.2% | EAB-F | 0.1% | G-1 | 1.8% | — | 0.0% |
| | | | | | Q | | | | | | | |
| Example 51 | C-3 | 6.3% | D-1 | 0.5% | MEH | 0.3% | EAB-F | 0.1% | G-1 | 1.7% | — | 0.0% |
| | | | | | Q | | | | | | | |
| Example 52 | C-3 | 8.4% | D-1 | 0.5% | MEH | 0.4% | EAB-F | 0.1% | G-1 | 1.6% | — | 0.0% |
| | | | | | Q | | | | | | | |
| Example 53 | C-3 | 6.4% | D-1 | 0.5% | MEH | 0.3% | — | 0.0% | G-1 | 1.7% | — | 0.0% |
| | | | | | Q | | | | | | | |
| Example 54 | C-3 | 6.3% | D-1 | 0.5% | MEH | 0.4% | EAB-F | 0.3% | G-1 | 1.7% | — | 0.0% |
| | | | | | Q | | | | | | | |
| Example 55 | C-3 | 6.3% | D-1 | 0.5% | MEH | 0.5% | EAB-F | 0.6% | G-1 | 1.7% | — | 0.0% |
| | | | | | Q | | | | | | | |
| Example 56 | C-3 | 6.3% | — | 0.0% | MEH | 0.3% | EAB-F | 0.1% | G-1 | 1.7% | — | 0.0% |
| | | | | | Q | | | | | | | |
| Example 57 | C-3 | 6.3% | D-1 | 1.0% | MEH | 0.3% | EAB-F | 0.1% | G-1 | 1.7% | — | 0.0% |
| | | | | | Q | | | | | | | |
| Example 58 | C-3 | 6.3% | D-1 | 2.0% | MEH | 0.3% | EAB-F | 0.1% | G-1 | 1.7% | — | 0.0% |
| | | | | | Q | | | | | | | |

TABLE 3

| | | | | | | | Evaluation | | | |
|---|---|---|---|---|---|---|---|---|---|---|
| | Formulation | | | | | | | | Step | Linear |
| | (I) Rust inhibitor | | (J) Other | | (Z) Filler | | Resolu- | Migration | follow- | expansion |
| | Name | Amount | Name | Amount | Name | Amount | tion | resistance | ability | coefficiency |
| Example 1 | HAT | 0.3% | J-1 | 1.6% | — | 0.0% | A | B | A | B |
| Example 2 | HAT | 0.3% | J-1 | 1.6% | — | 0.0% | A | B | A | B |
| Example 3 | HAT | 0.3% | J-1 | 1.6% | — | 0.0% | A | B | A | B |
| Example 4 | HAT | 0.3% | J-1 | 1.6% | — | 0.0% | A | B | B | B |
| Example 5 | HAT | 0.3% | J-1 | 1.6% | — | 0.0% | A | B | B | B |
| Example 6 | HAT | 0.3% | — | 0.0% | — | 0.0% | A | B | A | B |
| Example 7 | HAT | 0.3% | — | 0.0% | — | 0.0% | A | B | A | B |
| Example 8 | HAT | 0.3% | — | 0.0% | — | 0.0% | A | B | A | B |
| Example 9 | HAT | 0.3% | — | 0.0% | — | 0.0% | A | B | A | B |
| Example 10 | HAT | 0.3% | — | 0.0% | — | 0.0% | A | B | A | B |
| Example 11 | HAT | 0.3% | — | 0.0% | — | 0.0% | A | B | A | B |
| Example 12 | HAT | 0.3% | — | 0.0% | — | 0.0% | A | B | A | B |
| Example 13 | HAT | 0.3% | — | 0.0% | — | 0.0% | A | B | A | B |
| Example 14 | HAT | 0.3% | — | 0.0% | — | 0.0% | A | B | A | B |
| Example 15 | HAT | 0.3% | J-1 | 1.6% | — | 0.0% | A | B | A | B |
| Example 16 | HAT | 0.3% | J-1 | 1.6% | — | 0.0% | A | B | A | B |
| Example 17 | HAT | 0.3% | J-1 | 1.6% | — | 0.0% | A | B | A | B |
| Example 18 | HAT | 0.3% | J-1 | 1.6% | — | 0.0% | A | B | B | B |
| Example 19 | HAT | 0.3% | J-1 | 1.6% | — | 0.0% | A | B | B | B |
| Example 20 | HAT | 0.3% | — | 0.0% | — | 0.0% | A | B | A | B |
| Example 21 | HAT | 0.3% | — | 0.0% | — | 0.0% | A | B | A | B |
| Example 22 | HAT | 0.3% | — | 0.0% | — | 0.0% | A | B | A | B |
| Example 23 | HAT | 0.3% | — | 0.0% | — | 0.0% | A | B | A | B |
| Example 24 | HAT | 0.3% | — | 0.0% | — | 0.0% | A | B | A | B |
| Example 25 | HAT | 0.3% | — | 0.0% | — | 0.0% | A | B | A | B |
| Example 26 | HAT | 0.3% | — | 0.0% | — | 0.0% | A | B | A | B |
| Example 27 | HAT | 0.3% | — | 0.0% | — | 0.0% | A | B | A | B |
| Example 28 | HAT | 0.3% | — | 0.0% | — | 0.0% | A | B | A | B |
| Example 29 | — | 0.0% | J-1 | 1.6% | — | 0.0% | A | B | A | B |
| Example 30 | — | 0.0% | — | 0.0% | — | 0.0% | A | B | A | B |
| Example 31 | HAT | 0.3% | J-1 | 1.6% | — | 0.0% | A | B | A | B |
| Example 32 | HAT | 0.3% | J-1 | 1.6% | — | 0.0% | A | B | A | B |
| Example 33 | HAT | 0.3% | J-1 | 1.6% | — | 0.0% | A | B | A | B |
| Example 34 | HAT | 0.3% | J-1 | 1.6% | — | 0.0% | A | B | B | B |
| Example 35 | HAT | 0.3% | J-1 | 1.6% | — | 0.0% | A | B | B | B |
| Example 36 | HAT | 0.3% | — | 0.0% | — | 0.0% | A | B | A | B |
| Example 37 | HAT | 0.3% | — | 0.0% | — | 0.0% | A | B | A | B |
| Example 38 | HAT | 0.3% | — | 0.0% | — | 0.0% | A | B | A | B |
| Example 39 | HAT | 0.3% | — | 0.0% | — | 0.0% | A | B | A | B |
| Example 40 | HAT | 0.3% | — | 0.0% | — | 0.0% | A | B | A | B |
| Example 41 | HAT | 0.3% | — | 0.0% | — | 0.0% | A | B | A | B |
| Example 42 | HAT | 0.3% | — | 0.0% | — | 0.0% | A | B | A | B |
| Example 43 | HAT | 0.3% | — | 0.0% | — | 0.0% | A | B | A | B |
| Example 44 | HAT | 0.3% | — | 0.0% | — | 0.0% | A | B | A | B |
| Example 45 | HAT | 0.3% | J-1 | 1.6% | — | 0.0% | A | A | A | B |
| Example 46 | HAT | 0.3% | J-1 | 1.6% | — | 0.0% | A | A | A | B |
| Example 47 | HAT | 0.3% | J-1 | 1.6% | — | 0.0% | A | A | A | B |
| Example 48 | HAT | 0.3% | J-1 | 1.6% | — | 0.0% | A | A | B | B |
| Example 49 | HAT | 0.3% | J-1 | 1.6% | — | 0.0% | A | A | B | B |
| Example 50 | HAT | 0.3% | — | 0.0% | — | 0.0% | A | A | A | B |
| Example 51 | HAT | 0.3% | — | 0.0% | — | 0.0% | A | A | A | B |
| Example 52 | HAT | 0.3% | — | 0.0% | — | 0.0% | A | A | A | B |
| Example 53 | HAT | 0.3% | — | 0.0% | — | 0.0% | A | A | A | B |
| Example 54 | HAT | 0.3% | — | 0.0% | — | 0.0% | A | A | A | B |
| Example 55 | HAT | 0.3% | — | 0.0% | — | 0.0% | A | A | A | B |
| Example 56 | HAT | 0.3% | — | 0.0% | — | 0.0% | A | A | A | B |
| Example 57 | HAT | 0.3% | — | 0.0% | — | 0.0% | A | A | A | B |
| Example 58 | HAT | 0.3% | — | 0.0% | — | 0.0% | A | A | A | B |

TABLE 4

| | Formulation | | | | | | | | | |
|---|---|---|---|---|---|---|---|---|---|---|
| | (A) Polyimide | | (B) Polymerizable compound | | | | | | | |
| | precursor | | | | | | | | Total | |
| | Name | Amount | Name | Amount | Name | Amount | Name | Amount | Amount | B/A |
| Example 59 | A-1 | 72.0% | SR205NS (2) | 18.6% | — | 0.0% | — | 0.0% | 18.6% | 0.26 |
| Example 60 | A-1 | 72.0% | SR205NS (2) | 18.6% | — | 0.0% | — | 0.0% | 18.6% | 0.26 |
| Example 61 | A-1 | 72.2% | SR205NS (2) | 18.6% | — | 0.0% | — | 0.0% | 18.6% | 0.26 |
| Example 62 | A-1 | 70.5% | SR205NS (2) | 18.6% | — | 0.0% | — | 0.0% | 18.6% | 0.26 |
| Example 63 | A-2 | 65.0% | SR205NS (2) | 24.2% | — | 0.0% | — | 0.0% | 24.2% | 0.37 |
| Example 64 | A-2 | 71.0% | SR205NS (2) | 18.2% | — | 0.0% | — | 0.0% | 18.2% | 0.26 |
| Example 65 | A-2 | 72.2% | SR205NS (2) | 18.6% | — | 0.0% | — | 0.0% | 18.6% | 0.26 |
| Example 66 | A-2 | 71.9% | SR205NS (2) | 18.6% | — | 0.0% | — | 0.0% | 18.6% | 0.26 |
| Example 67 | A-2 | 70.7% | SR205NS (2) | 18.6% | — | 0.0% | — | 0.0% | 18.6% | 0.26 |
| Example 68 | A-2 | 71.2% | SR209 (2) | 17.5% | — | 0.0% | — | 0.0% | 17.5% | 0.25 |
| Example 69 | A-1 | 72.2% | BPE-100 (2) | 18.6% | — | 0.0% | — | 0.0% | 18.6% | 0.26 |
| Example 70 | A-1 | 72.2% | VISCOAT | 18.6% | — | 0.0% | — | 0.0% | 18.6% | 0.26 |
| | | | #295 (3) | | | | | | | |
| Example 71 | A-1 | 72.2% | TMPTMA (3) | 18.6% | — | 0.0% | — | 0.0% | 18.6% | 0.26 |
| Example 72 | A-1 | 72.2% | SR205NS (2) | 16.0% | M-130G (1) | 2.6% | — | 0.0% | 18.6% | 0.26 |
| Example 73 | A-1 | 72.2% | SR205NS (2) | 14.0% | AM-130G (1) | 4.6% | | 0.0% | 18.6% | 0.26 |
| Example 74 | A-1 | 72.2% | SR205NS (2) | 9.3% | BPE-100 (2) | 9.3% | | 0.0% | 18.6% | 0.26 |
| Example 75 | A-1 | 72.2% | SR205NS (2) | 9.3% | VISCOAT# | 9.3% | — | 0.0% | 18.6% | 0.26 |
| | | | | | 295 (3) | | | | | |
| Example 76 | A-1 | 72.2% | SR205NS (2) | 9.3% | TMPTMA (3) | 9.3% | — | 0.0% | 18.6% | 0.26 |
| Example 77 | A-1 | 72.2% | SR205NS (2) | 9.3% | SR355NS (4) | 9.3% | — | 0.0% | 18.6% | 0.26 |
| Example 78 | A-1 | 72.2% | SR205NS (2) | 12.0% | A-9550 (5~6) | 6.6% | — | 0.0% | 18.6% | 0.26 |
| Example 79 | A-1 | 72.2% | SR205NS (2) | 12.0% | DPHA (6) | 6.6% | — | 0.0% | 18.6% | 0.26 |
| Example 80 | A-1 | 72.2% | BPE-100 (2) | 9.3% | VISCOAT | 9.3% | — | 0.0% | 18.6% | 0.26 |
| | | | | | #295 (3) | | | | | |
| Example 81 | A-1 | 72.2% | SR209 (2) | 9.3% | TMPTMA (3) | 9.3% | — | 0.0% | 18.6% | 0.26 |
| Example 82 | A-1 | 72.2% | SR205NS (2) | 10.4% | TMPTMA (3) | 4.1% | SR355NS | 4.1% | 18.6% | 0.26 |
| | | | | | | | (4) | | | |
| Example 83 | A-1 | 72.2% | SR205NS (2) | 9.0% | SR209 (2) | 6.0% | DPHA | 3.6% | 18.6% | 0.26 |
| | | | | | | | (6) | | | |
| Example 84 | A-1 | 72.2% | SR205NS (2) | 10.6% | M-130G (1) | 3.0% | TMPTMA | 5.0% | 18.6% | 0.26 |
| | | | | | | | (3) | | | |
| Example 85 | A-1 | 72.2% | VISCOAT | 12.0% | SR355NS (4) | 6.6% | — | 0.0% | 18.6% | 0.26 |
| | | | #295 (3) | | | | | | | |
| Example 86 | A-1 | 72.2% | TMPTMA (3) | 10.0% | SR355NS (4) | 8.6% | — | 0.0% | 18.6% | 0.26 |
| Example 87 | A-2 | 65.0% | SR205NS (2) | 24.2% | — | 0.0% | — | 0.0% | 24.2% | 0.37 |
| Example 88 | A-1 | 71.0% | SR205NS (2) | 18.2% | — | 0.0% | — | 0.0% | 18.2% | 0.26 |
| Example 89 | A-1 | 72.2% | SR205NS (2) | 18.6% | — | 0.0% | — | 0.0% | 18.6% | 0.26 |
| Example 90 | A-1 | 71.9% | SR205NS (2) | 18.6% | — | 0.0% | — | 0.0% | 18.6% | 0.26 |
| Example 91 | A-1 | 70.7% | SR205NS (2) | 18.6% | — | 0.0% | — | 0.0% | 18.6% | 0.26 |
| Example 92 | A-1 | 71.2% | SR209 (2) | 17.5% | — | 0.0% | — | 0.0% | 17.5% | 0.25 |
| Example 93 | A-2 | 65.0% | SR205NS (2) | 24.2% | — | 0.0% | — | 0.0% | 24.2% | 0.37 |
| Example 94 | A-1 | 71.0% | SR205NS (2) | 18.2% | — | 0.0% | — | 0.0% | 18.2% | 0.26 |
| Example 95 | A-1 | 72.2% | SR205NS (2) | 18.6% | — | 0.0% | — | 0.0% | 18.6% | 0.26 |
| Example 96 | A-1 | 71.9% | SR205NS (2) | 18.6% | — | 0.0% | — | 0.0% | 18.6% | 0.26 |
| Example 97 | A-1 | 70.7% | SR205NS (2) | 18.6% | — | 0.0% | — | 0.0% | 18.6% | 0.26 |
| Example 98 | A-1 | 71.2% | SR209 (2) | 17.5% | — | 0.0% | — | 0.0% | 17.5% | 0.25 |
| Example 99 | A-1 | 18.0% | SR205NS (2) | 6.0% | — | 0.0% | — | 0.0% | 6.0% | 0.33 |
| Example 100 | A-2 | 18.0% | SR205NS (2) | 6.0% | — | 0.0% | — | 0.0% | 6.0% | 0.33 |
| Example 101 | A-1 | 18.0% | SR205NS (2) | 6.0% | — | 0.0% | — | 0.0% | 6.0% | 0.33 |
| Example 102 | A-1 | 18.0% | SR205NS (2) | 6.0% | — | 0.0% | — | 0.0% | 6.0% | 0.33 |
| Example 103 | A-1 | 17.0% | SR205NS (2) | 5.2% | — | 0.0% | — | 0.0% | 5.2% | 0.31 |
| Example 104 | A-1 | 17.8% | SR205NS (2) | 6.0% | — | 0.0% | — | 0.0% | 6.0% | 0.34 |
| Example 105 | A-1 | 17.8% | SR205NS (2) | 6.0% | — | 0.0% | — | 0.0% | 6.0% | 0.34 |
| Example 106 | A-4 | 60.0% | SR205NS (2) | 29.2% | — | 0.0% | — | 0.0% | 29.2% | 0.49 |
| Example 107 | A-5 | 65.0% | SR205NS (2) | 24.2% | — | 0.0% | — | 0.0% | 24.2% | 0.37 |
| Example 108 | A-6 | 60.0% | SR205NS (2) | 29.2% | — | 0.0% | — | 0.0% | 29.2% | 0.49 |
| Example 109 | A-7 | 65.0% | SR205NS (2) | 24.2% | — | 0.0% | — | 0.0% | 24.2% | 0.37 |
| Comparative | A-2 | 90.5% | — | 0% | — | 0.0% | — | 0.0% | 0.0% | 0.00 |
| Example 1 | | | | | | | | | | |
| Comparative | A-2 | 71.0% | M-130G (1) | 19.5% | — | 0.0% | — | 0.0% | 19.5% | 0.27 |
| Example 2 | | | | | | | | | | |
| Comparative | A-2 | 78.0% | SR205NS (2) | 21.4% | — | 0.0% | — | 0.0% | 21.4% | 0.27 |
| Example 3 | | | | | | | | | | |
| Comparative | A-3 | 71.9% | SR205NS (2) | 18.6% | — | 0.0% | — | 0.0% | 18.6% | 0.26 |
| Example 4 | | | | | | | | | | |

TABLE 5

| | Formulation | | | | | | | | | | | |
|---|---|---|---|---|---|---|---|---|---|---|---|---|
| | (C) Specific | | (D) Chain | | (E) Polymerization | | | | (G) Thermal- | | | |
| | compound | | transfer agent | | inhibitor | | (F) Sensitizer | | base generator | | (H) Surfactant | |
| | Name | Amount | Name | Amount | Name | Amount | Name | Amount | Name | Amount | Name | Amount |
| Example 59 | C-1 | 6.3% | D-1 | 0.5% | MEHQ | 0.3% | EAB-F | 0.1% | G-1 | 1.7% | F- | 0.2% |
| | | | | | | | | | | | 551 | |
| | | | | | | | | | | | A | |
| Example 60 | C-1 | 6.3% | D-1 | 0.5% | MEHQ | 0.3% | EAB-F | 0.1% | G-1 | 1.7% | S- | 0.2% |
| | | | | | | | | | | | 506 | |
| Example 61 | C-1 | 6.3% | D-1 | 0.5% | Phenox- | 0.3% | EAB-F | 0.1% | G-1 | 1.7% | — | 0.0% |
| | | | | | athiin | | | | | | | |
| Example 62 | C-1 | 6.3% | D-1 | 0.5% | Phenox- | 2.0% | EAB-F | 0.1% | G-1 | 1.7% | — | 0.0% |
| | | | | | athiin | | | | | | | |
| Example 63 | C-1 | 6.3% | D-1 | 0.5% | MEHQ | 0.3% | EAB-F | 0.1% | G-1 | 1.7% | — | 0.0% |
| Example 64 | C-3 | 6.3% | D-1 | 0.5% | MEHQ | 0.3% | EAB-F | 0.1% | G-1 | 1.7% | — | 0.0% |
| Example 65 | C-1 | 6.3% | D-1 | 0.5% | MEHQ | 0.3% | EAB-F | 0.1% | G-1 | 1.7% | — | 0.0% |
| Example 66 | C-1 | 6.3% | D-1 | 0.5% | MEHQ | 0.4% | EAB-F | 0.3% | G-1 | 1.7% | — | 0.0% |
| Example 67 | C-2 | 6.3% | D-1 | 2.0% | MEHQ | 0.3% | EAB-F | 0.1% | G-1 | 1.7% | — | 0.0% |
| Example 68 | C-1 | 8.4% | D-1 | 0.5% | MEHQ | 0.4% | EAB-F | 0.1% | G-1 | 1.6% | — | 0.0% |
| Example 69 | C-1 | 6.3% | D-1 | 0.5% | MEHQ | 0.3% | EAB-F | 0.1% | G-1 | 1.7% | — | 0.0% |
| Example 70 | C-1 | 6.3% | D-1 | 0.5% | MEHQ | 0.3% | EAB-F | 0.1% | G-1 | 1.7% | — | 0.0% |
| Example 71 | C-3 | 6.3% | D-1 | 0.5% | MEHQ | 0.3% | EAB-F | 0.1% | G-1 | 1.7% | — | 0.0% |
| Example 72 | C-1 | 6.3% | D-1 | 0.5% | MEHQ | 0.3% | EAB-F | 0.1% | G-1 | 1.7% | — | 0.0% |
| Example 73 | C-1 | 6.3% | D-1 | 0.5% | MEHQ | 0.3% | EAB-F | 0.1% | G-1 | 1.7% | — | 0.0% |
| Example 74 | C-2 | 6.3% | D-1 | 0.5% | MEHQ | 0.3% | EAB-F | 0.1% | G-1 | 1.7% | — | 0.0% |
| Example 75 | C-1 | 6.3% | D-1 | 0.5% | MEHQ | 0.3% | EAB-F | 0.1% | G-1 | 1.7% | — | 0.0% |
| Example 76 | C-1 | 6.3% | D-1 | 0.5% | MEHQ | 0.3% | EAB-F | 0.1% | G-1 | 1.7% | — | 0.0% |
| Example 77 | C-1 | 6.3% | D-1 | 0.5% | MEHQ | 0.3% | EAB-F | 0.1% | G-1 | 1.7% | — | 0.0% |
| Example 78 | C-3 | 6.3% | D-1 | 0.5% | MEHQ | 0.3% | EAB-F | 0.1% | G-1 | 1.7% | — | 0.0% |
| Example 79 | C-1 | 6.3% | D-1 | 0.5% | MEHQ | 0.3% | EAB-F | 0.1% | G-1 | 1.7% | — | 0.0% |
| Example 80 | C-1 | 6.3% | D-1 | 0.5% | MEHQ | 0.3% | EAB-F | 0.1% | G-1 | 1.7% | — | 0.0% |
| Example 81 | C-1 | 6.3% | D-1 | 0.5% | MEHQ | 0.3% | EAB-F | 0.1% | G-1 | 1.7% | — | 0.0% |
| Example 82 | C-2 | 6.3% | D-1 | 0.5% | MEHQ | 0.3% | EAB-F | 0.1% | G-1 | 1.7% | — | 0.0% |
| Example 83 | C-2 | 6.3% | D-1 | 0.5% | MEHQ | 0.3% | EAB-F | 0.1% | G-1 | 1.7% | — | 0.0% |
| Example 84 | C-1 | 6.3% | D-1 | 0.5% | MEHQ | 0.3% | EAB-F | 0.1% | G-1 | 1.7% | — | 0.0% |
| Example 85 | C-3 | 6.3% | D-1 | 0.5% | MEHQ | 0.3% | EAB-F | 0.1% | G-1 | 1.7% | — | 0.0% |
| Example 86 | C-1 | 6.3% | D-1 | 0.5% | MEHQ | 0.3% | EAB-F | 0.1% | G-1 | 1.7% | — | 0.0% |
| Example 87 | C-4 | 6.3% | D-1 | 0.5% | MEHQ | 0.3% | EAB-F | 0.1% | G-1 | 1.7% | — | 0.0% |
| Example 88 | C-4 | 6.3% | D-1 | 0.5% | MEHQ | 0.3% | EAB-F | 0.1% | G-1 | 1.7% | — | 0.0% |
| Example 89 | C-4 | 6.3% | D-1 | 0.5% | MEHQ | 0.3% | EAB-F | 0.1% | G-1 | 1.7% | — | 0.0% |
| Example 90 | C-4 | 6.3% | D-1 | 0.5% | MEHQ | 0.4% | EAB-F | 0.3% | G-1 | 1.7% | — | 0.0% |
| Example 91 | C-4 | 6.3% | D-1 | 2.0% | MEHQ | 0.3% | EAB-F | 0.1% | G-1 | 1.7% | — | 0.0% |
| Example 92 | C-4 | 8.4% | D-1 | 0.5% | MEHQ | 0.4% | EAB-F | 0.1% | G-1 | 1.6% | — | 0.0% |
| Example 93 | C-5 | 6.3% | D-1 | 0.5% | MEHQ | 0.3% | EAB-F | 0.1% | G-1 | 1.7% | — | 0.0% |
| Example 94 | C-5 | 6.3% | D-1 | 0.5% | MEHQ | 0.3% | EAB-F | 0.1% | G-1 | 1.7% | — | 0.0% |
| Example 95 | C-5 | 6.3% | D-1 | 0.5% | MEHQ | 0.3% | EAB-F | 0.1% | G-1 | 1.7% | — | 0.0% |
| Example 96 | C-5 | 6.3% | D-1 | 0.5% | MEHQ | 0.4% | EAB-F | 0.3% | G-1 | 1.7% | — | 0.0% |
| Example 97 | C-5 | 6.3% | D-1 | 2.0% | MEHQ | 0.3% | EAB-F | 0.1% | G-1 | 1.7% | — | 0.0% |
| Example 98 | C-5 | 8.4% | D-1 | 0.5% | MEHQ | 0.4% | EAB-F | 0.1% | G-1 | 1.6% | — | 0.0% |
| Example 99 | C-1 | 4.4% | D-1 | 0.5% | MEHQ | 0.2% | EAB-F | 0.1% | G-1 | 0.5% | — | 0.0% |
| Example | C-1 | 4.4% | D-1 | 0.5% | MEHQ | 0.2% | EAB-F | 0.1% | G-1 | 0.5% | — | 0.0% |
| 100 | | | | | | | | | | | | |
| Example | C-2 | 4.4% | D-1 | 0.5% | MEHQ | 0.2% | EAB-F | 0.1% | G-1 | 0.5% | — | 0.0% |
| 101 | | | | | | | | | | | | |
| Example | C-3 | 4.4% | D-1 | 0.5% | MEHQ | 0.2% | EAB-F | 0.1% | G-1 | 0.5% | — | 0.0% |
| 102 | | | | | | | | | | | | |
| Example | C-1 | 4.4% | D-1 | 0.5% | Phenox- | 2.0% | EAB-F | 0.1% | G-1 | 0.5% | — | 0.0% |
| 103 | | | | | athiin | | | | | | | |
| Example | C-1 | 4.4% | D-1 | 0.5% | MEHQ | 0.2% | EAB-F | 0.1% | G-1 | 0.5% | F- | 0.2% |
| 104 | | | | | | | | | | | 551 | |
| | | | | | | | | | | | A | |
| Example | C-1 | 4.4% | D-1 | 0.5% | MEHQ | 0.2% | EAB-F | 0.1% | G-1 | 0.5% | S- | 0.2% |
| 105 | | | | | | | | | | | 506 | |
| Example | C-1 | 6.3% | D-1 | 0.5% | MEHQ | 0.3% | EAB-F | 0.1% | G-1 | 1.7% | — | 0.0% |
| 106 | | | | | | | | | | | | |
| Example | C-1 | 6.3% | D-1 | 0.5% | MEHQ | 0.3% | EAB-F | 0.1% | G-1 | 1.7% | — | 0.0% |
| 107 | | | | | | | | | | | | |
| Example | C-1 | 6.3% | D-1 | 0.5% | MEHQ | 0.3% | EAB-F | 0.1% | G-1 | 1.7% | — | 0.0% |
| 108 | | | | | | | | | | | | |
| Example | C-1 | 6.3% | D-1 | 0.5% | MEHQ | 0.3% | EAB-F | 0.1% | G-1 | 1.7% | — | 0.0% |
| 109 | | | | | | | | | | | | |
| Compar- | C-1 | 6.3% | D-1 | 0.5% | MEHQ | 0.3% | EAB-F | 0.1% | G-1 | 2.0% | — | 0.0% |
| ative | | | | | | | | | | | | |
| Example 1 | | | | | | | | | | | | |
| Compar- | C-1 | 6.3% | D-1 | 0.5% | MEHQ | 0.3% | EAB-F | 0.1% | G-1 | 2.0% | — | 0.0% |
| ative | | | | | | | | | | | | |
| Example 2 | | | | | | | | | | | | |
| Compar- | C-9 | 0.3% | — | 0.0% | — | 0.0% | — | 0.0% | — | 0.0% | — | 0.0% |
| ative | | | | | | | | | | | | |
| Example 3 | | | | | | | | | | | | |
| Compar- | C-1 | 6.3% | D-1 | 0.5% | MEHQ | 0.3% | EAB-F | 0.1% | G-1 | 2.0% | — | 0.0% |
| ative | | | | | | | | | | | | |
| Example 4 | | | | | | | | | | | | |

TABLE 6

| | | | | | | | Evaluation | | | |
|---|---|---|---|---|---|---|---|---|---|---|
| | Formulation | | | | | | | | Step | Linear |
| | (I) Rust inhibitor | | (J) Other | | (Z) Filler | | Reso- | Migration | follow- | Expansion |
| | Name | Amount | Name | Amount | Name | Amount | lution | resistance | ability | Coefficiency |
| Example 59 | HAT | 0.3% | — | 0.0% | — | 0.0% | A | B | A | B |
| Example 60 | HAT | 0.3% | — | 0.0% | — | 0.0% | A | B | A | B |
| Example 61 | HAT | 0.3% | — | 0.0% | — | 0.0% | A | B | A | B |
| Example 62 | HAT | 0.3% | — | 0.0% | — | 0.0% | A | B | A | B |
| Example 63 | HAT | 0.3% | J-1 | 1.6% | — | 0.0% | A | B | A | B |
| Example 64 | HAT | 0.3% | J-1 | 1.6% | — | 0.0% | A | A | A | B |
| Example 65 | HAT | 0.3% | — | 0.0% | — | 0.0% | A | B | A | B |
| Example 66 | HAT | 0.3% | — | 0.0% | — | 0.0% | A | B | A | B |
| Example 67 | HAT | 0.3% | — | 0.0% | — | 0.0% | A | B | A | B |
| Example 68 | HAT | 0.3% | — | 0.0% | — | 0.0% | A | B | A | B |
| Example 69 | HAT | 0.3% | — | 0.0% | — | 0.0% | A | B | A | B |
| Example 70 | HAT | 0.3% | J-1 | 1.6% | — | 0.0% | A | B | A | B |
| Example 71 | HAT | 0.3% | — | 0.0% | — | 0.0% | A | A | A | B |
| Example 72 | HAT | 0.3% | — | 0.0% | — | 0.0% | A | B | A | B |
| Example 73 | HAT | 0.3% | — | 0.0% | — | 0.0% | A | B | A | B |
| Example 74 | HAT | 0.3% | — | 0.0% | — | 0.0% | A | B | A | B |
| Example 75 | HAT | 0.3% | — | 0.0% | — | 0.0% | A | B | A | B |
| Example 76 | HAT | 0.3% | — | 0.0% | — | 0.0% | A | B | A | B |
| Example 77 | HAT | 0.3% | — | 0.0% | — | 0.0% | A | B | A | B |
| Example 78 | HAT | 0.3% | — | 0.0% | — | 0.0% | A | A | A | B |
| Example 79 | HAT | 0.3% | J-1 | 1.6% | — | 0.0% | A | B | A | B |
| Example 80 | HAT | 0.3% | — | 0.0% | — | 0.0% | A | B | A | B |
| Example 81 | HAT | 0.3% | — | 0.0% | — | 0.0% | A | B | A | B |
| Example 82 | HAT | 0.3% | — | 0.0% | — | 0.0% | A | B | A | B |
| Example 83 | HAT | 0.3% | — | 0.0% | — | 0.0% | A | B | A | B |
| Example 84 | HAT | 0.3% | — | 0.0% | — | 0.0% | A | B | A | B |
| Example 85 | HAT | 0.3% | — | 0.0% | — | 0.0% | A | A | A | B |
| Example 86 | HAT | 0.3% | — | 0.0% | — | 0.0% | A | B | A | B |
| Example 87 | HAT | 0.3% | J-1 | 1.6% | — | 0.0% | A | B | A | B |
| Example 88 | HAT | 0.3% | J-1 | 1.6% | — | 0.0% | A | B | A | B |
| Example 89 | HAT | 0.3% | — | 0.0% | — | 0.0% | A | B | A | B |
| Example 90 | HAT | 0.3% | — | 0.0% | — | 0.0% | A | B | A | B |
| Example 91 | HAT | 0.3% | — | 0.0% | — | 0.0% | A | B | A | B |
| Example 92 | HAT | 0.3% | — | 0.0% | — | 0.0% | A | B | A | B |
| Example 93 | HAT | 0.3% | J-1 | 1.6% | — | 0.0% | A | B | A | B |
| Example 94 | HAT | 0.3% | J-1 | 1.6% | — | 0.0% | A | B | A | B |
| Example 95 | HAT | 0.3% | — | 0.0% | — | 0.0% | A | B | A | B |
| Example 96 | HAT | 0.3% | — | 0.0% | — | 0.0% | A | B | A | B |
| Example 97 | HAT | 0.3% | — | 0.0% | — | 0.0% | A | B | A | B |
| Example 98 | HAT | 0.3% | — | 0.0% | — | 0.0% | A | B | A | B |
| Example 99 | HAT | 0.3% | — | 0.0% | YA050C- | 70.0% | A | B | A | A |
| | | | | | MJE | | | | | |
| Example 100 | HAT | 0.3% | — | 0.0% | YA050C- | 70.0% | A | B | A | A |
| | | | | | MJE | | | | | |
| Example 101 | HAT | 0.3% | — | 0.0% | YA050C- | 70.0% | A | B | A | A |
| | | | | | MJE | | | | | |
| Example 102 | HAT | 0.3% | — | 0.0% | YA050C- | 70.0% | A | A | A | A |
| | | | | | MJE | | | | | |
| Example 103 | HAT | 0.3% | — | 0.0% | YA050C- | 70.0% | A | B | A | A |
| | | | | | MJE | | | | | |
| Example 104 | HAT | 0.3% | — | 0.0% | YA050C- | 70.0% | A | B | A | A |
| | | | | | MJE | | | | | |
| Example 105 | HAT | 0.3% | — | 0.0% | YA050C- | 70.0% | A | B | A | A |
| | | | | | MJE | | | | | |
| Example 106 | HAT | 0.3% | J-1 | 1.6% | — | 0.0% | A | C | A | B |
| Example 107 | HAT | 0.3% | J-1 | 1.6% | — | 0.0% | A | C | A | B |
| Example 108 | HAT | 0.3% | J-1 | 1.6% | — | 0.0% | A | B | A | B |
| Example 109 | HAT | 0.3% | J-1 | 1.6% | — | 0.0% | A | B | A | B |
| Comparative | HAT | 0.3% | — | 0.0% | — | 0.0% | B | B | C | B |
| Example 1 | | | | | | | | | | |
| Comparative | HAT | 0.3% | — | 0.0% | — | 0.0% | B | B | A | B |
| Example 2 | | | | | | | | | | |
| Comparative | HAT | 0.3% | — | 0.0% | — | 0.0% | B | B | A | B |
| Example 3 | | | | | | | | | | |
| Comparative | HAT | 0.3% | — | 0.0% | — | 0.0% | A | D | A | B |
| Example 4 | | | | | | | | | | |

From the comparison of Examples 1 to 5, 15 to 20, 31 to 36, and 45 to 49, it was found that, in a case where the mass ratio of the content of the polymerizable compound to the content of the polyimide precursor was 0.22 or more, the level difference conformability was more excellent.

From the comparison of Examples 99 to 105 with other examples, it was found that, in a case where the photosensitive composition contained a filler, the linear expansion coefficient was smaller.

From the comparison of Examples 15 to 28, 31 to 58, and 87 to 98, it was found that, in a case where R in the specific compound was an alkoxy group, the migration resistance was more excellent.

From the comparison of Examples 1, 63, and 106 to 109, it was found that, in a case where the acid value of the polyimide precursor was 10 mgKOH/g or less, the migration resistance was more excellent.

Photosensitive compositions of Examples 110 to 127 were prepared by the same procedure as the photosensitive compositions of Examples 1 to 109 and Comparative Examples 1 to 4, except that the formulation was changed to have the formulation amount (the formulation amount of the solid content ratio) shown in the tables below. Next, [Production of transfer film] and [Evaluation] were performed using the photosensitive compositions of Examples 110 to 127 by the same procedure as the photosensitive compositions of Examples 1 to 109 and Comparative Examples 1 to 4.

However, in Example 127, in a case of producing the evaluation sample of [Migration resistance] and the measurement sample of [Linear expansion coefficient], after the exposure, the sample was immersed in a treatment liquid prepared by mixing the following components for 120 seconds, and then a heat treatment was performed.

### Treatment Liquid

PGMEA: 90.3 parts by mass

Gamma-butyrolactone: 4.7 parts by mass

N-(3-dimethylaminopropyl) methacrylamide: 5 parts by mass

Various components contained in the photosensitive composition are shown below.
Compound G-2: thermal-base generator, the following compound
Compound G-3: thermal-base generator, the following compound
Compound D-2: chain transfer agent, N-phenylglycine, manufactured by FUJIFILM Wako Pure Chemical Corporation
Compound D-3: chain transfer agent, methoxybutyl-β-mercaptopropionate, manufactured by SAKAI CHEMICAL INDUSTRY CO., LTD.
Compound F-2: sensitizer, 4,4′-bis(dimethylamino) benzophenone, manufactured by FUJIFILM Wako Pure Chemical Corporation
Compound F-3: sensitizer, 2-isopropylthioxanthone, manufactured by FUJIFILM Wako Pure Chemical Corporation
Compound I-2: rust inhibitor, 3-amino-1H-1,2,4-triazole, manufactured by FUJIFILM Wako Pure Chemical Corporation
Compound I-3: rust inhibitor, 1H-triazole, manufactured by FUJIFILM Wako Pure Chemical Corporation

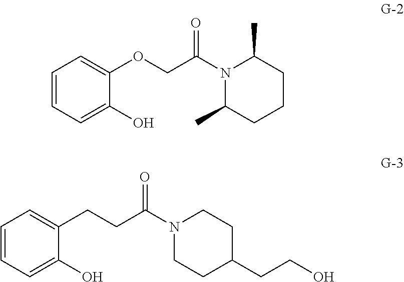 [SMILES: C[C@@H]1CCC[C@H](C)N1C(=O)COc1ccccc1O ; O=C(CCc1ccccc1O)N1CCC(CCO)CC1]

The formulations and evaluation results of the photosensitive compositions are shown in the tables below. Table 8 is a continuation of Table 7, and Table 9 is a continuation of Table 8. The meanings of the respective columns in Tables 7 to 9 are the same as the meanings of the respective columns in Tables 1 to 6.

TABLE 7

| | Formulation | | | | | | | | | |
|---|---|---|---|---|---|---|---|---|---|---|
| | (A) Polyimide | | | | | | | | | |
| | precursor | | (B) Polymerizable compound | | | | | | Total | |
| | Name | Amount | Name | Amount | Name | Amount | Name | Amount | amount | B/A |
| Example 110 | A-1 | 71.0% | SR205NS (2) | 18.5% | — | 0.0% | — | 0.0% | 18.5% | 0.26 |
| Example 111 | A-1 | 71.7% | SR205NS (2) | 18.2% | — | 0.0% | — | 0.0% | 18.2% | 0.25 |
| Example 112 | A-1 | 69.7% | SR205NS (2) | 18.2% | — | 0.0% | — | 0.0% | 18.2% | 0.26 |
| Example 113 | A-1 | 67.7% | SR205NS (2) | 18.2% | — | 0.0% | — | 0.0% | 18.2% | 0.27 |
| Example 114 | A-1 | 71.0% | SR205NS (2) | 18.2% | — | 0.0% | — | 0.0% | 18.2% | 0.26 |
| Example 115 | A-1 | 69.7% | SR205NS (2) | 18.2% | — | 0.0% | — | 0.0% | 18.2% | 0.26 |
| Example 116 | A-1 | 71.0% | SR205NS (2) | 18.2% | — | 0.0% | — | 0.0% | 18.2% | 0.26 |
| Example 117 | A-1 | 69.7% | SR205NS (2) | 18.2% | — | 0.0% | — | 0.0% | 18.2% | 0.26 |
| Example 118 | A-1 | 71.0% | SR205NS (2) | 18.2% | — | 0.0% | — | 0.0% | 18.2% | 0.26 |
| Example 119 | A-1 | 71.0% | SR205NS (2) | 18.2% | — | 0.0% | — | 0.0% | 18.2% | 0.26 |
| Example 120 | A-1 | 71.0% | SR205NS (2) | 18.2% | — | 0.0% | — | 0.0% | 18.2% | 0.26 |
| Example 121 | A-1 | 71.0% | SR205NS (2) | 18.2% | — | 0.0% | — | 0.0% | 18.2% | 0.26 |
| Example 122 | A-1 | 71.0% | SR205NS (2) | 18.2% | — | 0.0% | — | 0.0% | 18.2% | 0.26 |
| Example 123 | A-1 | 71.0% | SR205NS (2) | 18.2% | — | 0.0% | — | 0.0% | 18.2% | 0.26 |
| Example 124 | A-1 | 71.2% | SR205NS (2) | 18.2% | — | 0.0% | — | 0.0% | 18.2% | 0.26 |
| Example 125 | A-1 | 70.8% | SR205NS (2) | 18.2% | — | 0.0% | — | 0.0% | 18.2% | 0.26 |
| Example 126 | A-1 | 70.3% | SR205NS (2) | 18.2% | — | 0.0% | — | 0.0% | 18.2% | 0.26 |
| Example 127 | A-1 | 72.7% | SR205NS (2) | 18.2% | — | 0.0% | — | 0.0% | 18,2% | 0.25 |

TABLE 8

| | Formulation | | | | | | | | | | | |
|---|---|---|---|---|---|---|---|---|---|---|---|---|
| | (C) Specific | | (D) Chain | | (E) Polymeri- | | | | (G) Thermal- | | | |
| | compound | | transfer agent | | zation inhibitor | | (F) Sensitizer | | base generator | | (H) Surfactant | |
| | Name | Amount | Name | Amount | Name | Amount | Name | Amount | Name | Amount | Name | Amount |
| Example 110 | C-1 | 6.3% | D-1 | 0.5% | — | 0.0% | EAB-F | 0.1% | G-1 | 1.7% | — | 0.0% |
| Example 111 | C-1 | 6.3% | D-1 | 0.5% | MEHQ | 0.3% | EAB-F | 0.1% | G-1 | 1.0% | — | 0.0% |
| Example 112 | C-1 | 6.3% | D-1 | 0.5% | MEHQ | 0.3% | EAB-F | 0.1% | G-1 | 3.0% | — | 0.0% |
| Example 113 | C-1 | 6.3% | D-1 | 0.5% | MEHQ | 0.3% | EAB-F | 0.1% | G-1 | 5.0% | — | 0.0% |
| Example 114 | C-1 | 6.3% | D-1 | 0.5% | MEHQ | 0.3% | EAB-F | 0.1% | G-2 | 1.7% | — | 0.0% |
| Example 115 | C-1 | 6.3% | D-1 | 0.5% | MEHQ | 0.3% | EAB-F | 0.1% | G-2 | 3.0% | — | 0.0% |
| Example 116 | C-1 | 6.3% | D-1 | 0.5% | MEHQ | 0.3% | EAB-F | 0.1% | G-3 | 1.7% | — | 0.0% |
| Example 117 | C-1 | 6.3% | D-1 | 0.5% | MEHQ | 0.3% | EAB-F | 0.1% | G-3 | 3.0% | — | 0.0% |
| Example 118 | C-1 | 6.3% | D-2 | 0.5% | MEHQ | 0.3% | EAB-F | 0.1% | G-1 | 1.7% | — | 0.0% |
| Example 119 | C-1 | 6.3% | D-3 | 0.5% | MEHQ | 0.3% | EAB-F | 0.1% | G-1 | 1.7% | — | 0.0% |
| Example 120 | C-1 | 6.3% | D-1 | 0.5% | MEHQ | 0.3% | F-2 | 0.1% | G-1 | 1.7% | — | 0.0% |
| Example 121 | C-1 | 6.3% | D-1 | 0.5% | MEHQ | 0.3% | F-3 | 0.1% | G-1 | 1.7% | — | 0.0% |
| Example 122 | C-1 | 6.3% | D-1 | 0.5% | MEHQ | 0.3% | EAB-F | 0.1% | G-1 | 1.7% | — | 0.0% |
| Example 123 | C-1 | 6.3% | D-1 | 0.5% | MEHQ | 0.3% | EAB-F | 0.1% | G-1 | 1.7% | — | 0.0% |
| Example 124 | C-1 | 6.3% | D-1 | 0.5% | MEHQ | 0.3% | EAB-F | 0.1% | G-1 | 1.7% | — | 0.0% |
| Example 125 | C-1 | 6.3% | D-1 | 0.5% | MEHQ | 0.3% | EAB-F | 0.1% | G-1 | 1.7% | — | 0.0% |
| Example 126 | C-1 | 6.3% | D-1 | 0.5% | MEHQ | 0.3% | EAB-F | 0.1% | G-1 | 1.7% | — | 0.0% |
| Example 127 | C-1 | 6.3% | D-1 | 0.5% | MEHQ | 0.3% | EAB-F | 0.1% | — | 0.0% | — | 0.0% |

TABLE 9

| | | | | | | | Evaluation | | | |
|---|---|---|---|---|---|---|---|---|---|---|
| | Formulation | | | | | | | | Step | Linear |
| | (I) Rust inhibitor | | (J) Other | | (Z) Filler | | Reso- | Migration | follow- | Expansion |
| | Name | Amount | Name | Amount | Name | Amount | lution | resistance | ability | Coefficiency |
| Example 110 | HAT | 0.3% | J-1 | 1.6% | — | 0.0% | A | B | A | B |
| Example 111 | HAT | 0.3% | J-1 | 1.6% | — | 0.0% | A | B | A | B |
| Example 112 | HAT | 0.3% | J-1 | 1.6% | — | 0.0% | A | B | A | B |
| Example 113 | HAT | 0.3% | J-1 | 1.6% | — | 0.0% | A | B | A | B |
| Example 114 | HAT | 0.3% | J-1 | 1.6% | — | 0.0% | A | B | A | B |
| Example 115 | HAT | 0.3% | J-1 | 1.6% | — | 0.0% | A | B | A | B |
| Example 116 | HAT | 0.3% | J-1 | 1.6% | — | 0.0% | A | B | A | B |
| Example 117 | HAT | 0.3% | J-1 | 1.6% | — | 0.0% | A | B | A | B |
| Example 118 | HAT | 0.3% | J-1 | 1.6% | — | 0.0% | A | B | A | B |
| Example 119 | HAT | 0.3% | J-1 | 1.6% | — | 0.0% | A | B | A | B |
| Example 120 | HAT | 0.3% | J-1 | 1.6% | — | 0.0% | A | B | A | B |
| Example 121 | HAT | 0.3% | J-1 | 1.6% | — | 0.0% | A | B | A | B |
| Example 122 | I-2 | 0.3% | J-1 | 1.6% | — | 0.0% | A | B | A | B |
| Example 123 | I-3 | 0.3% | J-1 | 1.6% | — | 0.0% | A | B | A | B |
| Example 124 | HAT | 0.1% | J-1 | 1.6% | — | 0.0% | A | B | A | B |
| Example 125 | HAT | 0.5% | J-1 | 1.6% | — | 0.0% | A | B | A | B |
| Example 126 | HAT | 1.0% | J-1 | 1.6% | — | 0.0% | A | B | A | B |
| Example 127 | HAT | 0.3% | J-1 | 1.6% | — | 0.0% | A | B | A | B |

### Production of Semiconductor Package

The transfer film of each example was laminated on both surfaces of a glass epoxy substrate (CCL-EL190T, thickness: 1.0 mm, manufactured by MITSUBISHI GAS CHEMICAL COMPANY, INC.) on which a circuit pattern had been formed, thereby forming a composition layer on both surfaces of the glass epoxy substrate. At this time, a vacuum laminator was used. The lamination was carried out under the following conditions using a vacuum laminator manufactured by MCK Co., Ltd.: a substrate temperature of 50° C., a rubber roller temperature of 100° C., a linear pressure of 3 N/cm, and a transportation speed of 1 m/min.

The obtained laminate was exposed (high-pressure mercury lamp, the optimum exposure amount) through a mask having a light shielding part of 100 μmΦ from the temporary support side. After the exposure, the laminate was immersed in cyclopentanone for 120 seconds and immersed in PGMEA for 30 seconds to remove the non-exposed portion, thereby forming a pattern. After performing a heat treatment (200° C., 100 minutes), the residues were removed with a sodium permanganate aqueous solution as a roughening solution, and an electroless plating treatment was performed. Next, a resist pattern was formed at a predetermined position using a known dry film resist, and an electrolytic plating treatment was carried out. Next, the resist pattern was peeled off with a stripper. In Example 127, after the non-exposed portion was removed to form a pattern, the laminate was immersed in the above-described treatment liquid for 120 seconds and then subjected to a heat treatment.

Finally, a seed layer etching treatment was performed to form a copper wiring on the cured film.

The above-described process from the lamination to the heating treatment was carried out three times, and finally, a solder resist was formed as an outermost layer, and a semiconductor element was further sealed and mounted to produce a semiconductor package. The obtained semiconductor package was mounted at a predetermined position of a printed wiring board to obtain a semiconductor package substrate. It was found that the obtained semiconductor package substrate normally operated.

### EXPLANATION OF REFERENCES

12: temporary support
14: photosensitive composition layer
16: cover film
100: transfer film

What is claimed is:

1. A photosensitive composition comprising:
a polyimide precursor;
a polymerizable compound that is a compound different from the polyimide precursor; and
a compound represented by Formula (1),
wherein the polymerizable compound includes a compound having two or more polymerizable groups, and
an acid value of the polyimide precursor is 75 mgKOH/g or less, 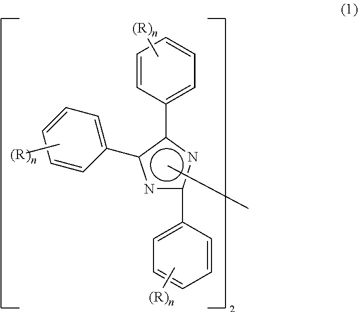
in Formula (1), R's each independently represents a substituent, and n's each independently represents an integer of 0 to 5.

2. The photosensitive composition according to claim 1, wherein the acid value of the polyimide precursor is 10 mgKOH/g or less.

3. The photosensitive composition according to claim 1, wherein the acid value of the polyimide precursor is 5 mgKOH/g or less.

4. The photosensitive composition according to claim 1, wherein a dissolution rate of the polyimide precursor in 200 mL of an aqueous solution of 2.38% by mass tetramethylammonium hydroxide at 23° C. is 100 mg/min or less.

5. The photosensitive composition according to claim 1, wherein a dissolution rate of the polyimide precursor in 200 mL of an aqueous solution of 2.38% by mass tetramethylammonium hydroxide at 23° C. is 50 mg/min or less.

6. The photosensitive composition according to claim 1, wherein a dissolution rate of the polyimide precursor in 200 mL of an aqueous solution of 2.38% by mass tetramethylammonium hydroxide at 23° C. is 1 mg/min or less.

7. The photosensitive composition according to claim 1, wherein the polyimide precursor has a polymerizable group.

8. The photosensitive composition according to claim 1, wherein a weight-average molecular weight of the polyimide precursor is 10,000 to 50,000.

9. The photosensitive composition according to claim 1, wherein a content of the polyimide precursor is 10.0% to 90.0% by mass with respect to a total solid content of the photosensitive composition.

10. The photosensitive composition according to claim 1, wherein a weight-average molecular weight of the polymerizable compound is 150 to 1,000.

11. The photosensitive composition according to claim 1, wherein a content of the polymerizable compound is 3.0% to 50.0% by mass with respect to a total solid content of the photosensitive composition.

12. The photosensitive composition according to claim 1, wherein a mass ratio of a content of the polymerizable compound to a content of the polyimide precursor is 0.20 or more.

13. The photosensitive composition according to claim 1, further comprising: a chain transfer agent.

14. The photosensitive composition according to claim 13, wherein a content of the chain transfer agent is 0.01% to 5.0% by mass with respect to a total solid content of the photosensitive composition.

15. The photosensitive composition according to claim 13, wherein the chain transfer is a compound represented by Formula (II), 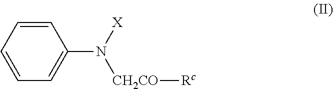
in Formula (II), X represents a hydrogen atom or a monovalent organic group, R^{c} represents a hydroxy group, an alkoxy group, or —O⁻M⁺, and M⁺ represents an alkali metal cation.

16. The photosensitive composition according to claim 1, wherein the acid value of the polyimide precursor is 10 mgKOH/g or less, a dissolution rate of the polyimide precursor in 200 mL of an aqueous solution of 2.38% by mass tetramethylammonium hydroxide at 23° C. is 100 mg/min or less, and the photosensitive composition further includes a chain transfer agent.

17. The photosensitive composition according to claim 1, further comprising: a polymerization inhibitor.

18. The photosensitive composition according to claim 17, wherein a content of the polymerization inhibitor is 0.01% to 5.0% by mass with respect to a total solid content of the photosensitive composition.

19. The photosensitive composition according to claim 1, further comprising: a sensitizer.

20. The photosensitive composition according to claim 19, wherein a content of the sensitizer is 0.01% to 5.0% by mass with respect to a total solid content of the photosensitive composition.

21. The photosensitive composition according to claim 1, further comprising: a filler.

22. The photosensitive composition according to claim 21, wherein the filler includes at least one selected from the group consisting of silicon dioxide, boron nitride, barium sulfate, and silicate.

23. The photosensitive composition according to claim 21, wherein an average particle diameter of the filler is 100 nm or less.

24. The photosensitive composition according to claim 21, wherein a content of the filler is 30.0% by mass or more with respect to a total solid content of the photosensitive composition.

25. The photosensitive composition according to claim 21, wherein a content of the filler is 90.0% by mass or less with respect to a total solid content of the photosensitive composition.

26. A transfer film comprising: a temporary support; and a photosensitive layer formed of the photosensitive composition according to claim 1.

27. A method for manufacturing a laminate, comprising:
a step 1 of forming a photosensitive composition layer on a substrate using the photosensitive composition according to claim 1;
a step 2 of forming a pattern including a via on the photosensitive composition layer; and
a step 3 of performing at least one of heating or exposure on the pattern.

28. A laminate manufactured by the method for manufacturing a laminate according to claim 27.

29. A semiconductor package comprising:
the laminate according to claim 28.
